(19) United States
(12) Patent Application Publication
(10) Pub. No.: US 2013/0260319 A1
(43) Pub. Date: Oct. 3, 2013

(54) METHOD OF PRODUCING POLYMERIC COMPOUND, RESIST COMPOSITION AND METHOD OF FORMING RESIST PATTERN

(71) Applicant: TOKYO OHKA KOGYO CO., LTD., Kawasaki-shi (JP)

(72) Inventors: Masatoshi Arai, Kawasaki-shi (JP); Yoshiyuki Utsumi, Kawasaki-shi (JP)

(21) Appl. No.: 13/851,880

(22) Filed: Mar. 27, 2013

(30) Foreign Application Priority Data
Mar. 28, 2012 (JP) 2012074955

(51) Int. Cl. G03F 7/004; G03F 7/20

(52) U.S. Cl. CPC G03F 7/004; G03F 7/20
USPC 430/325; 521/32

(57) ABSTRACT

A method of producing a polymeric compound having a structural unit that is decomposed and generates acid upon exposure, including reacting a first precursor polymer having a first ammonium cation with an amine whose conjugate acid has an acid dissociation constant (pKa) larger than that of the first ammonium cation to obtain a second precursor polymer having a second ammonium cation that is a conjugate acid of the amine; and performing a salt-exchange between the second precursor polymer and a sulfonium cation or an iodonium cation, in which the second ammonium cation is less hydrophobic than the first ammonium cation, and also less hydrophobic than the sulfonium cation or the iodonium cation.

### TECHNICAL FIELD

The present invention is related to a method of producing a polymeric compound useful as a base component of a resist composition, a resist composition containing the polymeric compound, and a method of forming a resist pattern utilizing the resist composition.

Priority is claimed on Japanese Patent Application No. 2012-074955, filed Mar. 28, 2012, the content of which is incorporated herein by reference.

### BACKGROUND ART

In lithography techniques, for example, a resist film composed of a resist material is formed on a substrate, and the resist film is subjected to selective exposure, followed by development, thereby forming a resist pattern having a predetermined shape on the resist film. A resist material in which the exposed portions of a resist film become soluble in a developing solution is called a positive-type, and a resist material in which the exposed portions become insoluble in a developing solution is called a negative-type.

In recent years, in the production of semiconductor elements and liquid crystal display elements, advances in lithography techniques have led to rapid progress in the field of pattern miniaturization.

Typically, these miniaturization techniques involve shortening the wavelength (increasing the energy) of the exposure light source. Conventionally, ultraviolet radiation typified by g-line and i-line radiation has been used, but nowadays KrF excimer lasers and ArF excimer lasers are starting to be introduced in mass production. Furthermore, research is also being conducted into lithography techniques that use an exposure light source having a wavelength shorter (energy higher) than these excimer lasers, such as EUV (extreme ultraviolet radiation), EB (electron beam), and X ray.

Resist materials for use with these types of exposure light sources require lithography properties such as a high resolution capable of reproducing patterns of minute dimensions, and a high level of sensitivity to these types of exposure light sources.

As a resist material that satisfies these conditions, a chemically amplified resist composition which contains a base component that exhibits a changed solubility in a developing solution under the action of acid and an acid-generator component that generates acid upon exposure has been conventionally used.

For example, in the case where the developing solution is an alkali developing solution (alkali developing process), a chemically amplified positive resist which contains, as a base component (base resin), a resin which exhibits increased solubility in an alkali developing solution under action of acid, and an acid generator is typically used. If the resist film formed using the resist composition is selectively exposed during formation of a resist pattern, then within the exposed portions, acid is generated from the acid-generator component, and the action of this acid causes an increase in the solubility of a base resin in an alkali developing solution, making the exposed portions soluble in the alkali developing solution. Accordingly, the unexposed portions remain to form a positive resist pattern following an alkali development. The base resin used exhibits increased polarity by the action of acid, thereby exhibiting increased solubility in an alkali developing solution, whereas the solubility in an organic solvent is decreased.

On the other hand, when a solvent developing process using a developing solution containing an organic solvent (organic developing solution) is employed instead of an alkali developing process, the solubility of the exposed portions in an organic developing solution is decreased. As a result, the unexposed portions of a resist film are dissolved and removed by the organic developing solution, and a negative resist pattern in which the exposed portions remain as a pattern is formed. According to the above, a solvent developing process forming a negative resist pattern is also referred to as a negative tone-developing process (see, for example, Patent Document 1).

Currently, resins that contain structural units derived from (meth)acrylate esters within the main chain (acrylic resins) and the like are now typically used as base resins for chemically amplified resist compositions that use ArF excimer laser lithography, as they exhibit excellent transparency in the vicinity of 193 nm (see, for example, Patent Document 2).

Here, the term “(meth)acrylate ester” is a generic term that includes either or both of the acrylate ester having a hydrogen atom bonded to the α-position and the methacrylate ester having a methyl group bonded to the α-position. The term “(meth)acrylate” is a generic term that includes either or both of the acrylate having a hydrogen atom bonded to the α-position and the methacrylate having a methyl group bonded to the α-position. The term “(meth)acrylic acid” is a generic term that includes either or both of acrylic acid having a hydrogen atom bonded to the α-position and methacrylic acid having a methyl group bonded to the α-position.

In recent years, a base resin having an acid generating group that are decomposed and generates acid upon exposure has been proposed. For example, a polymer obtained by copolymerizing a monomer having an acid generating group that generates acid upon exposure and a monomer having an acid decomposable group whose polarity is changed by the action of acid has been proposed (see, for example, Patent Document 3).

Since such a polymer serves as not only as an acid-generator but also as a base component, the polymer can compose a chemically amplified resist composition by one component. That is, when the polymer is exposed, an acid generating group in a structure generates an acid, and an acid decomposable group is decomposed by the action of the acid to form a polar group such as a carboxy group, and thereby a polarity is increased. Thus, when a resist film formed with the polymer is selectively exposed, a polarity of a exposed portion is increased, and the exposed portion is dissolved and removed by developing with an alkali developing solution, and thereby a positive resist pattern is formed. Also, an unexposed portion is dissolved and removed by developing with an organic developing solution, and thereby a negative resist pattern is formed.

### DOCUMENTS OF RELATED ART

### Patent Documents

[Patent Document 1] Japanese Unexamined Patent Application, First Publication No. 2009-25707
[Patent Document 2] Japanese Unexamined Patent Application, First Publication No. 2003-241385
[Patent Document 3] PCT International Publication No. WO2006/121096

### SUMMARY OF THE INVENTION

By using a polymer having both an acid generating group and an acid decomposable group as described in Patent Document 3 of the above, a resolution will be improved compared to the case where an acid generator and a base component are added separately. A reason why the resolution is improved seems to be that an acid generating group present in a base resin or a base component tends to be uniformly distributed within the resist film, and thereby an acid generated from the acid generating group upon exposure tends to be uniformly distributed within the resist film. Such a polymer having both an acid generating group and an acid decomposable group is typically produced by a conventional radical polymerization method in which a monomer is used to induce repeating units that composes the polymer.

However, when the polymer having both an acid generating group and an acid decomposable group of the above is produced by a conventional radical polymerization method in which the monomer having an acid generating group and the monomer having an acid decomposable group are copolymerized, a desired polymer cannot be produced depending on a type of the monomer having an acid generating group.

The present invention takes the above circumstances into consideration, with an object of providing a novel method of producing a polymeric compound having a structural unit that is decomposed and generates acid upon exposure; a resist composition containing the polymeric compound; and a method of forming a resist pattern utilizing the resist composition.

The present inventors have found a problem in producing a polymeric compound having a structural unit that is decomposed and generates acid upon exposure by directly radical polymerizing a monomer having an acid generating group that generates an acid upon exposure and another monomer, that is, polymerization may not occur depending on the structure of a cation moiety in a monomer having an acid generating group. As a result of intensive studies, the present inventors have found that a desired polymeric compound can be produced by synthesizing a precursor polymer having an ammonium cation with lower hydrophobicity utilizing differences of acid dissociation constants (pKa) of conjugate acids, and performing a salt-exchange to introduce a predetermined cation utilizing differences of hydrophobicities, and thereby the present invention has been completed. That is, the present invention employs the following aspects.

A first aspect of the present invention is a method of producing a polymeric compound having a structural unit that is decomposed and generates acid upon exposure, including reacting a first precursor polymer having a first ammonium cation with an amine whose conjugate acid has an acid dissociation constant (pKa) larger than that of the first ammonium cation to obtain a second precursor polymer having a second ammonium cation that is a conjugate acid of the amine; and performing a salt-exchange between the second precursor polymer and a sulfonium cation or an iodonium cation, in which the second ammonium cation is less hydrophobic than the first ammonium cation, and also less hydrophobic than the sulfonium cation or the iodonium cation.

A second aspect of the present invention is a resist composition containing a polymeric compound produced by the method of producing a polymeric compound according to the first aspect.

A third aspect of the present invention is a method of forming a resist pattern, including forming a resist film on a substrate by using a resist composition of the second aspect; exposing the resist film; and developing the resist film to form a resist pattern.

A fourth aspect of the present invention is a method of producing a polymeric compound, including reacting a first precursor polymer having a first ammonium cation with an amine whose conjugate acid has an acid dissociation constant (pKa) larger than that of the first ammonium cation, and the conjugate acid is less hydrophobic than the first ammonium cation.

In the present description and claims, the term “exposure” is used as a general concept that includes irradiation with any form of radiation.

The term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified. The same applies for the alkyl group within an alkoxy group.

The term “alkylene group” includes linear, branched or cyclic, divalent saturated hydrocarbon, unless otherwise specified.

A “halogenated alkyl group” is a group in which part or all of the hydrogen atoms of an alkyl group is substituted with a halogen atom, and a “halogenated alkylene group” is a group in which part or all of the hydrogen atoms of an alkylene group is substituted with a halogen atom. Examples of the halogen atom include a fluorine atom, a chlorine atom, a bromine atom and an iodine atom.

A “fluorinated alkyl group” is a group in which part or all of the hydrogen atoms of an alkyl group are substituted with a fluorine atom, and a “fluorinated alkylene group” is a group in which part or all of the hydrogen atoms of an alkylene group have been substituted with a fluorine atom.

In the present description, the term “polymeric compound” or “resin” refers to a polymer having a molecular weight of 1,000 or more. With respect to a polymeric compound, the “molecular weight” is the weight average molecular weight in terms of the polystyrene equivalent value determined by gel permeation chromatography (GPC).

The term “structural unit” refers to a monomer unit that contributes to the formation of a polymeric compound (resin, polymer, copolymer).

According to the present invention, there is provided a novel method of producing a polymeric compound having a structural unit that is decomposed and generates acid upon exposure; a resist composition containing the polymeric compound; and a method of forming a resist pattern utilizing the resist composition.

### MODE FOR CARRYING OUT THE INVENTION

### Method of Producing a Polymeric Compound

A method of producing a polymeric compound according to the present invention includes reacting the first precursor polymer having a first ammonium cation and an amine whose conjugate acid has an acid dissociation constant (pKa) larger than that of the first ammonium cation to obtain the second precursor polymer having a second ammonium cation that is a conjugate acid of the amine (hereinafter, the step referred to as “amine reaction step”); and performing a salt-exchange between the second precursor polymer and a sulfonium cation or an iodonium cation (hereinafter, the step referred to as “salt-exchange step”).

A polymeric compound produced by the production method has a structural unit that is decomposed and generates acid upon exposure. The structural unit that is decomposed and generates acid upon exposure has a cation moiety and an anion moiety, and the cation moiety has a sulfonium cation or an iodonium cation.

Such a polymeric compound is suitable as a base resin used for a base component of a resist composition.

In a production method according to the present invention, the first precursor polymer having a first ammonium cation, an amine, and a compound for salt-exchange which satisfy a relationship between a predetermined pKa and hydrophobicity are selected by taking into consideration hydrophobicity of a sulfonium cation or an iodonium cation in a polymeric compound as a final product and used in combination.

### [Amine Reaction Step]

In an amine reaction step, the first precursor polymer having the first ammonium cation is reacted with an amine whose conjugate acid has a pKa larger than that of the first ammonium cation to obtain the second precursor polymer having a second ammonium cation that is a conjugate acid of the amine.

In the present invention, an “ammonium cation” refers to an NH₄⁺, or a cation in which H of the NH₄⁺ is substituted with a hydrocarbon group that may have a heteroatom (a primary-quaternary ammonium cation), or a cyclic cation forming a ring with an N thereof.

### (Amine)

In an amine used for a reaction with the first precursor polymer in the amine reaction step, a pKa of a conjugate acid of the amine (it is a second ammonium cation) is larger than that of the first ammonium cation, and the conjugate acid of the amine (the second ammonium cation) is less hydrophobic than the first ammonium cation.

In addition, the conjugate acid (the second ammonium cation) is less hydrophobic than a sulfonium cation or an iodonium cation used in a salt-exchange step following the amine reaction step, and the conjugate acid is exchangeable with these sulfonium cation and iodonium cation.

By reacting such an amine with the first precursor polymer, a cation that is less hydrophobic than a cation to be finally obtained (a sulfonium cation or an iodonium cation used for a salt-exchange of the second precursor polymer in a salt-exchange step, and hereinafter it is referred to as “a final sulfonium or iodonium cation”) is introduced.

In the present invention, “hydrophobicity of cation” can be compared between two or more of cations by retention times analyzed by the high performance liquid chromatography (HPLC) method under the same conditions. In the present invention, a cation having a relatively longer retention time measured by the HPLC method is referred to as “high-hydrophobicity cation” and a cation having a relatively shorter retention time is referred to as “low-hydrophobicity cation”.

Devices and conditions used in the HPLC method are general devices and conditions used for analyzing compounds, and are not particularly limited as long as cations can be analyzed with those. Specifically, the following conditions can be used for measurements.

Eluant (developing solvent): acetonitrile/buffer (50/50 volume ratio).

Buffer: 0.1 wt % trifluoroacetic acid aqueous solution.

Device: Dionex U3000 (manufactured by Dionex, Co., Ltd.).
Column: Speriorex ODS (manufactured by Shiseido, Co., Ltd.); Column length 25 cm.
Detector: Corona CAD (manufactured by ESA Biosciences, Co., Ltd.).
Flow rate: 1 mL/min.
Column temperature: 30° C.
Sample concentration: acetonitrile solution having the solid content of 0.1 wt %.
Injection volume: 2 μL.

Note that the sample concentration of the above indicates the solid content of the compound in which an anion is Br⁻, and a cation is a variety of objective structures.

A retention time of a conjugate acid of an amine (second ammonium cation) measured by HPLC under the specific conditions of the above is preferably 1 to 3.5 minutes, more preferably 1.5 to 3 minutes, and still more preferably 1.5 to 2.5 minutes.

When the retention time is greater than or equal to the preferable lower limit of the value, the conjugate acid of an amine (second ammonium cation) exhibits an excellent solubility in an organic solvent, while the retention time is less than or equal to the preferable upper limit of the value, a salt-exchange reaction with a sulfonium salt or an iodonium salt in the salt-exchange step becomes easier to perform.

Also, a retention time of a conjugate acid of an amine (second ammonium cation), is preferably shorter (faster) by 0.2 minutes or more, and more preferably shorter (faster) by 0.3 minutes or more than that of a final sulfonium or iodonium cation.

When a retention time is relatively shorter by 0.2 minutes or more, a salt-exchange reaction with a sulfonium salt or an iodonium salt in the salt-exchange step becomes easier to perform.

In the present invention, “pKa” refers to an acid dissociation constant which is generally used as a parameter which shows the acid strength of an objective substance. The pKa value of the cation (ammonium cation, a conjugate acid of an amine) can be determined as measured by a conventional method. Alternatively, the pKa value can be estimated by calculation using a conventional software such as “ACD/Labs” (trade name; manufactured by Advanced Chemistry Development, Inc.).

A conjugate acid of an amine (second ammonium cation) can be determined by, for example, a simulation by using the software of the above (as one example, ACD/Labs, Software V11.02).

The conjugate acid of an amine (second ammonium cation) preferably has a greater pKa by 2 or more than that of the first ammonium cation, more preferably by 3 or more.

When the conjugate acid of an amine (second ammonium cation) preferably has a greater pKa by 2 or more than that of the first ammonium cation, a reaction between the first precursor polymer and an amine easily proceeds.

The specific pKa of a conjugate acid of an amine (second ammonium cation) is preferably 7.5 or greater, more preferably 8 to 20, and still more preferably 8.5 to 18.

When the pKa is greater than or equal to the preferable lower limit of the value, it is a relatively strong base, while the pKa is less than or equal to the preferable upper limit of the value, a stability of a polymer on a polymerization reaction or after a polymerization is more enhanced.

Examples of an amine that can be a second ammonium cation includes those represented by the following general formula (ca2-1), as well as cyclic amines such as cyclic amidines and cyclic tertiary alkylamine.

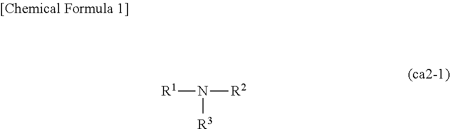

In the formula, R¹, R², and R³ each independently represent a hydrogen atom or an alkyl group of 1 to 15 carbon atoms, an aralkyl group, or a nitrogen-containing heterocyclic group, which may have a substituent.

Examples of the alkyl group for R¹, R², and R³ in the aforementioned formula (ca2-1) include a linear, branched, or cyclic alkyl group, and a linear or branched alkyl group is preferable. The alkyl group for R¹, R², and R³ has 1 to 15 carbon atoms, preferably has 1 to 5 carbon atoms. Specific examples of the alkyl group preferably include a methyl group, an ethyl group, a propyl group, an isopropyl group, an n-butyl group, an isobutyl group, a tert-butyl group, a pentyl group, an isopentyl group, and a neopentyl group, and among these, an ethyl group and an isopropyl group are more preferable.

The aralkyl group for R¹, R², and R³ is preferably a benzyl group or a naphthylmethyl group.

The nitrogen-containing heterocyclic group for R¹, R², and R³ may be an aromatic group or an aliphatic group. The nitrogen-containing heterocyclic group is preferably a 4- to 7-membered ring, and more preferably a 4- to 6-membered ring, and a pyridine cyclic group and a triazine cyclic group are included as examples.

Examples of a substituent which R¹, R², and R³ may have include an alkyl group, an alkoxy group, a hydroxyl group, an oxo group (═O), and an amino group. The alkyl group and the alkoxy group each preferably has 1 to 5 carbon atoms.

Specific examples of the amine represented by the above-described general formula (ca2-1) are shown below.

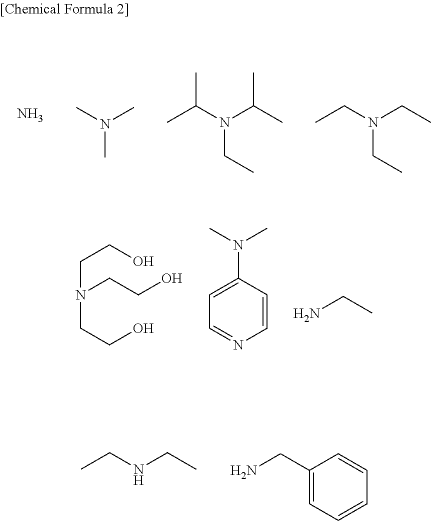

Specific examples of cyclic amines (cyclic amidines and cyclic tertiary alkylamines) are shown below.

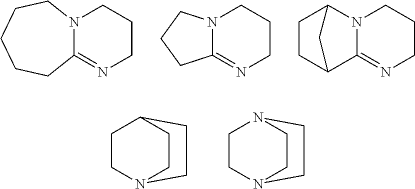

Note that the cyclic amines above may have substituents shown below.

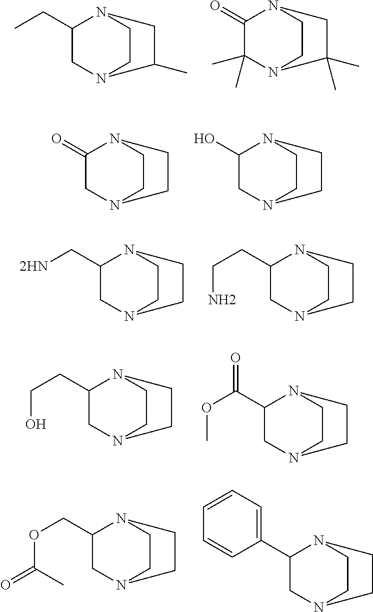

In addition, each conjugate acid in the specific examples of the amine and the retention time and the pKa of the each conjugate acid are shown below.

Note that the retention time shown with the chemical structure is the value measured under the specific conditions of the HPLC. Also, the pKa is a simulation result by using the ACD/Labs, Software V11.02 (trade name; manufactured by Advanced Chemistry Development, Inc.).

With respect to conjugate acids of amines which are not shown below, it is presumed that the retention times thereof are within 1 to 3 min (3.5 min, even in the longest case) because all of them have higher hydrophilicities. The pKa thereof are 7.5 or greater, since all of them are strong bases (the pKa of a conjugate acid of a triethanolamine is 7.7).

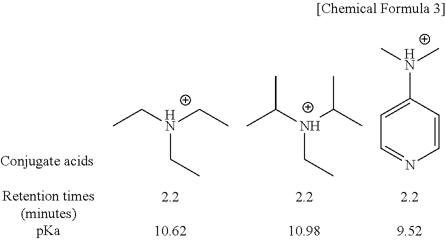

### (First Precursor Polymer)

The first precursor polymer has a first ammonium cation, as well as an anion group that generates an acid upon exposure.

### The First Ammonium Cation

The first ammonium cation has a pKa that is smaller than that of a conjugate acid of an amine (second ammonium cation) used in the amine reaction step, and the first ammonium cation is more hydrophobic than the conjugate acid of an amine.

A retention time of the first ammonium cation measured by HPLC under the specific conditions of the above is considered only when the first precursor polymer is obtained via a precursor polymer (a precursor of the first precursor polymer: a third precursor polymer).

Such a retention time of the first ammonium cation is preferably longer than a retention time of a cation (sulfonium cation and the like) in the third precursor polymer. Specifically, 3 minutes or longer is preferable, and 3.5 minutes or longer is more preferable. Although an upper limit value is not particularly limited, 60 minutes or less is preferable.

When the retention time is greater than or equal to the preferable lower limit of the value, a salt-exchange reaction between the third precursor polymer and a first ammonium cation easily proceeds. When the retention time becomes longer, it becomes more preferable.

Also, regarding a difference between retention times of a first ammonium cation and a cation (sulfonium cation and the like) in the third precursor polymer, a retention time of the first ammonium cation is preferably longer by 10 seconds or more, more preferably longer by 20 seconds or more than that of the cation (sulfonium cation and the like) in the third precursor polymer.

In a first ammonium cation, a pKa determined by, for example, a simulation by using the software of the above (as one example, ACD/Labs, Software V11.02) is preferably lower than that of a second ammonium cation. Specifically, the pKa is preferably less than 8, more preferably, 7.5 or less, but over 0, and still more preferably 1 to 7.

When the pKa is less than or equal to the preferable upper limit of the value, a reaction with an amine easily proceeds. On the other hand, when the pKa is greater than or equal to the preferable lower limit of the value, a stability of a polymer on a polymerization reaction or after a polymerization is more enhanced.

The first ammonium cation preferably has an electron-withdrawing group to lower the pKa of a conjugate acid, and to make a reaction with an amine easier. Specific and preferable examples are shown below.

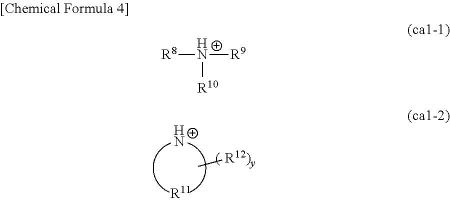

In the formula, R⁸ to R¹⁰ each independently represent a hydrogen atom or an alkyl group of 1 to 15 carbon atoms, a fluorinated alkyl group, or an aryl group, which may have a substituent, and at least one of them is a fluorinated alkyl group or an aryl group. R¹¹ represents a group which forms an aromatic ring with the nitrogen atom to which the R¹¹ is bonded, and R¹² represents an alkyl group of 1 to 15 carbon atoms or a halogen atom, and y represents an integer of 0 to 5.

Examples of the alkyl group for R⁸ to R¹⁰ in the aforementioned formula (ca1-1) include a linear, branched, or cyclic alkyl group, and a linear or branched alkyl group is preferable, and a linear alkyl group is more preferable. The alkyl group for R⁸ to R¹⁰ has 1 to 15 carbon atoms.

When the first precursor polymer is obtained via the third precursor polymer, the number of carbon atoms is preferably larger to enhance hydrophobicity; however, the industrially preferable number of carbon atoms is 1 to 5, and the specific examples preferably include a methyl group, an ethyl group, a propyl group, an isopropyl group, a n-butyl group, an isobutyl group, a tert-butyl group, a pentyl group, an isopentyl group, and a neopentyl group. When two of R⁸ to R¹⁰ are alkyl groups, these may be mutually bonded to form a ring.

An alkyl group of a fluorinated alkyl group in R⁸ to R¹⁰ is the same as defined above. The fluorination ratio is preferably 50% or more, and more preferably 75% or more.

The aryl group in R⁸ to R¹⁰ is preferably a phenyl group or a naphthyl group.

When at least one of R⁸ to R¹⁰ represents a fluorinated alkyl group or an aryl group, it tends to have weak basicity, and a reaction to generate the second precursor polymer proceeds easily.

Also, when the first precursor polymer is obtained via the third precursor polymer, at least one of R⁸ to R¹⁰ represents preferably an aryl group to enhance hydrophobicity (to make the retention time longer, and thereby the salt-exchange reaction between a cation of the third precursor polymer and the first ammonium cation is performed easily).

Among R⁸ to R¹⁰, when only R¹⁰ represents a fluorinated alkyl group or an aryl group, remaining R⁸ and R⁹ represent preferably a hydrogen atom or an alkyl group, and more preferably a hydrogen atom or a n-butyl group. In addition, still more preferably, R⁸ and R⁹ are identical.

In the aforementioned formula (ca1-2), R¹¹ represents a group which forms an aromatic ring with the nitrogen atom to which the R¹¹ is bonded. The aromatic ring is preferably a 4- to 7-membered ring, more preferably a 4- to 6-membered ring, and still more preferably a 6-membered ring.

R¹² represents an alkyl group of 1 to 15 carbon atoms, and preferable examples are the same as above. When the first precursor polymer is obtained via the third precursor polymer, the number of carbon atoms in R¹² is preferably larger to enhance hydrophobicity; however, in terms of industrial availability, a tert-butyl group is preferable.

The halogen atom in R¹² is preferably a fluorine atom.

y represents an integer of 0 to 5, preferably an integer of 0 to 2, and more preferably 2.

Specific examples of the first ammonium cation represented by each of the above-described general formula (ca1-1) and the general formula (ca1-2) are shown below.

Note that the retention time shown with the chemical structure is the value measured under the specific condition of the HPLC. A retention time is considered only when the first precursor polymer is obtained via the third precursor polymer. To make the retention time at least 3 min or more, preferably at least one of R⁸ to R¹⁰ in the formula (ca1-1) represents an aryl group, and remaining groups represent alkyl groups; and R¹² in the formula (ca1-2) represents an alkyl group, and y represents 1 or more.

The pKa is a simulation result by using the ACD/Labs, Software V11.02 (trade name; manufactured by Advanced Chemistry Development, Inc.).

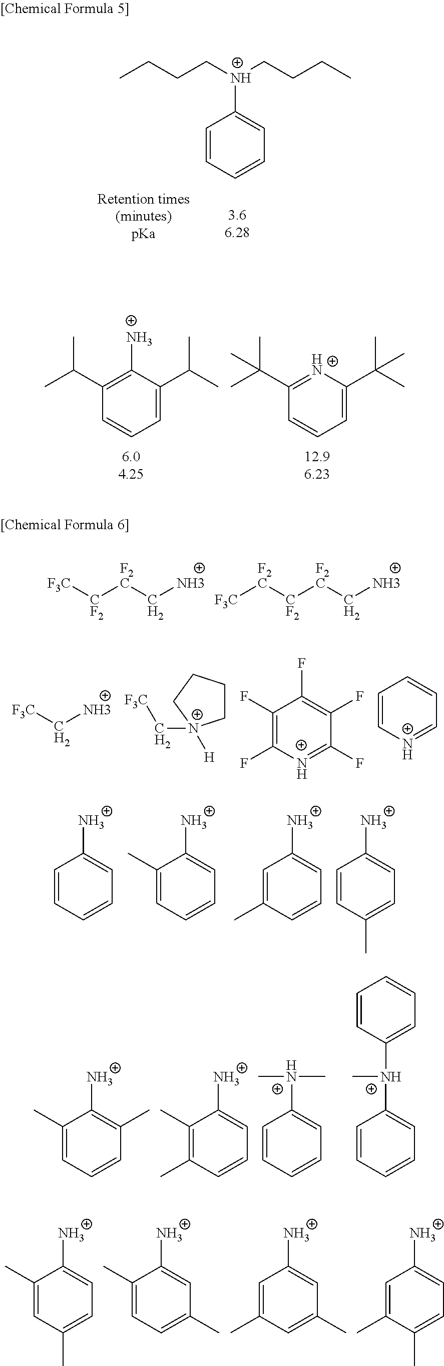

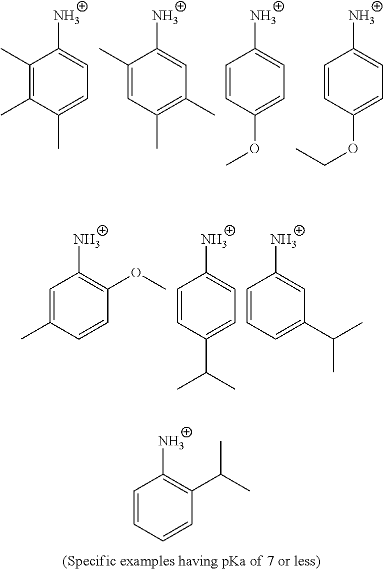

### Anion Group

Although an anion group that generates an acid upon exposure in the first precursor polymer is not particularly limited, preferably it is at least one group selected from the group consisting of a sulfonic acid anion, a carboxylic acid anion, a sulfonyl imide anion, bis(alkylsulfonyl)imide anion, and a tris(alkylsulfonyl)methide anion.

Of these, the anion group is preferably any group represented by each of the following formulae (an1) to (an4).

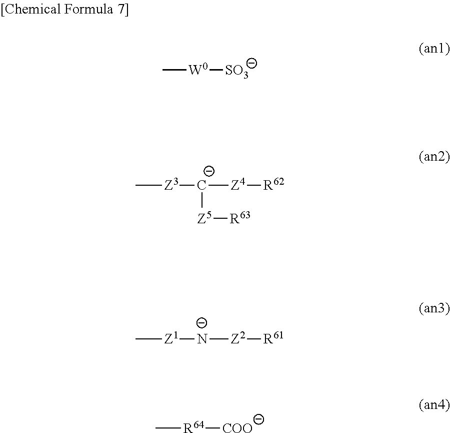

In the formula, W⁰ represents a hydrocarbon group of 1 to 30 carbon atoms, which may have a substituent. Z³ represents —C(═O)—O—, —SO₂—, or a hydrocarbon group that may have a substituent, Z⁴ and Z⁵ each independently represent —C(═O)— or —SO₂—. R⁶² and R⁶³ each independently represent a hydrocarbon group that may have a fluorine atom. Z¹ represents —C(═O)—, —SO₂—, —C(═O)—O—, or a single bond, Z² represents —C(═O)— or —SO₂—. R⁶¹ represents a hydrocarbon group that may have a fluorine atom. R⁶⁴ represents a hydrocarbon group that may have a fluorine atom.

In the formula (an1), W⁰ represents a hydrocarbon group of 1 to 30 carbon atoms, which may have a substituent.

A hydrocarbon group of 1 to 30 carbon atoms, which may have a substituent represented by W⁰ may be an aliphatic hydrocarbon group or an aromatic group.

An “aliphatic hydrocarbon group” refers to a hydrocarbon group that has no aromaticity. The aliphatic hydrocarbon group may be saturated or unsaturated. In general, the aliphatic hydrocarbon group is preferably saturated.

Specific examples of an aliphatic hydrocarbon group in W⁰ include a linear or branched aliphatic hydrocarbon group and an aliphatic hydrocarbon group containing a ring in the structure thereof.

The linear or branched aliphatic hydrocarbon group preferably has 1 to 10, more preferably 1 to 8, and still more preferably 1 to 5 carbon atoms.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent which substitutes for a hydrogen atom (a group or an atom other than a hydrogen atom). Examples of the substituent include a fluorine atom, a fluorinated alkyl group of 1 to 5 carbon atoms, which is substituted with a fluorine atom, and an oxo group (═O).

Examples of the aliphatic hydrocarbon group containing a ring in the structure thereof include a cyclic aliphatic hydrocarbon group that may contain a heteroatom-containing substituent in the ring structure (a group in which two hydrogen atoms have been removed from an aliphatic hydrocarbon ring); a group in which the cyclic aliphatic hydrocarbon group is bonded to the terminal of the linear or branched aliphatic hydrocarbon group; and a group in which the cyclic aliphatic hydrocarbon group is interposed within the linear or branched aliphatic hydrocarbon group. As examples of the linear or branched aliphatic hydrocarbon group, the same groups as those described above can be given.

The cyclic aliphatic hydrocarbon group (aliphatic cyclic group) preferably has 3 to 20 carbon atoms, and more preferably 3 to 12 carbon atoms.

The cyclic aliphatic hydrocarbon group may be either a polycyclic group or a monocyclic group. As the monocyclic aliphatic hydrocarbon group, a group in which two hydrogen atoms have been removed from a monocycloalkane is preferable. The monocycloalkane preferably has 3 to 6 carbon atoms, and specific examples thereof include cyclopentane and cyclohexane. As the polycyclic aliphatic hydrocarbon group, a group in which two hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The cyclic aliphatic hydrocarbon group may or may not have a substituent which substitutes for a hydrogen atom (a group or an atom other than a hydrogen atom). Examples of the substituent include an alkyl group, an alkoxy group, a halogen atom, a halogenated alkyl group, a hydroxyl group, and an oxo group (═O).

The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent for is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom as the substituent include a fluorine atom, a chlorine atom, a bromine atom and an iodine atom, and a fluorine atom is preferable.

An example of the halogenated alkyl group as the substituent includes a group in which part or all of the hydrogen atoms within the aforementioned alkyl group have been substituted with the aforementioned halogen atoms.

In the cyclic aliphatic hydrocarbon group, part of the carbon atoms constituting the ring structure may be substituted with a heteroatom-containing substituent. As the heteroatom-containing substituent, —O—, —C(═O)—O—, —S—, —S(═O)₂—, and —S(═O)₂—O— are preferable.

An aromatic group for W⁰ is a divalent hydrocarbon group having at least one aromatic ring, which may have a substituent.

An aromatic group for W⁰ is not particularly limited as long as it is a cyclic conjugated system having the (4n+2)π electrons, and it may be either a monocyclic group or a polycyclic group. The aromatic ring preferably has 5 to 30, more preferably 5 to 20, still more preferably 6 to 15, and most preferably 6 to 12 carbon atoms. Here, the number of carbon atoms within a substituent(s) is not included in the number of carbon atoms of the aromatic hydrocarbon group. Specific examples of the aromatic ring include an aromatic hydrocarbon ring such as benzene, naphthalene, anthracene, and phenanthrene; and an aromatic hetero ring in which part of the carbon atoms constituting the aromatic hydrocarbon ring has been substituted with a heteroatom. Examples of the hetero atom within the aromatic hetero rings include an oxygen atom, a sulfur atom and a nitrogen atom. Specific examples of the aromatic hetero rings include a pyridine ring and a thiophene ring.

Specific examples of the aromatic group for W⁰ include a group (arylene group or hetero arylene group) which is the aromatic hydrocarbon ring or the aromatic hetero ring having two hydrogen atoms removed therefrom; a group which is an aromatic compound containing two or more aromatic rings (for example, biphenyl and florene) having two hydrogen atoms removed therefrom; and a group (for example, a group in which one hydrogen atom of the aryl group of an arylalkyl group such as a benzyl group, a phenethyl group, a 1-naphthylmethyl group, a 2-naphthylmethyl group, a 1-naphthylethyl group or a 2-naphthylethyl group further has been removed) in which one hydrogen atom of a group (aryl group or heteroaryl group) which is the aromatic hydrocarbon ring or the aromatic hetero ring having one hydrogen atom removed therefrom has been substituted with an alkylene group. The alkylene group bonded to the aryl group or the heteroaryl group preferably has 1 to 4 carbon atoms, more preferably 1 or 2, and most preferably 1.

The aromatic group may or may not have a substituent. For example, a hydrogen atom bonded to the aromatic ring within the aromatic group may be substituted with a substituent. As the substituent, an alkyl group, an alkoxy group, a halogen atom, a halogenated alkyl group, a hydroxyl group, an oxo group (═O) or the like can be used.

The alkyl group, alkoxy group, halogen atom, and halogenated alkyl group as the substituent are the same as the alkyl group, alkoxy group, halogen atom, and halogenated alkyl group as the substituent for the cyclic aliphatic hydrocarbon group.

Of these, the group represented by the following formula (an1-1) is preferable.

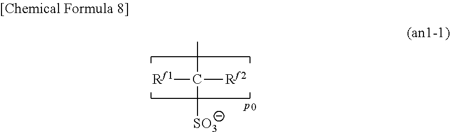

In the formula, R^{f1} and R^{f2} each independently represent a hydrogen atom, an alkyl group, a fluorine atom, or a fluorinated alkyl group, and at least one of R^{f1} and R^{f2} represents a fluorine atom or a fluorinated alkyl group, and p0 represents an integer of 1 to 8.

R^{f1} and R^{f2} each independently represent a hydrogen atom, an alkyl group, a fluorine atom, or a fluorinated alkyl group, and at least one of R^{f1} and R^{f2} represents a fluorine atom or a fluorinated alkyl group.

The alkyl group for R^{f1} and R^{f2} is preferably an alkyl group of 1 to 5 carbon atoms, and specific examples include a methyl group, an ethyl group, a propyl group, an isopropyl group, an n-butyl group, an isobutyl group, a tert-butyl group, a pentyl group, an isopentyl group, and a neopentyl group.

The fluorinated alkyl group for R^{f1} and R^{f2} is preferably a group in which part or all of the hydrogen atoms of an alkyl group in the R^{f1} and R¹² is substituted with a fluorine atom.

R^{f1} and R^{f2} are preferably a fluorine atom or a fluorinated alkyl group.

In the formula (an1-1), p0 represents an integer of 1 to 8, preferably an integer of 1 to 4, and more preferably 1 or 2.

In addition to the example represented by the formula (an1-1), other preferable examples of the hydrocarbon group in W⁰, which may have a substituent include an aliphatic cyclic group or an aromatic group, which may have a substituent, and a group in which 2 or more hydrogen atoms have been removed from adamantane, norbornane, isobornane, tricyclodecane, tetracyclododecane, camphor, benzene or the like (the group may have a substituent) is more preferable.

In the formula (an2), Z³ represents —C(═O)—O—, —SO₂—, or a hydrocarbon group that may have a substituent. Examples of the hydrocarbon group that may have a substituent represented by Z³ are the same as the hydrocarbon group of 1 to 30 carbon atoms, which may have a substituent, represented by W⁰. Of these, —SO₂— is preferable for Z³.

In the formula (an2), Z⁴ and Z⁵ each independently represent —C(═O)— or —SO₂—, and preferably at least one of them represents —SO₂—, and more preferably both of them represents —SO₂—.

R⁶² and R⁶³ each independently represent a hydrocarbon group that may have a fluorine atom, and examples are the same as the hydrocarbon group that may have a fluorine atom represented by R⁶¹, which will be described later.

In the formula (an3), Z¹ represents —C(═O)—, —SO₂—, —C(═O)—O—, or a single bond. When Z¹ represents a single bond, N⁻ in the formula is preferably not bonded directly to —C(═O)— at the side (that is, the left side in the formula), which is opposite to the side bonded to Z².

In the formula (an3), Z² represents —C(═O)— or —SO₂—, and preferably represents —SO₂—.

R⁶¹ represents a hydrocarbon group that may have a fluorine atom. Examples of the hydrocarbon group represented by R⁶¹ include an alkyl group, a monovalent alicyclic hydrocarbon group, an aryl group, and an aralkyl group.

An alkyl group represented by R⁶¹ preferably has 1 to 8 carbon atoms, more preferably 1 to 6 carbon atoms, and still more preferably 1 to 4 carbon atoms; and may be either linear or branched. Specific preferable examples include a methyl group, an ethyl group, a propyl group, a butyl group, a hexyl group, and an octyl group.

A monovalent alicyclic hydrocarbon group represented by R⁶¹ preferably has 3 to 20 carbon atoms, and more preferably 3 to 12 carbon atoms; and may be either a polycyclic group or a monocyclic group. As the monocyclic alicyclic hydrocarbon group, a group in which one or more hydrogen atoms have been removed from a monocycloalkane is preferable. The monocycloalkane preferably has 3 to 6 carbon atoms, and specific examples thereof include cyclo butane, cyclopentane, and cyclohexane. As the polycyclic group, a group in which one or more hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

An aryl group represented by R⁶¹ preferably has 6 to 18 carbon atoms, and more preferably 6 to 10 carbon atoms; and specifically a phenyl group is most preferable.

A preferable example of an aralkyl group represented by R⁶¹ is the group in which an alkylene group of 1 to 8 carbon atoms is bonded to the “aryl group represented by R⁶¹” of the above. An aralkyl group in which an alkylene group of 1 to 6 carbon atoms is bonded to the “aryl group represented by R⁶¹” of the above is more preferable, and an aralkyl group in which an alkylene group of 1 to 4 carbon atoms is bonded to the “aryl group represented by R⁶¹” of the above is most preferable.

In a hydrocarbon group represented by R⁶¹, preferably part or all of the hydrogen atoms of the hydrocarbon group are substituted with a fluorine atom, and more preferably 30 to 100% of the hydrogen atoms of the hydrocarbon group are substituted with a fluorine atom. Of these, a perfluoroalkyl group, in which all of the hydrogen atoms of the above-described alkyl group are substituted with a fluorine atom, is most preferable.

In the formula (an4), R⁶⁴ represents a hydrocarbon group that may have a fluorine atom. Examples of a hydrocarbon group represented by R⁶⁴ include an alkylene group, a divalent alicyclic hydrocarbon group, a group in which one or more hydrogen atoms have been removed from an aryl group, and a group in which one or more hydrogen atoms have been removed from an aralkyl group.

A specific example of a hydrocarbon group represented by R⁶⁴ is a group in which one or more hydrogen atoms have been removed from a hydrocarbon group (alkyl group, a monovalent alicyclic hydrocarbon group, an aryl group, an aralkyl group or the like) as described above for R⁶¹.

In a hydrocarbon group represented by R⁶⁴, preferably part or all of the hydrogen atoms of the hydrocarbon group is substituted with a fluorine atom, and more preferably 30 to 100% of the hydrogen atoms of the hydrocarbon group is substituted with a fluorine atom.

Among those described above, for example, when an anion group is a group within the groups represented by the formula (an1), which has a fluorine atom (in particular, a group represented by the formula (an1-1)); or when an anion group has a group represented by the formula (an2) or a group represented by the formula (an3) in which Z¹ and Z² represents —SO₂—; the anion group generates a relatively strong acid such as a fluorinated alkylsulfonic acid anion, a carbanion, a sulfonyl imide anion or the like upon exposure.

On the other hand, when an anion group is a group within the groups represented by the formula (an1), which does not have any fluorine atoms; or when an anion group has a group represented by the formula (an4) or a group represented by the formula (an3) in which Z¹ and Z² represents —C(═O)—; the anion group generates a relatively weak acid such as an alkylsulfonic acid anion, an arylsulfonic acid anion, a carboxylic acid anion, an imide anion or the like upon exposure.

As described above, an acid having a desired acid strength can be generated depending on the type of anion group, and thus the anion group can be appropriately selected depending on demand characteristics and the like of a resist composition in which a polymeric compound produced by the present invention is used. For example, when the anion group plays the same role to an acid generator that usually used in a resist composition, an anion group that generates a strong acid is preferably selected.

Also, for example, when the anion group plays the same role to a quencher (a quencher which traps a strong acid by performing a salt-exchange with the strong acid generated from an acid generator) that usually used in a resist composition, an anion group that generates a weak acid is preferably selected.

Note that the strong acid and weak acid used herein are determined by the relationship with the activation energy of an acid decomposable group as contained in the structural unit (a1) described later, which is decomposed by the action of acid; and by the relationship with the acid strength of an acid generator used together. Accordingly, the above-described “relatively weak acid” cannot necessarily be used as a quencher.

The first precursor polymer preferably has a structural unit containing the first ammonium cation and the anion group that generates an acid upon exposure.

The structural unit can be introduced into a polymeric compound by a method in which the structural unit is derived from a monomer (hereinafter, the monomer is referred to as “monomer (G)”) having the first ammonium cation and the anion group that generates an acid upon exposure, or by a method in which a salt-exchange is used, such as “a step for obtaining the first precursor polymer,” which will be described later.

Here, a “structural unit derived from a monomer” refers to a monomer unit of a single bond that is formed by the cleavage of the ethylenic double bond of a monomer.

The first precursor polymer may contain other structural units in addition to the “structural unit containing the first ammonium cation and the anion group that generates an acid upon exposure,” if required.

Other structural units are not limited as long as those can constitute the first precursor polymer together with the “structural unit containing the first ammonium cation and the anion group that generates an acid upon exposure,” and among those, a structural unit containing an acid decomposable group whose polarity is increased by the action of acid (the structural unit (a1), which will be described later) is most preferable.

Examples of other structural units also include the structural units (a2), (a3), and (a4), which will be described later.

### (Monomer (G))

Examples of the monomer (G) include the above-described anion group bonded to a polymerizable group either via a linking group or not via a linking group (i.e., directly).

Examples of the polymerizable group include a vinyl group, an allyl group, an acryloyl group, a methacryloyl group, a fluorovinyl group, a difluorovinyl group, a trifluorovinyl group, a difluorotrifluoromethylvinyl group, a trifluoroallyl group, a perfluoroallyl group, a trifluoromethylacryloyl group, a nonylfluorobutylacryloyl group, a vinyl ether group, a fluorine-containing vinyl ether group, an allyl ether group, a fluorine-containing allyl ether group, a styryl group, a fluorine-containing styryl group, a norbornyl group, a fluorine-containing norbornyl group, and a silyl group.

An example of a preferable monomer (G) is a compound represented by the following general formula (1).

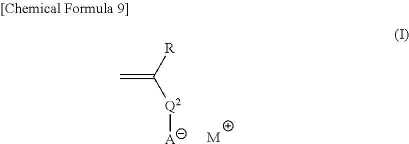

In the formula, R represents a hydrogen atom, an alkyl group of 1 to 5 carbon atoms, or a halogenated alkyl group of 1 to 5 carbon atoms; Q² represents a single bond or a divalent linking group; A⁻ represents an anion group; and M⁺ represents a first ammonium cation.

R represents a hydrogen atom, an alkyl group of 1 to 5 carbon atoms, or a halogenated alkyl group of 1 to 5 carbon atoms.

The alkyl group of 1 to 5 carbon atoms for R is preferably a linear or branched alkyl group, and specific examples include a methyl group, an ethyl group, a propyl group, an isopropyl group, an n-butyl group, an isobutyl group, a tert-butyl group, a pentyl group, an isopentyl group, and a neopentyl group.

An example of the halogenated alkyl group of 1 to 5 carbon atoms for R is a group in which part or all of the hydrogen atoms within the aforementioned “alkyl group of 1 to 5 carbon atoms for R” have been substituted with halogen atoms. Examples of the halogen atom include a fluorine atom, a chlorine atom, a bromine atom and an iodine atom, and a fluorine atom is particularly desirable.

Of these, R preferably represents a hydrogen atom, an alkyl group of 1 to 5 carbon atoms, or a fluorinated alkyl group of 1 to 5 carbon atoms, and a hydrogen atom or a methyl group is most preferable for industrial availability.

In the formula, although a divalent linking group represented by Q² is not particularly limited, preferable examples include a divalent hydrocarbon group that may have a substituent and a divalent linking group that may contain a heteroatom.

A hydrocarbon “has a substituent” means that part or all of the hydrogen atoms within the hydrocarbon group is substituted with a substituent (a group or an atom other than hydrogen).

The hydrocarbon group represented by Q² may be an aliphatic hydrocarbon group, or may be an aromatic group. Examples of the aliphatic hydrocarbon group or the aromatic group for Q² include the same as those described above for the aliphatic hydrocarbon group or the aromatic group for W⁰.

The heteroatom in the above-described “divalent linking group that may contain a heteroatom” represented by Q² is an atom other than a carbon atom or a hydrogen atom, and examples include an oxygen atom, a nitrogen atom, a sulfur atom, and a halogen atom.

Examples of the divalent linking group containing a heteroatom include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O—, —NH—C(═O)—, ═N—; and a group represented by the general formula —Y²¹—O—Y²²—, —Y²¹—C(═O)—O—, —Y²¹—O—C(═O)—, —[(Y²¹—C(═O)—O]_{m′}—Y²²—, —Y²¹—O—C(═O)—Y²²—, —Y²¹—O—Y²²—O—C(═O)—, —Y²¹—O—S(═O)₂—, —Y²¹—S(═O)₂—Y²²—O—S(═O)₂—, —Y²¹—S—Y²²—O—S(═O)₂—Y²³—, or —Y²¹—O—C(═O)—Y²²—O—S(═O)₂—Y²³— [In the formula, Y²¹, Y²², and Y²³ each independently represent a divalent hydrocarbon group that may have a substituent, O represents an oxygen atom, C represents a carbon atom, S represents a sulfur atom, and m′ represents an integer of 0 to 3].

When Q² represents —NH—, the H may be substituted with a substituent such as an alkyl group or an acyl group.

The Y²¹ and Y²² each independently represent a divalent hydrocarbon group that may have a substituent. Examples of the divalent hydrocarbon group include the same as those described above for the “divalent hydrocarbon group that may have a substituent” (the aliphatic hydrocarbon group or the aromatic group for W⁰).

For Y²¹, an aliphatic hydrocarbon group or an aromatic hydrocarbon group, which may have a substituent is preferable, a linear or cyclic alkylene group is more preferable, a linear alkylene group of 1 to 5 carbon atoms is still more preferable, and a methylene group or an ethylene group is most preferable.

For Y²², an aliphatic hydrocarbon group or an aromatic hydrocarbon group, which may have a substituent is preferable, and a methylene group, an ethylene group, an alkylmethylene group, a (poly)cycloalkylene group, a phenylene group, or a naphthylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

For Y²³, substituent a linear or branched aliphatic hydrocarbon group that may have a substituent is preferable, and a linear or branched alkylene group that may have a substituent is more preferable.

In the group represented by the formula —[Y²¹—C(═O)—O]_{m′}—Y²²—, m′ represents an integer of 0 to 3, preferably an integer of 0 to 2, more preferably 0 or 1, and most preferably 1. Namely, it is particularly desirable that the group represented by the formula —[Y²¹—C(═O)—O]_{m′}—Y²²— is a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

As the divalent linking group containing a heteroatom, a linear group containing an oxygen atom as the heteroatom e.g., a group containing an ether bond or an ester bond is preferable, and a group represented by the aforementioned formula —Y²¹—C(═O)—O—, —Y²¹—O—C(═O)—, —Y²¹—O—Y²²—, —[Y²¹—C(═O)—O]_{m′}—Y²²—, or —Y²¹—O—C(═O)—Y²²— is more preferable.

Among the above-mentioned examples, in particular, a linear or branched alkylene group, a divalent alicyclic hydrocarbon group, or a divalent linking group containing a heteroatom are preferable as the divalent linking group represented by Q². Among these, a linear or branched alkylene group, or a divalent linking group containing a heteroatom are more preferable.

In the formula, an anion group represented by A⁻ is the same as defined above, and each group represented by each of the aforementioned formulae (an1) to (an4) is preferable.

In the formula, M⁺ represents a first ammonium cation that is same as the above-described first ammonium cation.

As a monomer containing an anion group, at least one monomer selected from the group consisting of the each compound represented by each of the following formulae (an11) to (an14), (an21) to (an25), (an31) to (an32), and (an41) to (an44) is preferable.

Among the compounds represented by the following formulae (an11) to (an14), each compound represented by each of the following formulae (an11-1) to (an13-1) is preferable.

In the following formulae, each M⁺ represents a first ammonium cation.

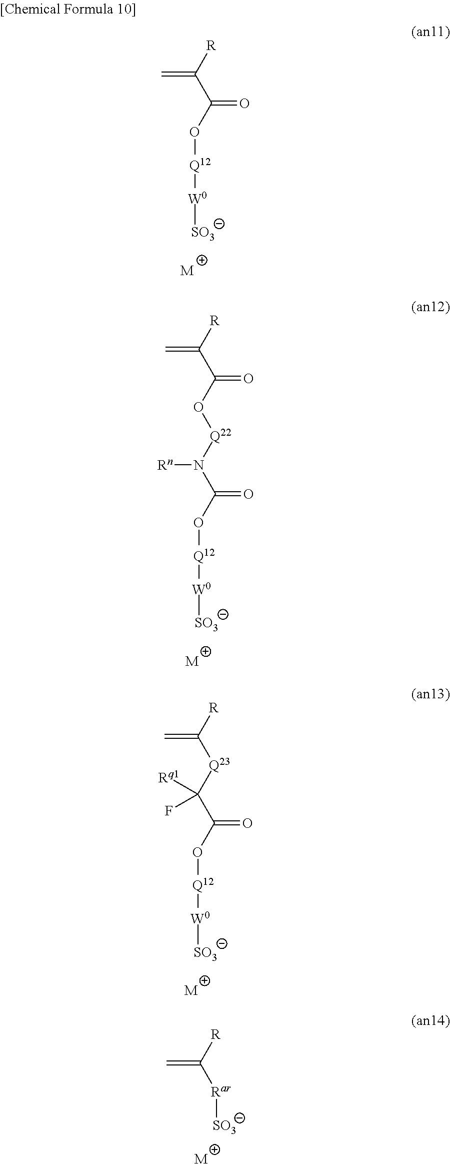

In the formula, R and W⁰ are the same as defined above. Q²¹ represents a single bond or a divalent linking group. Q²² represents a divalent linking group. Q²³ represents a group containing —O—, —CH₂—O—, or —C(═O)—O—. R^{q1} represents a fluorine atom or a fluorinated alkyl group. R^{ar} represents a divalent aromatic group that may have a substituent. Rⁿ represents a hydrogen atom or an alkyl group of 1 to 5 carbon atoms. M⁺ represents a first ammonium cation.

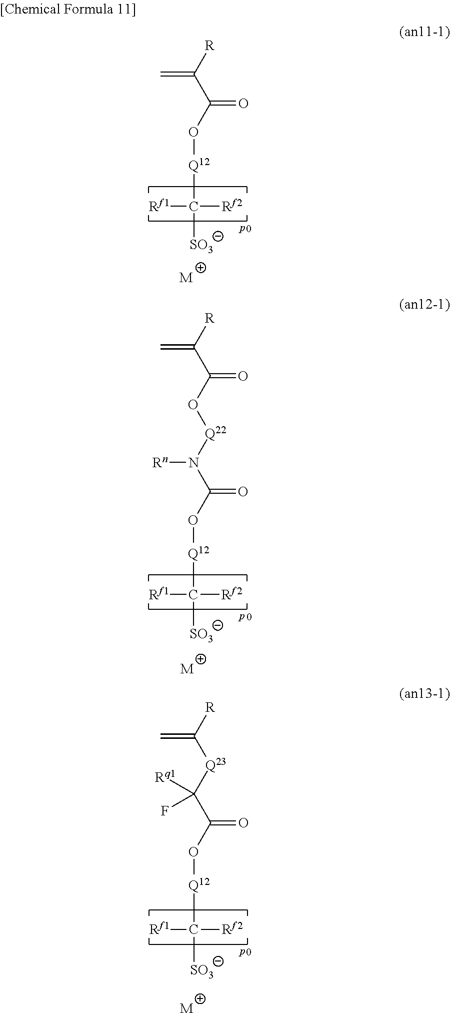

In the formula, R, R^{f1}, R^{f2}, and p0 are the same as defined above. Rⁿ represents a hydrogen atom or an alkyl group of 1 to 5 carbon atoms. Q²¹ represents a single bond or a divalent linking group. Q²² represents a divalent linking group. Q²³ represents a group containing —O—, —CH₂—O—, or —C(═O)—O—. R^{q1} represents a fluorine atom or a fluorinated alkyl group. M⁺ represents a first ammonium cation.

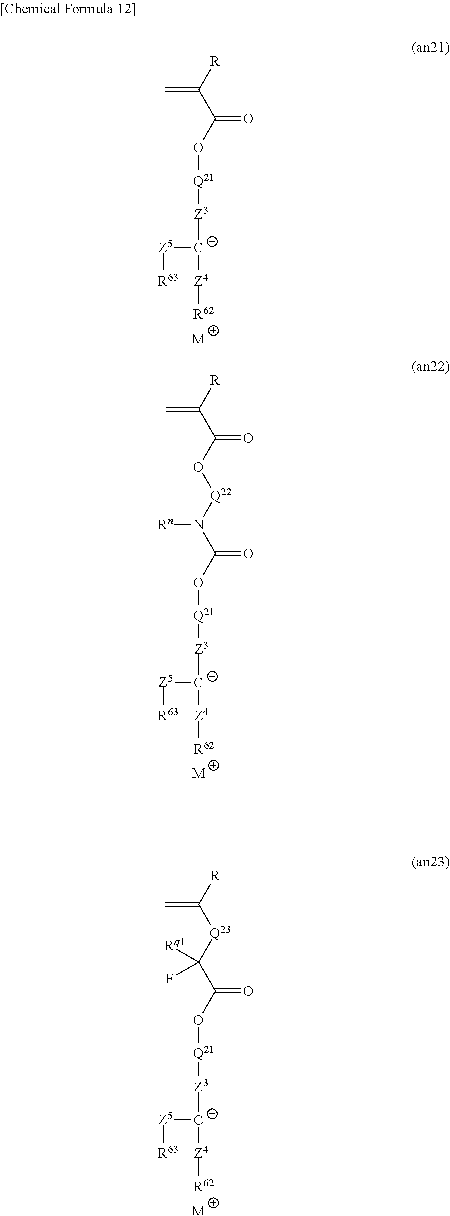

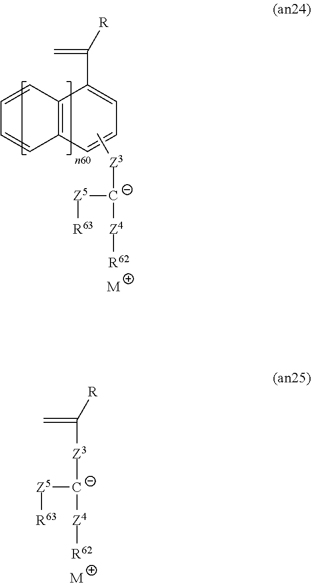

In the formula, R, Q²¹ to Q²³, Z³ to Z⁵, R⁶² to R⁶³, Rⁿ, and R^{q1} are the same as defined above. n60 represents an integer of 0 to 3. M⁺ represents a first ammonium cation.

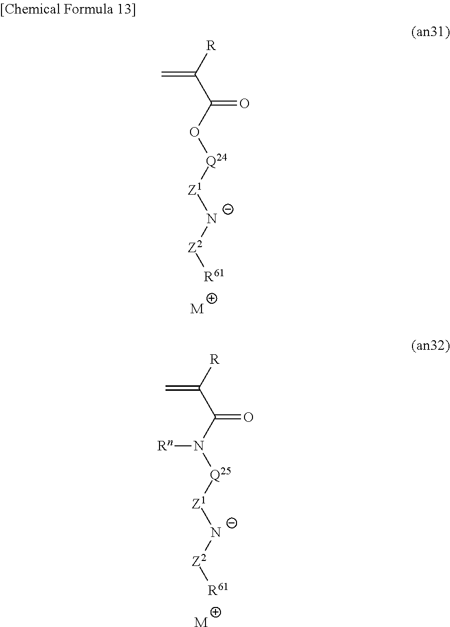

In the formula, R, Z¹ and Z², and Rⁿ are the same as defined above. Q²⁴ and Q²⁵ each independently represent a single bond or a divalent linking group. M⁺ represents a first ammonium cation.

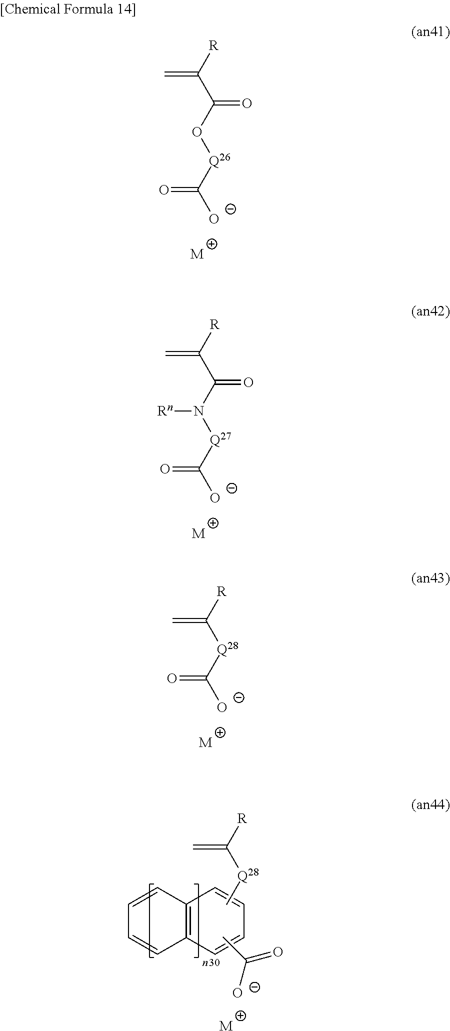

In the formula, R and Rⁿ are the same as defined above. Q²⁶ to Q²⁸ each independently represent a single bond or a divalent linking group. n30 represents an integer of 0 to 3. M⁺ represents a first ammonium cation.

In the formula (an11) to (an14), W⁰ and R^{q1} are the same as defined above.

R^{ar} represents a divalent aromatic group that may have a substituent. Examples of the divalent aromatic group include a group that is the same as the aromatic group, which is described as a divalent hydrocarbon group in the explanation for the divalent linking group represented by W⁰ of the general formula (an1). Of these, a phenylene group that may have a substituent, or a naphthylene group that may have a substituent is preferable.

Q²¹ represents a single bond or a divalent linking group. Examples of a divalent linking group represented by Q²¹ include the divalent linking group that is the same as those represented by Q². Of these, a linear or branched alkylene group, a cyclic aliphatic hydrocarbon group, an aromatic hydrocarbon group, or a divalent linking group containing a heteroatom are preferable for Q²¹; a linear or branched alkylene group, a combination of a linear or branched alkylene group and a divalent linking group containing a heteroatom, a combination of a cyclic aliphatic hydrocarbon group and a divalent linking group containing a heteroatom, and a combination of an aromatic hydrocarbon group and a divalent linking group containing a heteroatom are more preferable; a linear or branched alkylene group, a combination of a linear or branched alkylene group and an ester bond [—C(═O)—O—], and a combination of a divalent alicyclic hydrocarbon group and an ester bond [—C(═O)—O—] are still more preferable; and a linear or branched alkylene group, or a combination of a linear or branched alkylene group and an ester bond [—C(═O)—O—] is most preferable.

In the formula (an12), Q²² represents a divalent linking group, and examples include the divalent linking group that is the same as those represented by Q². Of these, a linear or branched alkylene group, a cyclic aliphatic hydrocarbon group, or a divalent aromatic hydrocarbon group as those described above for W⁰ are preferable, a linear alkylene group is more preferable, and a methylene group or an ethylene group is most preferable.

In the formula (an12), Rⁿ represents a hydrogen atom or an alkyl group of 1 to 5 carbon atoms. Examples of an alkyl group of 1 to 5 carbon atoms include the alkyl group of 1 to 5 carbon atoms that is the same as those represented by R. Of these, a hydrogen atom or a methyl group is preferable for Rⁿ.

In the formula (an13), Q²³ represents a group containing —O—, —CH₂—O—, or —C(═O)—O—.

Specific examples of Q²³ include the group consisting of —O—, —CH₂—O—, or —C(═O)—O—; and the group composed of —O—, —CH₂—O—, or —C(═O)—O—, and a divalent hydrocarbon group that may have a substituent.

Examples of the divalent hydrocarbon group that may have a substituent include the same groups as the divalent hydrocarbon groups that may have a substituent described above for the aforementioned divalent linking group for Q².

Q²³ represents preferably the group consisting of —C(═O)—O— and a divalent hydrocarbon group that may have a substituent, more preferably the group consisting of —C(═O)—O— and an aliphatic hydrocarbon group, and still more preferably the group consisting of —C(═O)—O— and a linear or branched alkylene group.

Specifically, a group represented by the general formula Q²-1) is most preferable for Q²³.

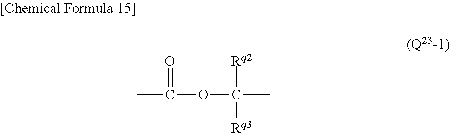

In the formula (Q²³-1), R^{q2} and R^{q3} each independently represent a hydrogen atom, an alkyl group, or a fluorinated alkyl group, and may be mutually bonded to form a ring.

In the formula (Q²³-1), an alkyl group represented by R^{q2} and R^{q3} can be linear, branched, or cyclic, and linear or branched is preferable.

A linear or branched alkyl group preferably has 1 to 5 carbon atoms and is preferably an ethyl group or a methyl group, and most preferably an ethyl group.

A cyclic alkyl group preferably has 4 to 15 carbon atoms, more preferably has 4 to 12 carbon atoms, and most preferably has 5 to 10 carbon atoms. Specific examples include each of groups in which one or more hydrogen atoms have been removed from a monocycloalkane; or a polycycloalkane such as bicycloalkane, tricycloalkane, and tetracycloalkane. More specific examples include each of groups in which one or more hydrogen atoms have been removed from a monocycloalkane such as cyclopentane and cyclohexane, or a polycycloalkane such as adamantane, norbornane, isobornane, tricyclodecane, and tetracyclododecane. Of these, a group in which one or more hydrogen atoms have been removed from adamantane is desirable.

The fluorinated alkyl group for R^{q2} and R^{q3}, is an alkyl group in which part or all of the hydrogen atoms have been substituted with fluorine atoms.

In the fluorinated alkyl group, an alkyl group without any fluorine atoms as a substituent can be linear, branched, or cyclic, and examples include those same as the “alkyl group represented by R^{q2} and R^{q3}.”

R^{q2} and R^{q3}, may be mutually bonded to form a ring, and examples of a ring constituted by R^{q2}, R^{q3}, and carbon atoms to which R^{q2} and R^{q3} are bonded include a ring in which two hydrogen atoms have been removed from a monocycloalkane or a polycycloalkane of the cyclic alkyl group, and the ring is preferably a 4- to 10-membered ring, and more preferably a 5- to 7-membered ring.

Among these, R^{q2} and R^{q3} represent preferably hydrogen atoms or alkyl groups.

In the formula (an13), R^{q1} represents a fluorine atom or a fluorinated alkyl group.

In the fluorinated alkyl group represented by R^{q1}, an alkyl group without any fluorine atoms as a substituent can be linear, branched, or cyclic.

A linear or branched alkyl group preferably has 1 to 5 carbon atoms, more preferably has 1 to 3 carbon atoms, and most preferably has 1 or 2 carbon atoms.

A cyclic alkyl group preferably has 4 to 15 carbon atoms, more preferably has 4 to 12 carbon atoms, and still more preferably has 5 to 10 carbon atoms. Specific examples include each of groups in which one or more hydrogen atoms have been removed from a monocycloalkane; or a polycycloalkane such as bicycloalkane, tricycloalkane, and tetracycloalkane. More specific examples include each of groups in which one or more hydrogen atoms have been removed from a monocycloalkane such as cyclopentane and cyclohexane; or a polycycloalkane such as adamantane, norbornane, isobornane, tricyclodecane, and tetracyclododecane.

In the fluorinated alkyl group, the percentage of the number of fluorine atoms based on the total number of fluorine atoms and hydrogen atoms (fluorination ratio (%)) is preferably 30 to 100%, and more preferably 50 to 100%. A higher fluorination ratio increases the hydrophobicity of a resist film.

Among these, R^{q1} represent preferably a fluorine atom.

In the formulae (an11-1) to (an13-1), those represented by R, Q²¹ to Q²³, R^{f1}, R^{f2}, p0, and Rⁿ are the same as those described above.

In the formulae (an21) to (an25), R, Q²¹ to Q²³, Z³ to Z⁵, R⁶² and R⁶³, Rⁿ, and R^{q1} are the same as those described above.

In the formula (an24), n60 represents an integer of 0 to 3, and either 0 or 1 is preferable.

In the formulae (an31) to (an32), R, Z¹ and Z², and Rⁿ are the same as those described above, and Q²⁴ and Q²⁵ each independently represent a single bond or a divalent linking group.

Examples of a divalent linking group represented by Q²⁴ and Q²⁵ include a divalent linking group that is the same as those represented by Q². As described above, when Z¹ is a single bond, the terminals of Q²⁴ and Q²⁵ bonded to Z¹ are preferably not —C(═O)—. As a divalent linking group represented by Q²⁴ and Q²⁵, a linear or branched alkylene group, a cyclic aliphatic hydrocarbon group, or a divalent linking group containing a heteroatom are particularly desirable. Of these, a linear or branched alkylene group and a cyclic aliphatic hydrocarbon group are preferable, and a linear alkylene group and a cyclic aliphatic hydrocarbon group are more preferable.

In the formulae (an41) to (an44), R and Rⁿ are the same as those described above, Q²⁶ to t Q²⁸ each independently represent a single bond or a divalent linking group. Q²⁶ to Q²⁸ are the same as the above-described Q²⁴ and Q²⁵.

In the formula (an44), n30 represents an integer of 0 to 3, and either 0 or 1 is preferable.

Specific examples of the monomer (G) are shown below. In each of the following formulae, R^{α} represents a hydrogen atom, a methyl group, or a trifluoromethyl group, and M⁺ (first ammonium cation) are the same as those described above.

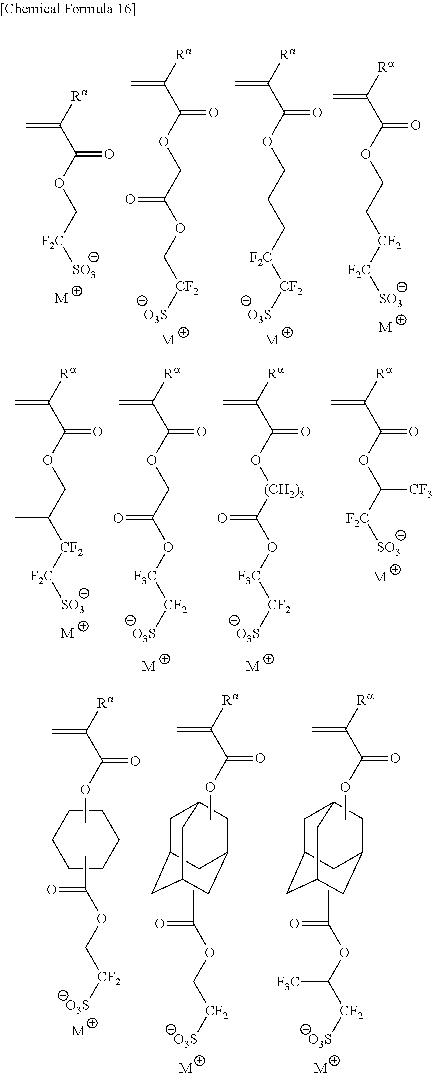

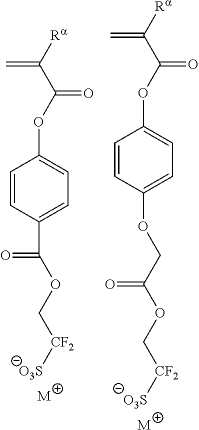

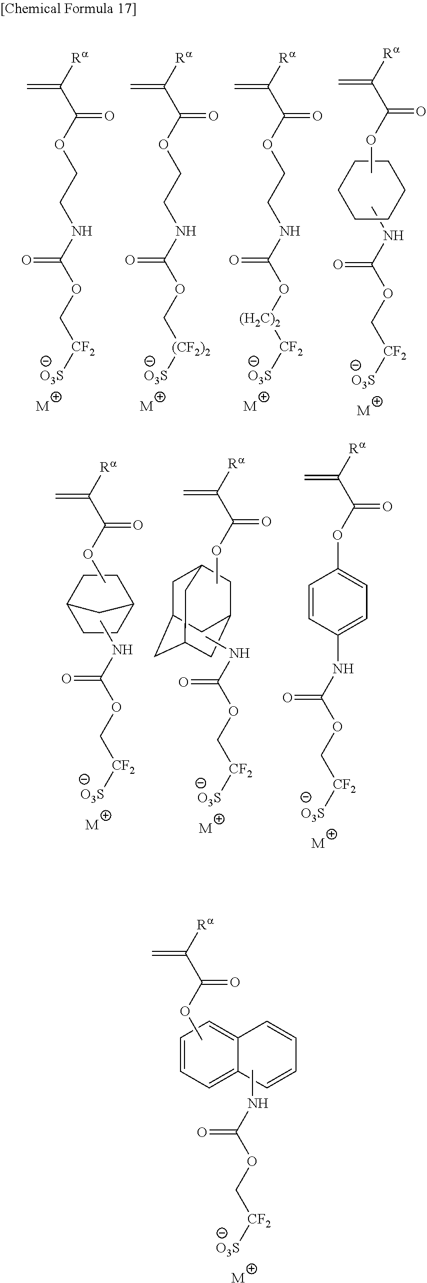

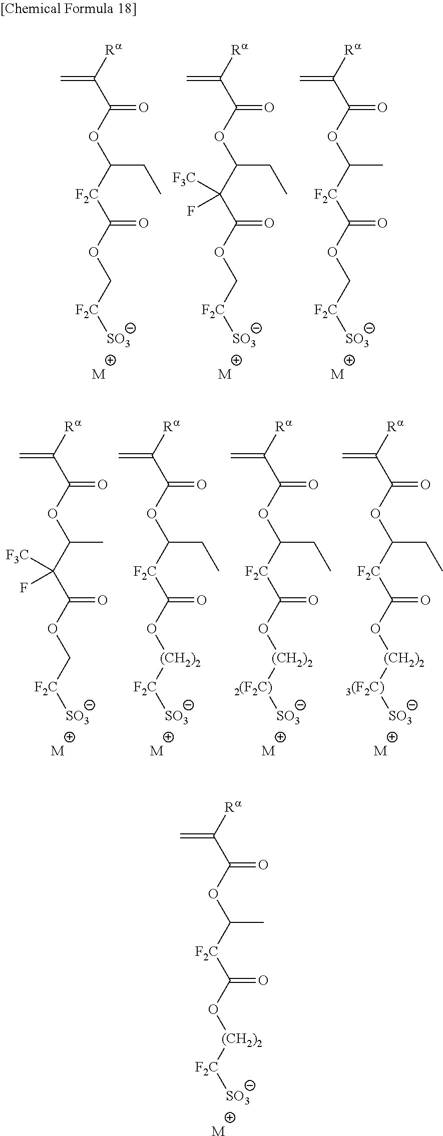

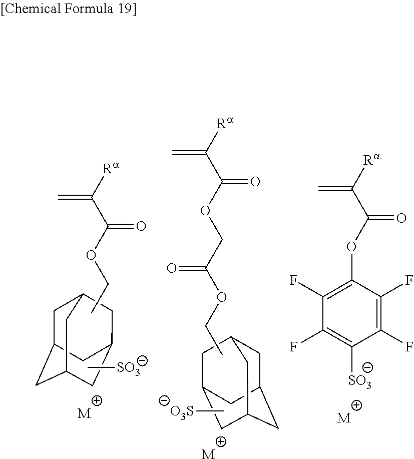

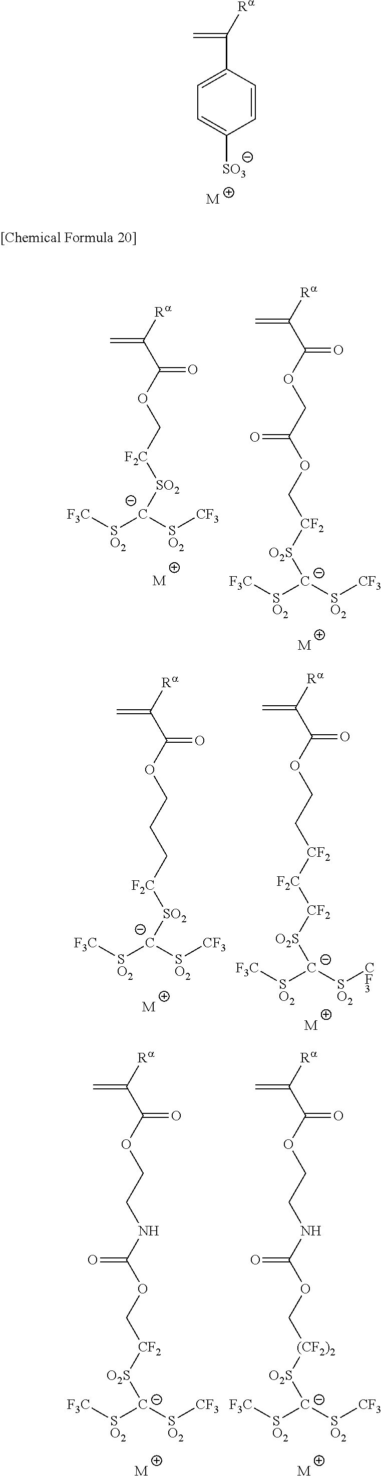

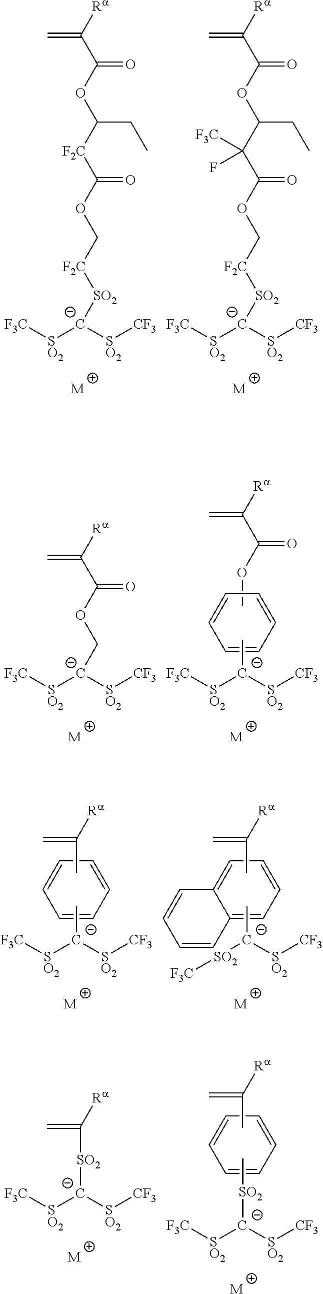

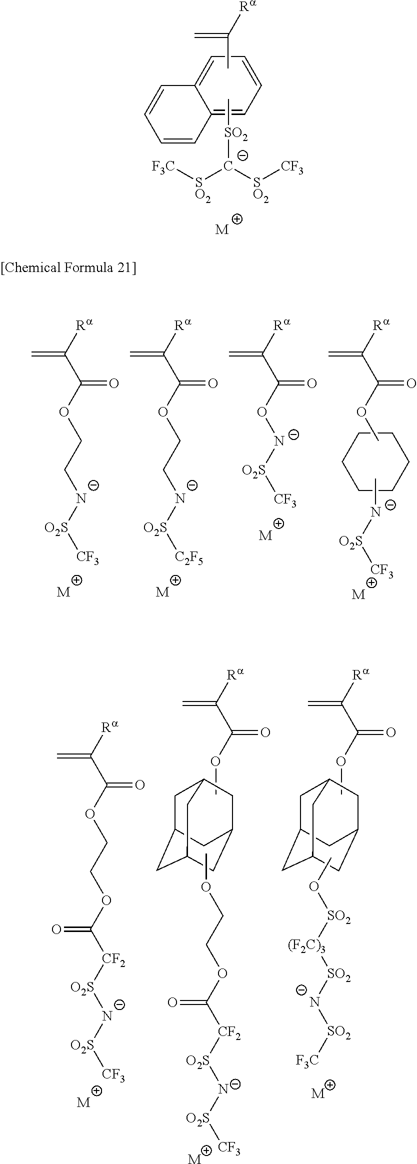

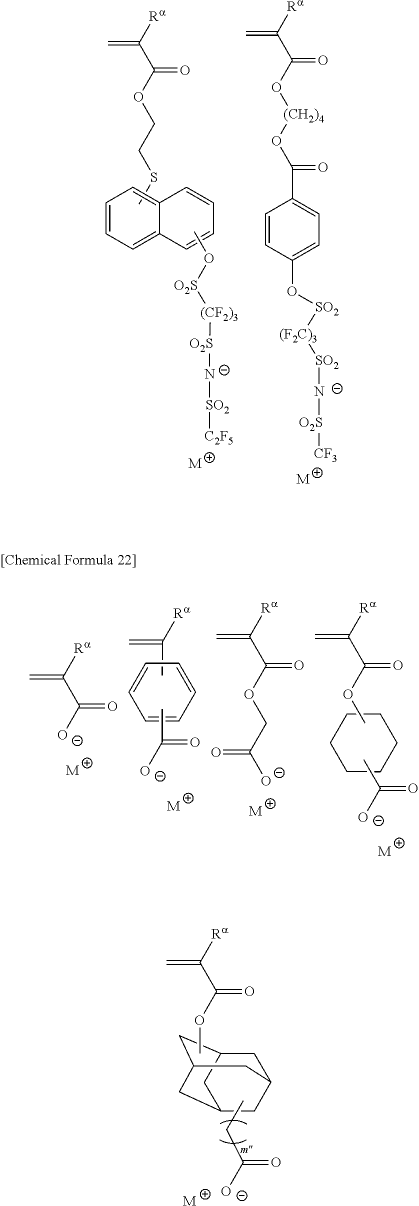

The structure, types of other structural units, which are introduced if required, the containing ratio of each of the structural units; mass average molecular weight, dispersity and the like of the “structural unit containing the first ammonium cation and the anion group that generates an acid upon exposure” in the first precursor polymer can be appropriately determined, by taking the desired composition of the copolymer, demand characteristics and the like into consideration.

The first precursor polymer can be obtained by a method for polymerizing monomers (including the monomer (G)) corresponding with each of the structural units that composes the first precursor polymer by a conventional radical polymerization or the like; a method in the [step for obtaining the first precursor polymer] which will be described later; or the like method.

Furthermore, by using a chain transfer agent such as HS—CH₂—CH₂—CH₂—C(CF₃)₂—OH, a —C(CF₃)₂—OH group can be introduced at the terminals when the above polymerization is performed. Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern) when utilized for resist compositions.

### (Reaction Between First Precursor Polymer and Amine)

In the amine reaction step, for example, by reacting the first precursor polymer with an amine in an organic solvent, the first ammonium cation in the first precursor polymer is replaced by the conjugate acid (second ammonium cation) of an amine, and thereby the second precursor polymer having the second ammonium cation is obtained.

The amounts of the first precursor polymer and an amine can be appropriately determined by taking the amount of the first ammonium cation in the first precursor polymer into consideration.

As the reaction temperature, 0 to 50° C. is preferable, and 10 to 30° C. is more preferable.

Although the reaction time varies depending on reactivity between the first precursor polymer and an amine, the reaction temperature and the like; 5 min or longer and 24 hr or less is preferable, 10 to 120 min is more preferable, and 10 to 60 min is still more preferable.

An organic solvent contains at least a component that dissolve both the first precursor polymer and an amine, and in particular, a combination of a good solvent that dissolves the obtained second precursor polymer and a poor solvent that does not dissolve the second precursor polymer is preferable.

Examples of a good solvent include polar solvents such as acetonitrile, dimethyl sulfoxide, N,N-dimethylformamide, and methanol.

Examples of a poor solvent include hydrocarbon solvents such as n-heptane and n-hexane; and ether solvents such as tert-butylmethyl ether and diisopropyl ether.

After reacting the first precursor polymer with an amine, for example, by dropping the reaction solution (when a good solvent and a poor solvent are combined, a good solvent portion) into, for example, a large volume of an organic solvent (diisopropanol, heptane, methanol or the like), the polymer is deposited, and then by separating it by filtration, the second precursor polymer is obtained.

### [Salt-Exchange Step]

In the salt-exchange step, performing a salt-exchange between the second precursor polymer obtained in the above-described amine reaction step and a sulfonium cation or an iodoniumcation (a final sulfonium or iodonium cation).

### (Final Sulfonium or Iodonium Cation)

The final sulfonium or iodonium cation used in the salt-exchange step is a cation that is more hydrophobic than the second ammonium cation. In the salt-exchange step, by performing the salt-exchange as an exchange in which a less hydrophobic cation is replaced by a more hydrophobic cation, the salt-exchange proceeds easily, and a polymeric compound having a desired final sulfonium or iodonium cation (a final product) can be produced.

Examples of a final sulfonium or iodonium cation include each cation represented by each of the following general formulae (ca-1) to (ca-3).

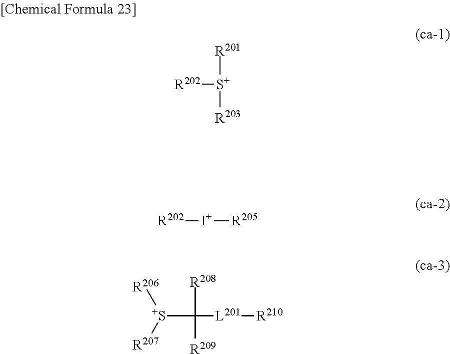

In the formula, R²⁰¹ to R²⁰⁷, and R²¹⁰ each independently represent an aryl group, an alkyl group, or an alkenyl group, which may have a substituent, and any two of R²⁰¹ to R²⁰³, and R²⁰⁶ and R²⁰⁷ are mutually bonded to form a ring together with the sulfur atom in the formula. R²⁰⁸ to R²⁰⁹ each independently represent a hydrogen atom or an alkyl group of 1 to 5 carbon atoms, and L²⁰¹ represents —C(═O)— or —C(═O)—O—.

The method of producing a polymeric compound of the present invention is particularly useful to produce a polymeric compound in which the number of aromatic rings represented by R²⁰¹ to R²⁰⁵ in the general formula (ca-1) or the general formula (ca-2) is smaller (preferably two or less, and more preferably 0 or 1).

Examples of an aryl group represented by R²⁰¹ to R²⁰⁷, and R²¹⁰ include an unsubstituted aryl group of 6 to 20 carbon atoms, and a phenyl group and a naphthyl group are preferable.

An alkyl group represented by R²⁰¹ to R²⁰⁷, and R²¹⁰ is preferably a linear or branched alkyl group of 1 to 30 carbon atoms.

An alkenyl group represented by R²⁰¹ to R²⁰⁷, and R²¹⁰ preferably has 2 to 10 carbon atoms.

Examples of a substituent which R²⁰¹ to R²⁰⁷, and R²¹⁰ may have include an alkyl group, a halogen atom (preferably a fluorine atom), a halogenated alkyl group, an oxo group (═O), a cyano group, an amino group, an aryl group, and each group represented by each of the following formulae (ca-r-1) to (ca-r-7).

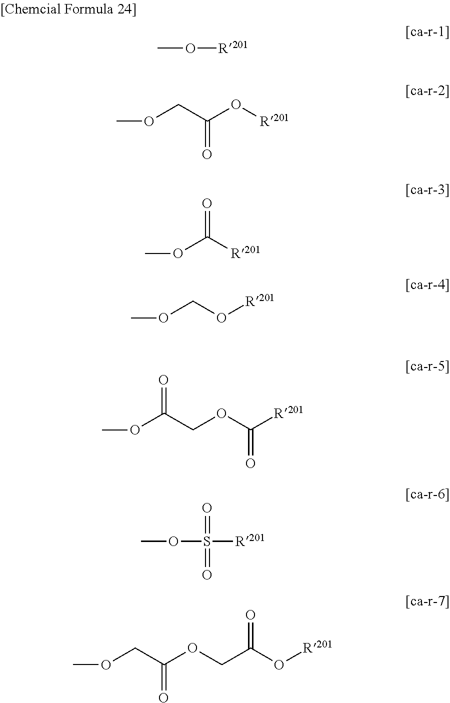

In the formula, R′²⁰¹ represents a hydrogen atom or a hydrocarbon group of 1 to 30 carbon atoms.

A hydrocarbon group represented by R′²⁰¹ is the same as the cyclic group represented by R¹⁰¹, which may have a substituent, and will be described later, a linear alkyl group or an alkenyl group, which may have a substituent.

When any two of R²⁰¹ to R²⁰³, and R²⁰⁶ and R²⁰⁷ are mutually bonded to form a ring together with the sulfur atom in the formula, they can be bonded via heteroatoms such as a sulfur atom, an oxygen atom, and a nitrogen atom; or a functional group such as a carbonyl group, —SO—, —SO₂—, —SO₃—, —COO—, —CONH—, or —N(R_{N})— (the R_{N} represents an alkyl group of 1 to 5 carbon atoms). As the formed ring, one ring that has a sulfur atom in the formula within the ring skeleton thereof is preferably a 3- to 10-membered ring including a sulfur atom, and most preferably a 5- to 7-membered ring. Specific examples of the formed ring include a thiophene ring, a thiazole ring, a benzothiophene ring, a thianthrene ring, a benzothiophene ring, a dibenzothiophene ring, a 9H-thioxanthene ring, a thioxanthone ring, a thianthrene ring, a phenoxathiin ring, tetrahydrothiophenium ring, and a tetrahydrothiopyranium ring.

Preferable specific examples of the cation represented by the formula (ca-1) include the cation represented by the following formula.

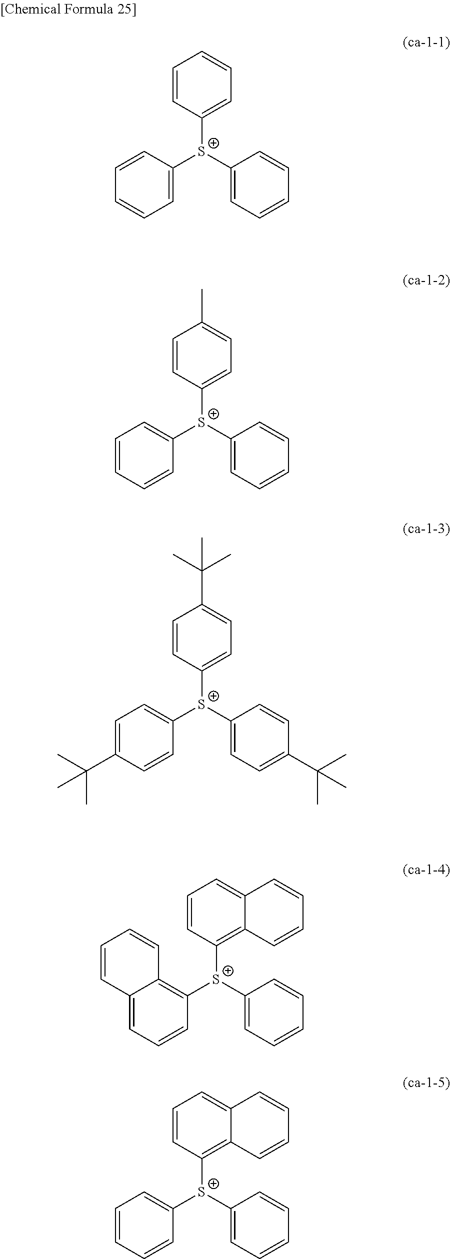

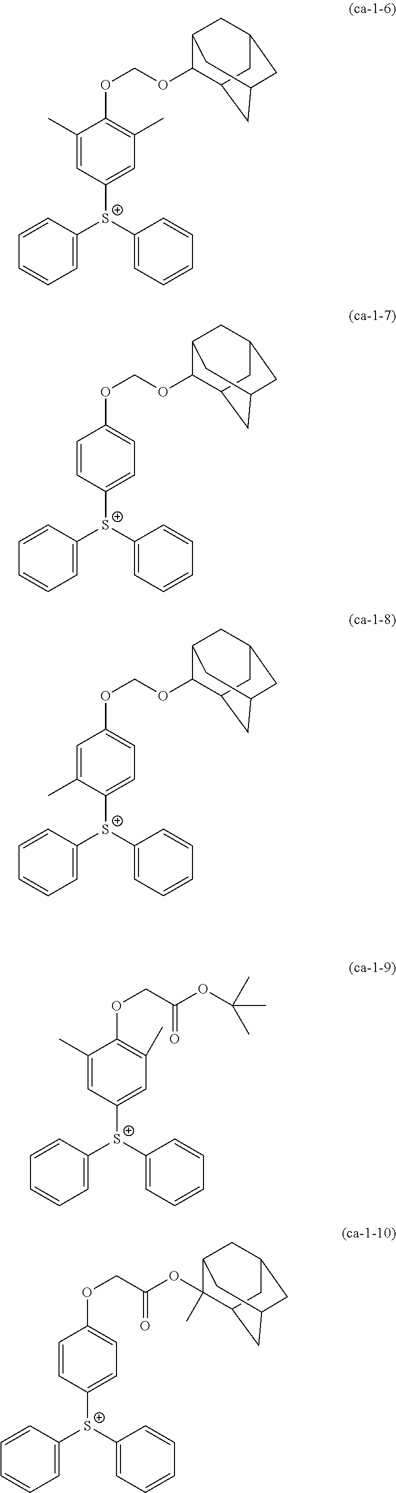

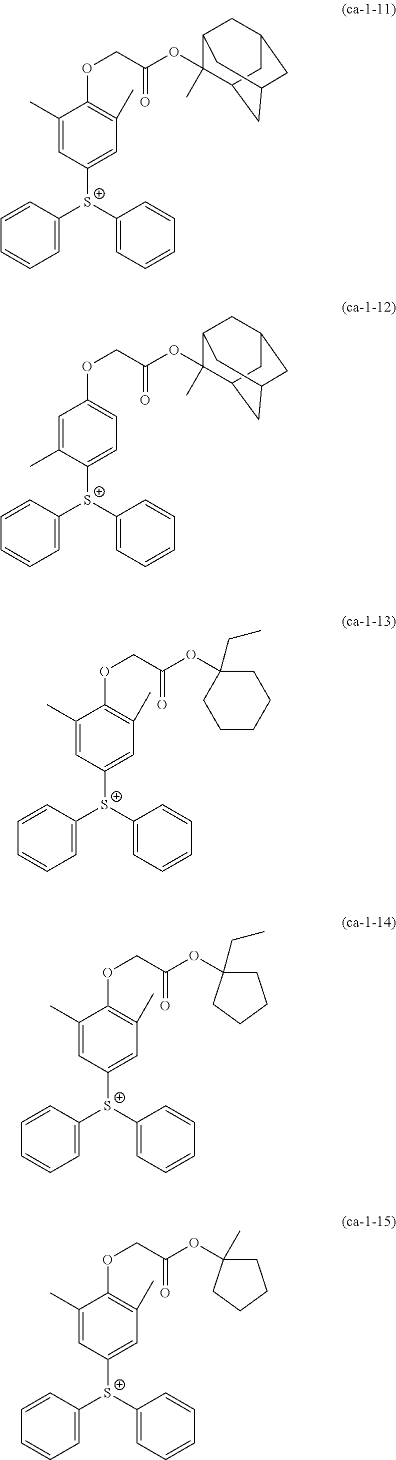

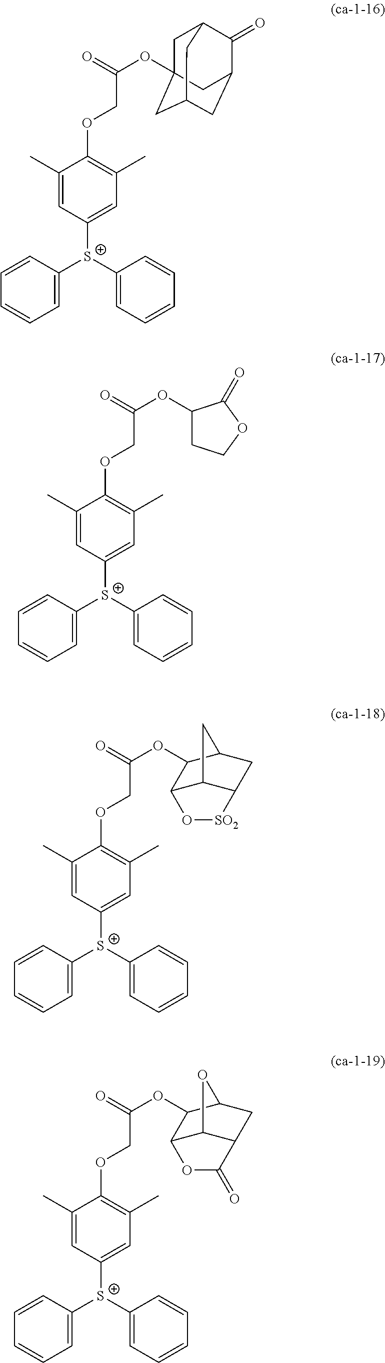

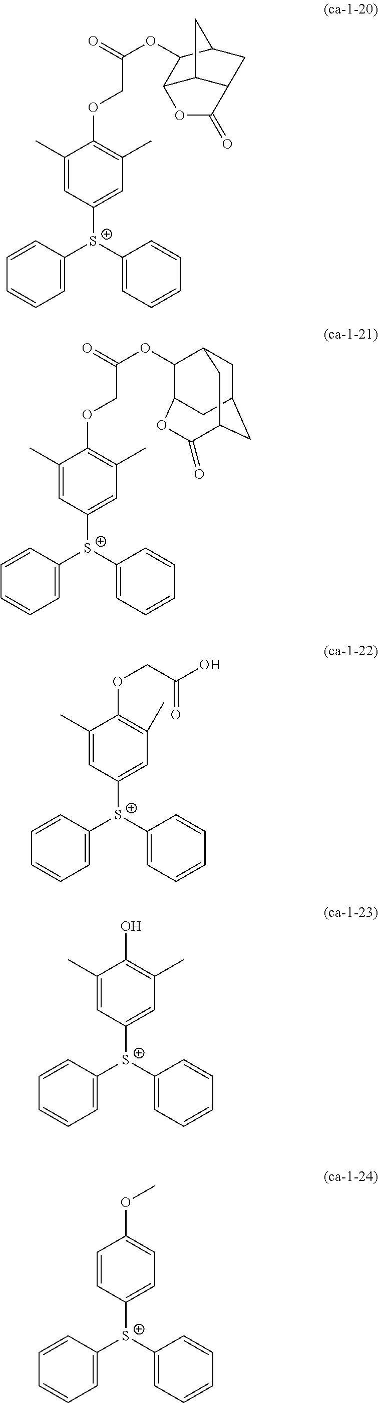

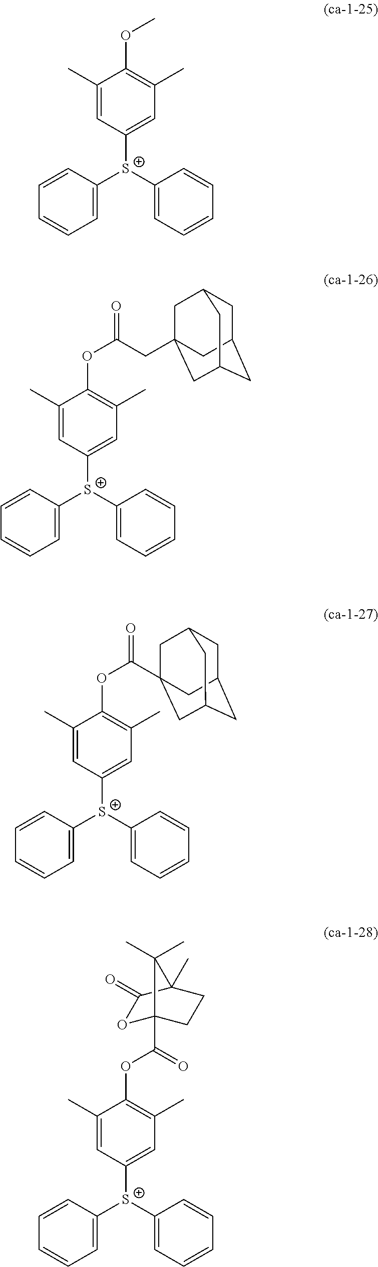

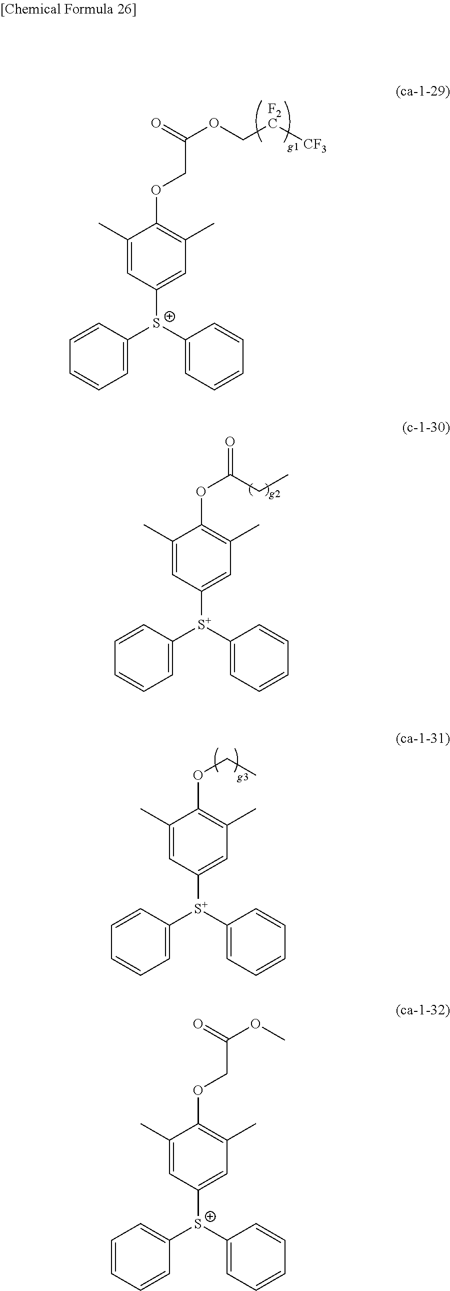

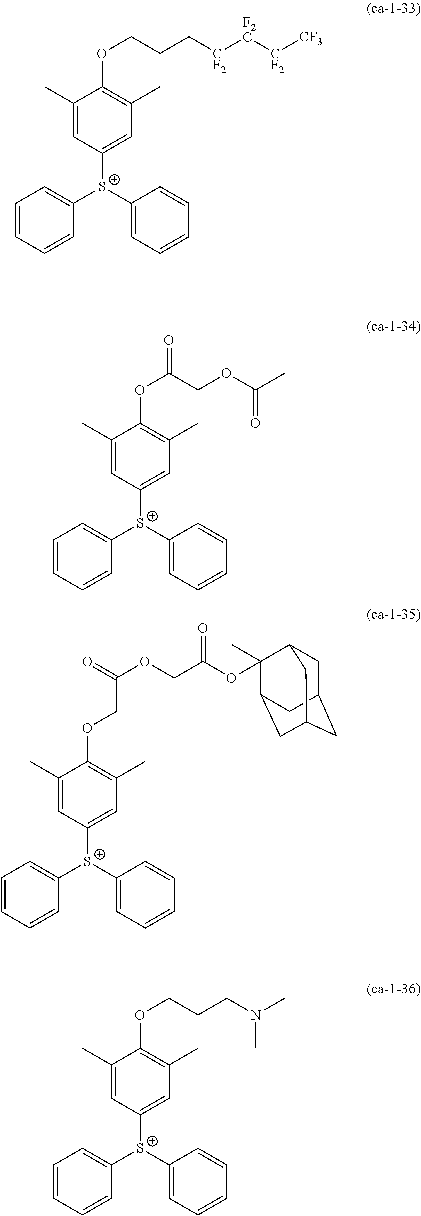

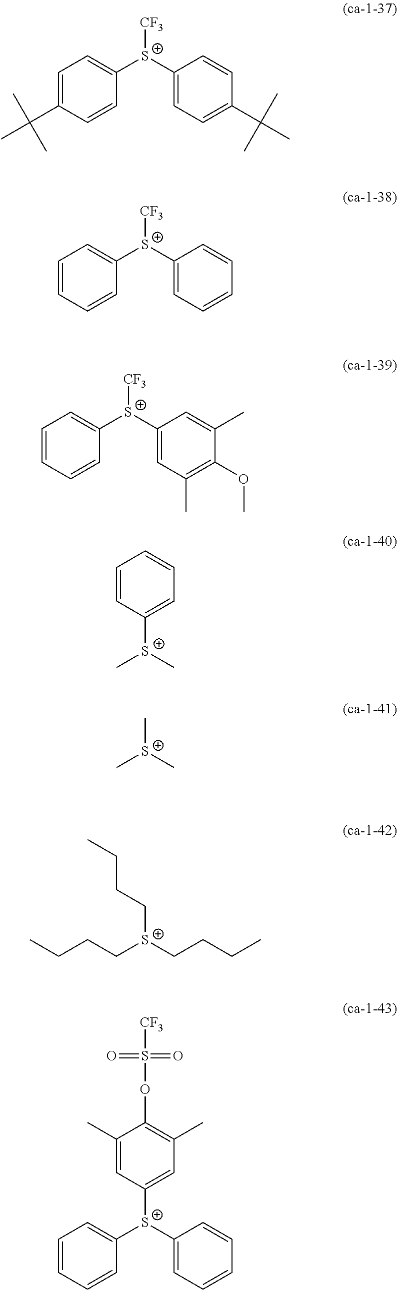

In the formula, g1, g2, and g3 represent recurring numbers, in which g1 represents an integer of 1 to 5, g2 represents an integer of 0 to 20, and g3 represents an integer of 0 to 20.

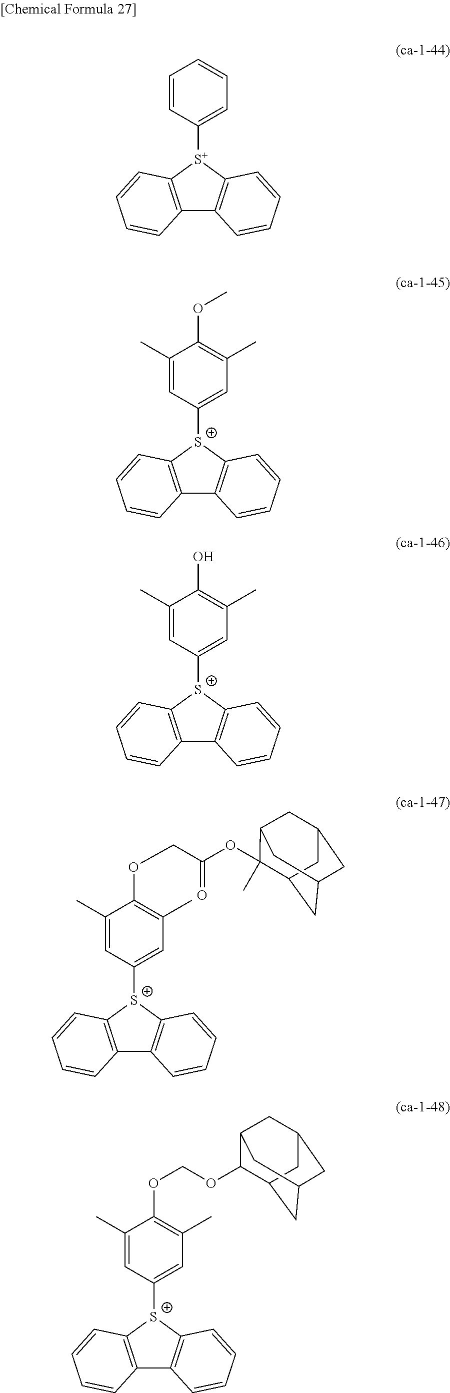

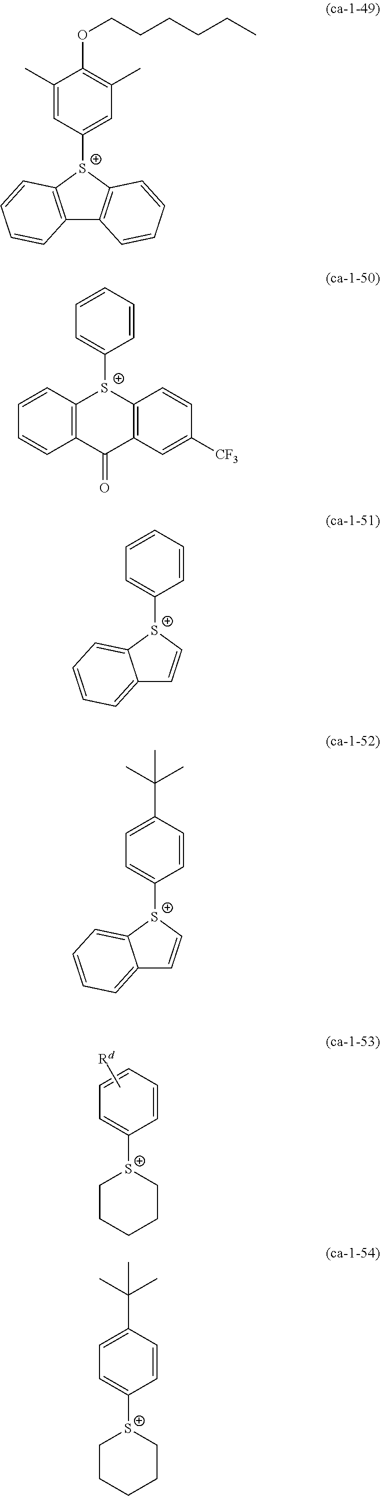

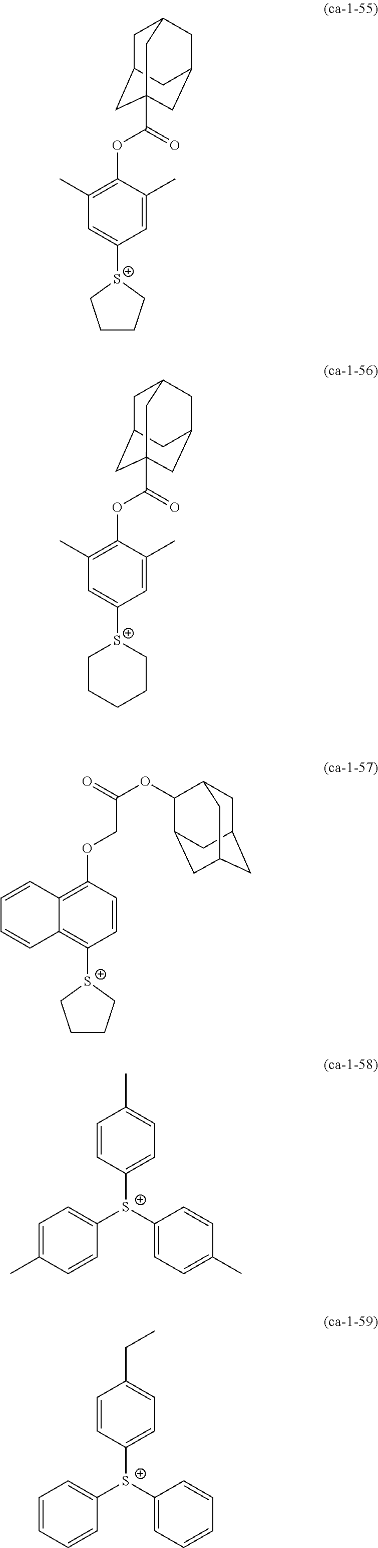

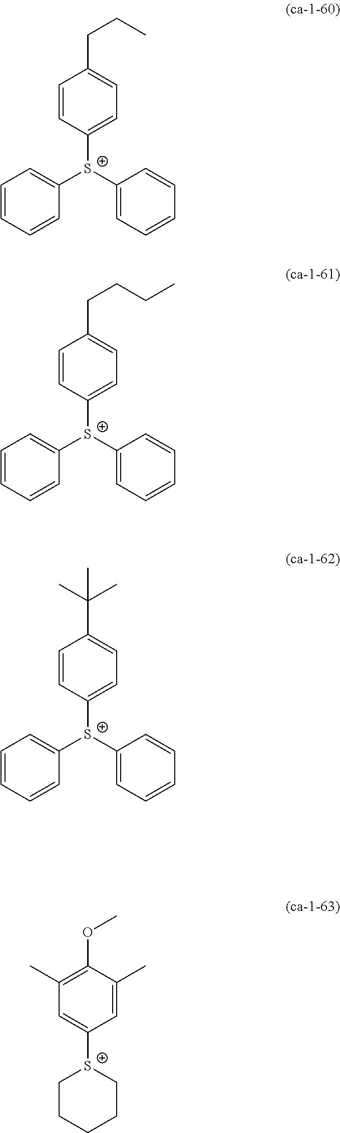

In the formula, Rd represents a hydrogen atom or a substituent, and the substituent is the same as those the above-described R²⁰¹ to R²⁰⁷ and R²¹⁰ to R²¹² may have.

Preferable specific examples of the cation represented by the formula (ca-3) include the cation represented by the following formula.

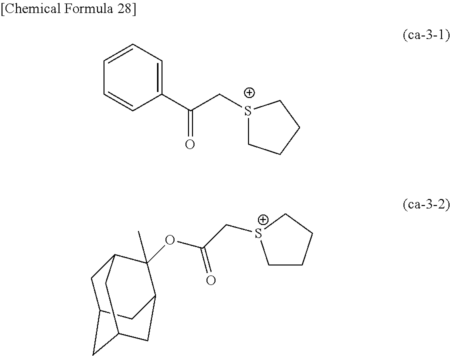 [SMILES: O=C(C[S+]1CCCC1)c1ccccc1 ; CC1(OC(=O)C[S+]2CCCC2)C2CC3CC(C2)CC1C3]

A final sulfonium or iodonium cation preferably has a retention time of 1.5 minutes or more, and more preferably 2 minutes or more, when measured under the above-described specific condition for the HPLC method. Although the upper limit of the value is not particularly limited, 60 minutes or less is preferable. When the retention time is greater than or equal to the preferable lower limit value, a salt-exchange reaction between the second precursor polymer and a sulfonium or an iodonium cation can easily proceed.

The retention time of the above-described final sulfonium or iodonium cation, which is measured under the above-described specific condition for the HPLC method is as follows.

Examples of a cation whose retention time is in the range of 2.6 minutes or less include each cation represented by each of the formulae (ca-1-38) to (ca-1-42) and (ca-1-63); among the cations represented by the formula (ca-1-53), a cation in which Rd represents a smaller group such as a hydrogen atom, a methyl group, or an alkoxy group, or a cation containing a polar group such as a hydroxyl group or a carboxy group; and a cation represented by the formula (ca-3-1). For example, the retention time of the cation represented by the formula (ca-1-38) is 2.3 minutes, and the retention time of the cation represented by the formula (ca-1-63) is 2.6 minutes.

Examples of a cation whose retention time is in the range of over 2.6 minutes to 4 minutes or less include a cation represented by the formulae (ca-1-1), (ca-1-2), (ca-1-17) to (ca-1-25), (ca-1-28), and (ca-1-29); a cation represented by the formulae (ca-1-30) to (ca-1-31), in which recurring numbers represented by g2 and g3 are smaller (about 0 to 2); and each cation represented by each of the formulae (ca-1-32), (ca-1-34), (ca-1-36), (ca-1-43) to (ca-1-46), (ca-1-50) to (ca-1-52), (ca-1-54), (ca-1-58) to (ca-1-60), and (ca-1-53) other than the above. For example, the retention time of the cation represented by the formula (ca-1-1) is 2.7 minutes, and the retention time of the cation represented by the formula (ca-1-2) is 3.1 minutes.

Examples of a cation whose retention time is over 4 minutes include a cation represented by the formulae (ca-1-3) to (ca-1-16), (ca-1-21), (ca-1-26), (ca-1-27), and (ca-1-29); a cation represented by the formulae (ca-1-30) to (ca-1-31), in which recurring numbers represented by g2 and g3 are larger (3 or more); and each cation represented by each of the formulae (ca-1-33), (ca-1-35), (ca-1-37), (ca-1-47) to (ca-1-49), (ca-1-55) to (ca-1-57), (ca-1-61), (ca-1-62), and (ca-3-2). For example, the retention time of the cation represented by the formula (ca-1-29) is 6.7 minutes (when g1 is 1).

A retention time of a cation having a more hydrophobic substituent becomes longer, while a retention time of a cation having a hydrophilic group such as a polar group becomes shorter.

In a measuring by the above-described HPLC method, there must be certain differences of the retention times between the second ammonium cation and a final sulfonium or iodonium cation, and the value obtained by dividing (the retention time of a final sulfonium or iodonium cation) by (the retention time of the second ammonium cation) is larger than 1, preferably 1.005 or more, and more preferably 1.01 or more. When the value is 1.005 or more, the salt-exchange easily proceeds. Since the second ammonium cation is more hydrophilic, and its retention time is basically shorter, the salt-exchange easily proceeds if there is only a difference between the second ammonium cation and a final sulfonium or iodonium cation.

### (Salt-Exchange Between Second Precursor Polymer and Sulfonium Cation or Iodonium Cation)

The salt-exchange between the second precursor polymer and a sulfonium or an iodonium cation (a final sulfonium or iodonium cation) is performed preferably in the double-layer of an organic solvent and water.

In the salt-exchange step, for example, by mixing the second precursor polymer and a compound containing a final sulfonium or iodonium cation (a compound for salt-exchange) in a mixed solvent of an organic solvent and water, a desired polymeric compound (a polymeric compound having a structural unit that is decomposed and generates acid upon exposure) can be obtained.

The compound for salt-exchange used in the salt-exchange step is a compound having a final sulfonium or iodonium cation and can be used for salt-exchange between a final sulfonium or iodonium cation, which is contained in the compound for salt-exchange, and the second precursor polymer. That is, a final sulfonium or iodonium cation contained in the compound for salt-exchange is the cation contained in the polymeric compound produced by the production method of the present invention.

A compound composed of a cation moiety constituted of a final sulfonium or iodonium cation and an anion moiety constituted of a non-nucleophilic ion is preferable as the compound for salt-exchange.

Examples of a non-nucleophilic ion include halogen ions such as a bromine ion and a chlorine ion; an ion whose acidity may be lower than that of the second precursor polymer; and BF₄⁻, AsF₆⁻, SbF₆⁻, PF₆⁻, or ClO₄⁻. Although an ion whose acidity may be lower than that of the second precursor polymer is not particularly limited, and can be appropriately determined depending on a type of monomer used for the second precursor polymer, examples include sulfonic acid ions such as a p-toluenesulfonic acid ion, a methanesulfonic acid ion, and a benzenesulfonic acid ion.

An organic solvent that composes a mixed solvent with water is not limited as long as it can be separated from water, and can dissolve the second precursor polymer, and for example, cyclohexanone, methyl ethyl ketone, propylene glycol monomethyl ether acetate, tetrahydrofuran, dichloromethane, 1,2-dichloroethane, ethyl acetate, propionitrile, or a mixed solvent thereof can be used.

The temperature for performing the salt-exchange is preferably 0 to 50° C., and more preferably 10 to 30° C.

Although a mixing time of the second precursor polymer and the compound for salt-exchange varies depending on reactivity between the second precursor polymer and the compound for salt-exchange, a temperature and the like; 0.5 minutes or longer and 24 hours or less is preferable, 5 minutes or longer and 12 hours or less is more preferable, and 10 to 60 minutes is still more preferable.

The amount of the compound for salt-exchange used in the salt-exchange is preferably about 1 to 10 mol, more preferably about 1 to 5 mol for 1 mol of a monomer that induces the structural unit having the second ammonium cation in the second precursor polymer.

Note that the amount of the monomer that induces the structural unit having the second ammonium cation in the second precursor polymer can be calculated from a ratio of the composition of the copolymer (ratio (molar ratio) of the respective structural units within the structural formula) obtained by carbon 13 nuclear magnetic resonance spectroscopy (600 MHz, ¹³C-NMR).

After the salt-exchange reaction between the second precursor polymer and the compound for salt-exchange is completed, a polymeric compound in the reaction solution (a final product) is preferably separated and purified.

The separation and purification can be conducted by a conventional method. For example, any one of concentration, washing with water, washing with an organic solvent, solvent extraction, distillation, crystallization, recrystallization and chromatography can be used alone, or two or more of these methods may be used in combination.

The polymeric compound produced by the production method of the present invention can be preferably used as a base component of a resist composition. When the polymeric compound is used as a base component of a resist composition, the containing ratio of each of the structural units, mass average molecular weight, dispersity and the like of the polymeric compound will be explained in detail in the <<Resist composition>> below.

### [Step for Obtaining the First Precursor Polymer]

In addition to the amine reaction step and the salt-exchange step, the method of producing a polymeric compound of the present invention preferably includes the step for obtaining the first precursor polymer, in which performing salt-exchange between the third precursor polymer having a sulfonium cation or an iodonium cation (in the present specification, these cations are referred to as “the second sulfonium or iodonium cation”) and the first ammonium cation that is more hydrophobic than the second sulfonium or iodonium cation.

In the step for obtaining the first precursor polymer, for example, by mixing the third precursor polymer and a salt having the first ammonium cation in a mixed solvent of an organic solvent and water, the first precursor polymer can be obtained.

### (Salt Having the First Ammonium Cation)

The first ammonium cation is the same as the first ammonium cation in the aforementioned first precursor polymer, and is more hydrophobic than the second sulfonium or iodonium cation.

The salt having the first ammonium cation can be used for salt-exchange between the first ammonium cation contained in the salt and the third precursor polymer. That is, the first ammonium cation contained in the salt becomes the cation contained in the first precursor polymer.

A compound composed of a cation moiety constituted of the first ammonium cation and an anion moiety constituted of a non-nucleophilic ion is preferable as the salt having the first ammonium cation.

Examples of the non-nucleophilic ion are the same as those of the non-nucleophilic ion in the above-described compound for salt-exchange.

### (The Third Precursor Polymer)

The third precursor polymer has the second sulfonium or iodonium cation.

The second sulfonium or iodonium cation is a cation that is less hydrophobic than the first ammonium cation. In the step for obtaining the first precursor polymer, by performing the salt-exchange as an exchange in which a less hydrophobic cation is replaced by a more hydrophobic cation, the salt-exchange proceeds easily, and the first precursor polymer having the desired first ammonium cation can be produced.

The second sulfonium or iodonium cation preferably has a retention time of 2 to 10 minutes, more preferably 2.5 to 6 minutes, and still more preferably more than 2.6 minutes, but 5 minutes or less, when measured under the above-described specific condition for the HPLC method. When the retention time is greater than or equal to the preferable lower limit value, the polymer has good solubility to an organic solvent, and the third precursor polymer can be easily synthesized. On the other hand, the retention time is less than or equal to the preferable upper limit value, the salt-exchange reaction easily proceeds when producing the first precursor polymer.

Specific examples of the second sulfonium or iodonium cation include the cations which are same as those described for the aforementioned final sulfonium or iodonium cation, and it can be appropriately selected depending on hydrophobicity of the first ammonium cation.

The retention time of the cation preferably within the range of over 2.6 minutes, and particularly preferably the cation is represented by any of the above-described formulae (ca-1-1), (ca-1-2), and (ca-1-58) to (ca-1-62).

In a measuring by the above-described HPLC method, there must be certain differences of the retention times between the second sulfonium or iodonium cation and the first ammonium cation, and the value obtained by dividing (the retention time of the second ammonium cation) by (the retention time of the second sulfonium or iodonium cation) is larger than 1, preferably 1.1 or more, and more preferably 1.2 or more. When the value is 1.1 or more, the salt-exchange easily proceeds.

An organic solvent that composes a mixed solvent with water is not limited as long as it can be separated from water and can dissolve the second precursor polymer, and for example, cyclohexanone, methyl ethyl ketone, propylene glycol monomethyl ether acetate, tetrahydrofuran, dichloromethane, 1,2-dichloroethane, ethyl acetate, propionitrile, or a mixed solvent thereof can be used.

The temperature and mixing time for performing the salt-exchange in the step for obtaining the first precursor polymer are same as the temperature and mixing time in the above-described salt-exchange step.

The amount of the salt having the first ammonium cation is preferably about 1 to 5 mol for 1 mol of a monomer that induces the structural unit having the second sulfonium or iodonium cation in the third precursor polymer.

After the salt-exchange reaction in the step for obtaining the first precursor polymer is completed, a polymeric compound in the reaction solution (the first precursor polymer) is preferably separated and purified.

The separation and purification can be conducted by a conventional method. For example, any one of concentration, washing with water, washing with an organic solvent, solvent extraction, distillation, crystallization, recrystallization and chromatography can be used alone, or two or more of these methods may be used in combination.

Examples of the third precursor polymer include those in which the first ammonium cation in the first precursor polymer is replaced by the second sulfonium or iodonium cation.

The third precursor polymer preferably has a structural unit that is derived from the monomer (hereinafter, the monomer is referred to as “monomer (G′)”) in which the first ammonium cation in the aforementioned monomer (G) is replaced by the second sulfonium or iodonium cation.

Same as the first precursor polymer, the third precursor polymer preferably include, in addition to the structural unit derived from the monomer (G′), the structural unit (a1), which will be described later, and may also include other structural units (a2), (a3), and (a4), which will be described later.

The third precursor polymer can be obtained by a method for polymerizing monomers (including the monomer (G′)) corresponding with each of the structural units that composes the third precursor polymer by a conventional radical polymerization or the like. Furthermore, by using a chain transfer agent such as HS—CH₂—CH₂—CH₂—C(CF₃)₂—OH, a —C(CF₃)₂—OH group can be introduced at the terminals when the above polymerization is performed.

The polymeric compound produced by the method of producing a polymeric compound according to the present invention has a structural unit that is decomposed and generates acid upon exposure (hereinafter, the structural unit is also referred to as “structural unit (a0)”).

The present inventors have found that, when an anion group that generates an acid upon exposure and a monomer containing a cation (a final sulfonium or iodonium cation) which is less hydrophobic compared to the conventional triphenylsulfonium cation and the like, or the compound for salt-exchange containing a final sulfonium or iodonium cation are used as raw materials for producing a polymeric compound having the structural unit (a0), a polymeric compound is difficult to be synthesized by the conventional radical polymerization, salt-exchange and the like. This may result from instability of a cation contained in the monomer or the compound for salt-exchange.

Therefore, in the production method according to the present invention, firstly, the precursor polymer (first precursor polymer) having the cation (first ammonium cation) that is (structurally) stable and more hydrophobic is used, instead of the cation (a final sulfonium or iodonium cation) that must be contained in the structural unit (a0).

Thus, by utilizing differences of acid dissociation constants (pKa), i.e., utilizing an amine whose pKa is larger than that of the first ammonium cation, the second precursor polymer having the conjugate acid (second ammonium cation) that is less hydrophobic than the final sulfonium or iodonium cation is synthesized from a reaction between the amine and the first precursor polymer. Accordingly, in the salt-exchange of the following step, a less hydrophobic cation is replaced by a more hydrophobic cation. As a result, the salt-exchange proceeds easily, and a polymeric compound having the desired structural unit (a0) can be produced.

According to the production method, a polymeric compound having a structural unit that is decomposed and generates acid upon exposure, which has been difficult to synthesize directly, can be easily produced.

Also according to the production method, a variety of cations can be introduced into a polymeric compound. Accordingly, the selection of types of cations contained in the polymeric compound becomes flexible. In addition, a component of a resist composition in which the polymeric compound is used can be optimized, and thus lithography properties are improved.

### <<Resist Composition>>

The resist composition of the present invention contains a polymeric compound produced by the above-described method of producing a polymeric compound of the present invention, i.e., a polymeric compound containing a structural unit that is decomposed and generates acid upon exposure (structural unit (a0)).

The resist composition of the present invention preferably contains the base component (A) (hereinafter, referred to as “component (A)”) that exhibits a changed solubility in a developing solution under the action of acid. When a resist film composed of such a resist composition is subjected to selective exposure, acid is generated from the structural unit (a0) within the exposed portions, and the solubility of the component (A) in a developing solution is changed under the action of acid, while the solubility of the component (A) in the developing solution within the unexposed portions is not changed, and thereby a difference of solubility is made between the exposed and unexposed portions. Accordingly, following a development of the resist film, when the resist composition is a positive-type resist composition, a positive resist pattern is formed by dissolving and removing the exposed portions, while the resist composition is a negative-type resist composition, a negative resist pattern is formed by dissolving and removing the unexposed portions.

In the present specification, a resist composition which forms a positive resist pattern by dissolving and removing the exposed portions is called a positive resist composition, and a resist composition which forms a negative resist pattern by dissolving and removing the unexposed portions is called a negative resist composition.

The resist composition of the present invention may be either a positive resist composition or a negative resist composition.

Also, the resist composition of the present invention in the formation of resist pattern may be used for an alkali developing process in which an alkali developing solution is used in developing treatment, or a solvent developing process using a developing solution containing an organic solvent (organic developing solution) in the developing treatment.

### <Component (A)>

As the component (A), organic compounds which are conventionally used as base components for chemically amplified resists can be used alone, or two or more of those in combination.

Here, the term “base component” refers to an organic compound capable of forming a film, and an organic compound having a molecular weight of 500 or more is preferably used as the base component. When the organic compound has a molecular weight of 500 or more, the film-forming ability is improved, and a resist pattern of nano level can be easily formed.

The “organic compound having a molecular weight of 500 or more” which can be used as a base component is broadly classified into non-polymers and polymers.

In general, as a non-polymer, any of those which have a molecular weight in the range of 500 to less than 4,000 is used. Hereafter, a “low molecular weight compound” refers to a non-polymer having a molecular weight in the range of 500 to less than 4,000.

As a polymer, any of those which have a molecular weight of 1,000 or more is generally used. In the present description and claims, the term “resin” refers to a polymer having a molecular weight of 1,000 or more.

As the molecular weight of the polymer, the weight average molecular weight in terms of the polystyrene equivalent value determined by gel permeation chromatography (GPC) is used.

The component (A) may exhibit increased solubility in a developing solution under action of acid, or may exhibit decreased solubility in a developing solution under action of acid.

When the resist composition of the present invention is a resist composition which forms a negative resist pattern in an alkali developing process (or forms a positive resist pattern in a solvent developing process), a base component that is soluble in an alkali developing solution (hereinafter, also referred to as “component (A0′)”) is preferably used as the component (A), and a cross-linking agent is blended in the resist composition. Usually, a resin (alkali-soluble resin) is used as the component (A0′). In the resist composition, when acid is generated from the structural unit (a0) upon exposure, the action of the generated acid causes cross-linking between the component (A0′) and the cross-linking agent, and thus solubility in an alkali developing solution is decreased (solubility in an organic developing solution is increased). Therefore, in the formation of a resist pattern, by conducting selective exposure of a resist film formed by applying the resist composition onto a substrate, the exposed portions become insoluble in an alkali developing solution (soluble in an organic developing solution), whereas the unexposed portions remain soluble in an alkali developing solution (insoluble in an organic developing solution), and hence, a negative resist pattern can be formed by alkali developing. Also, a positive resist pattern can be formed by developing with an organic developing solution.

Resins known as soluble in an alkali developing solution (hereinafter, referred to as “alkali-soluble resin”) can be used as the component (A0′).

Preferable examples of an alkali-soluble resin to form a resist pattern with minimal swelling, include a resin having a unit which is derived from at least one selected from α-(hydroxyalkyl)acrylic acid and an alkyl ester of α-(hydroxyalkyl)acrylic acid (preferably an alkyl ester of 1 to 5 carbon atoms), disclosed in Japanese Unexamined Patent Application, First Publication No. 2000-206694; an acrylic resin or a polycycloolefin resin in which an atom other than a hydrogen atom or a substituent may be bonded to the carbon atom on the α-position which has a sulfonamide group, disclosed in U.S. Pat. No. 6,949,325; an acrylic resin containing a fluorinated alcohol, in which an atom other than a hydrogen atom or a substituent may be bonded to the carbon atom on the α-position, disclosed in U.S. Pat. No. 6,949,325, Japanese Unexamined Patent Application, First Publication No. 2005-336452, and Japanese Unexamined Patent Application, First Publication No. 2006-317803; and a polycycloolefin resin containing a fluorinated alcohol, disclosed in Japanese Unexamined Patent Application, First Publication No. 2006-259582.

Among the acrylic acid in which an atom other than a hydrogen atom or a substituent may be bonded to the carbon atom on the α-position, the above-described “α-(hydroxyalkyl)acrylic acid” refers to one of, or both of the acrylic acid in which a hydrogen atom is bonded to the carbon atom on the α-position which has a carboxy group bonded thereto; and the α-hydroxyalkyl acrylic acid in which a hydroxyalkyl group (preferably a hydroxyalkyl group of 1 to 5 carbon atoms) is bonded to the carbon atom on the α-position.

As the cross-linking agent, for example, typically an amino-based cross-linking agent such as a glycoluril that has a methylol group or alkoxymethyl group, or the melamine-based cross-linking agent is preferable, as it enables formation of a resist pattern with minimal swelling. The amount of the cross-linker added is preferably within a range from 1 to 50 parts by weight, relative to 100 parts by weight of the alkali-soluble resin.

In the case where the resist composition of the present invention is a resist composition which forms a positive pattern in an alkali developing process and a negative pattern in a solvent developing process, it is preferable to use a base component (A0) (hereinafter, referred to as “component (A0)”) which exhibits increased polarity by the action of acid as the component (A). Since the polarity of the component (A0) changes prior to and after exposure, an excellent development contrast can be obtained not only in an alkali developing process, but also in a solvent developing process.

More specifically, in the case of applying an alkali developing process, the component (A0) is substantially insoluble in an alkali developing solution prior to exposure, but when acid is generated from the structural unit (a0) upon exposure, the action of this acid causes an increase in the polarity of the base component, thereby increasing the solubility of the component (A0) in an alkali developing solution. Therefore, in the formation of a resist pattern, by conducting selective exposure of a resist film formed by applying the resist composition to a substrate, the exposed portions change from an insoluble state to a soluble state in an alkali developing solution, whereas the unexposed portions remain insoluble in an alkali developing solution, and hence, a positive resist pattern can be formed by alkali developing.

On the other hand, in the case of a solvent developing process, the component (A0) exhibits high solubility in an organic developing solution prior to exposure, and when acid is generated from the structural unit (a0) upon exposure, the polarity of the component (A0) is increased by the action of the generated acid, thereby decreasing the solubility of the component (A0) in an organic developing solution. Therefore, in the formation of a resist pattern, by conducting selective exposure of a resist film formed by applying the resist composition to a substrate, the exposed portions change from a soluble state to an insoluble state in an organic developing solution, whereas the unexposed portions remain soluble in an organic developing solution. As a result, by conducting development using an organic developing solution, a contrast can be made between the exposed portions and unexposed portions, thereby enabling the formation of a negative resist pattern.

In the present invention, the component (A) is preferably the component (A0). That is, the resist composition of the present invention is preferably a chemically amplified resist composition which becomes a positive type in the case of an alkali developing process, and a negative type in the case of a solvent developing process.

The component (A0) may be a resin component that exhibits increased polarity under the action of acid, a low molecular weight compound that exhibits increased polarity under the action of acid, or a mixture thereof.

As the component (A0), a resin component that exhibits increased polarity under the action of acid is preferable, and in particular, a resin component containing the polymeric compound (A1) (hereinafter, referred to as “component (A1)”) which generates acid upon exposure, and exhibits increased polarity under the action of acid is preferable.

### [Component (A1)]

As the component (A1), specifically, a polymeric compound having the structural unit (a0) that is decomposed and generates acid upon exposure and the structural unit (a1) which contains a decomposable group that exhibits increased polarity under the action of acid is preferable, and the polymeric compound produced by the method of producing a polymeric compound of the above-described first aspect is particularly preferable.

(Structural Unit (a0))

The structural unit (a0) is a structural unit that is decomposed and generates acid upon exposure.

Examples of the structural unit (a0) include the structural unit containing the aforementioned final sulfonium or iodonium cation and the anion group that generates acid upon exposure, and specifically, the structural unit represented by the following general formula (a0-1) is preferable.

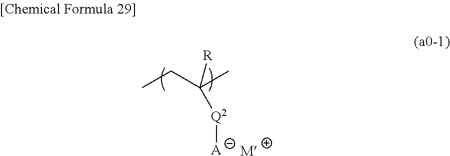

In the formula, R, Q², and A⁻ are the same as above, and M″⁺ represents the second sulfonium or iodonium cation described above.

Specific examples of the structural unit (a0) include a structural unit that is derived from at least one compound selected from the group consisting of the compounds each of which is represented by each of the formulae (an11) to (an14), (an21) to (an25), (an31) to (an32), and (an41) to (an44), and a structural unit whose cation moiety is the aforementioned final sulfonium or iodonium cation is particularly preferable.

As the structural unit (a0) in the component (A1), one can be used alone, or two or more can be used in combination.

In the component (A1), the amount of the structural unit (a0) based on the combined total of all structural units constituting the component (A1) is preferably 1 to 40 mol %, more preferably 1 to 35 mol %, still more preferably 3 to 30 mol %.

When the amount of the structural unit (a0) is at least as large as the lower limit of the above-mentioned range, a resist pattern is easily obtained when the resist composition is made, and lithography properties are further improved. On the other hand, when the amount of the structural unit (a0) is no more than the upper limit of the above-mentioned range, a good balance can be achieved with the other structural units.

(Structural Unit (a1))

The structural unit (a1) is a structural unit containing an acid decomposable group that exhibits increased polarity under the action of acid.

The term “acid decomposable group” refers to a group in which at least a part of the bond within the structure thereof is cleaved by the action of an acid.

Examples of acid decomposable groups which exhibit increased polarity by the action of an acid include groups which are decomposed by the action of an acid to form a polar group.

Examples of the polar group include a carboxy group, a hydroxy group, an amino group and a sulfo group (—SO₃H). Among these, a polar group containing —OH in the structure thereof (hereafter, referred to as “OH-containing polar group”) is preferable, a carboxy group or a hydroxy group is more preferable, and a carboxy group is particularly desirable.

More specifically, as an example of an acid decomposable group, a group in which the aforementioned polar group has been protected with an acid dissociable group (such as a group in which the hydrogen atom of the OH in the OH-containing polar group has been protected with an acid dissociable group) can be given.

An “acid dissociable group” is a group in which at least the bond between the acid dissociable group and the adjacent carbon atom is cleaved by the action of acid. It is necessary that the acid dissociable group that constitutes the acid decomposable group is a group which exhibits a lower polarity than the polar group generated by the dissociation of the acid dissociable group. Thus, when the acid dissociable group is dissociated by the action of acid, a polar group exhibiting a higher polarity than that of the acid dissociable group is generated, thereby increasing the polarity. As a result, the polarity of the entire component (A1) is increased. By the increase in the polarity, the solubility in a developing solution is relatively changed. When the developing solution is an alkali developing solution, the solubility in the alkali developing solution is increased. On the other hand, when the developing solution is an organic developing solution, the solubility in the organic developing solution decreases.

The acid dissociable group is not particularly limited, and any of the groups that have been conventionally proposed as acid dissociable groups for the base resins of chemically amplified resists can be used. Generally, groups that form either a cyclic or chain-like tertiary alkyl ester with the carboxyl group of the (meth)acrylic acid, and acetal-type acid dissociable groups such as alkoxyalkyl groups are widely known.

Here, a tertiary alkyl ester describes a structure in which an ester is formed by substituting the hydrogen atom of a carboxyl group with a chain-like or cyclic tertiary alkyl group, and a tertiary carbon atom within the chain-like or cyclic tertiary alkyl group is bonded to the oxygen atom at the terminal of the carbonyloxy group (—C(═O)—O—). In this tertiary alkyl ester, the action of acid causes cleavage of the bond between the oxygen atom and the tertiary carbon atom, thereby forming a carboxy group.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable groups”.

Examples of tertiary alkyl ester-type acid dissociable groups include aliphatic branched, acid dissociable groups and aliphatic cyclic group-containing acid dissociable groups.

The term “aliphatic branched” refers to a branched structure having no aromaticity. The “aliphatic branched, acid dissociable group” is not limited to be constituted of only carbon atoms and hydrogen atoms (not limited to hydrocarbon groups), but is preferably a hydrocarbon group. Further, the “hydrocarbon group” may be either saturated or unsaturated, but is preferably saturated.

As an example of the aliphatic branched, acid dissociable group, for example, a group represented by the formula —C(R⁷¹)(R⁷²)(R⁷³) can be given (in the formula, each of R⁷¹ to R⁷³ independently represents a linear alkyl group of 1 to 5 carbon atoms). The group represented by the formula —C(R⁷¹)(R⁷²)(R⁷³) preferably has 4 to 8 carbon atoms, and specific examples include a tert-butyl group, a 2-methyl-2-butyl group, a 2-methyl-2-pentyl group and a 3-methyl-3-pentyl group.

Among these, a tert-butyl group is particularly desirable.

The term “aliphatic cyclic group” refers to a monocyclic group or polycyclic group that has no aromaticity.

In the “aliphatic cyclic group-containing acid dissociable group”, the “aliphatic cyclic group” may or may not have a substituent. Examples of the substituent include an alkyl group of 1 to 5 carbon atoms, an alkoxy group of 1 to 5 carbon atoms, a fluorine atom, a fluorinated alkyl group of 1 to 5 carbon atoms, and an oxygen atom (═O).

The basic ring of the “aliphatic cyclic group” exclusive of substituents is not limited to be constituted from only carbon and hydrogen (not limited to hydrocarbon groups), but is preferably a hydrocarbon group. Further, the “hydrocarbon group” may be either saturated or unsaturated, but is preferably saturated.

The aliphatic cyclic group may be either a monocyclic group or a polycyclic group.

As such aliphatic cyclic groups, groups in which one or more hydrogen atoms have been removed from a monocycloalkane or a polycycloalkane such as a bicycloalkane, tricycloalkane or tetracycloalkane which may or may not be substituted with an alkyl group of 1 to 5 carbon atoms, a fluorine atom or a fluorinated alkyl group, may be used. Specific examples of aliphatic cyclic hydrocarbon groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane. In these aliphatic cyclic hydrocarbon groups, part of the carbon atoms constituting the ring may be replaced with an ethereal oxygen atom (—O—).

Examples of aliphatic cyclic group-containing acid dissociable groups include

(i) a monovalent aliphatic cyclic group in which a substituent (a group or an atom other than hydrogen) is bonded to the carbon atom on the ring skeleton to which an atom adjacent to the acid dissociable group (e.g., “—O—” within “—C(═O)—O— group”) is bonded to form a tertiary carbon atom; and

(ii) a group which has a branched alkylene group containing a tertiary carbon atom, and a monovalent aliphatic cyclic group to which the tertiary carbon atom is bonded.

In the group (i), as the substituent bonded to the carbon atom to which an atom adjacent to the acid dissociable group on the ring skeleton of the aliphatic cyclic group, an alkyl group can be mentioned. Examples of the alkyl group include the same groups as those represented by R¹⁴ in formulae (1-1) to (1-9) described later.

Specific examples of the group (i) include groups represented by general formulae (1-1) to (1-9) shown below.

Specific examples of the group (ii) include groups represented by general formulae (2-1) to (2-6) shown below.

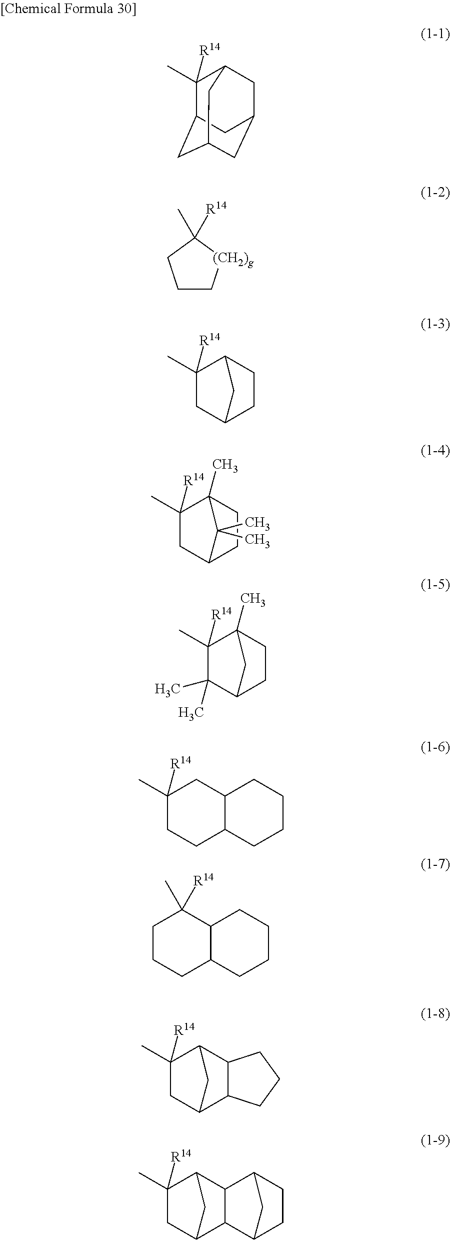

In the formulae above, R¹⁴ represents an alkyl group; and g represents an integer of 0 to 8.

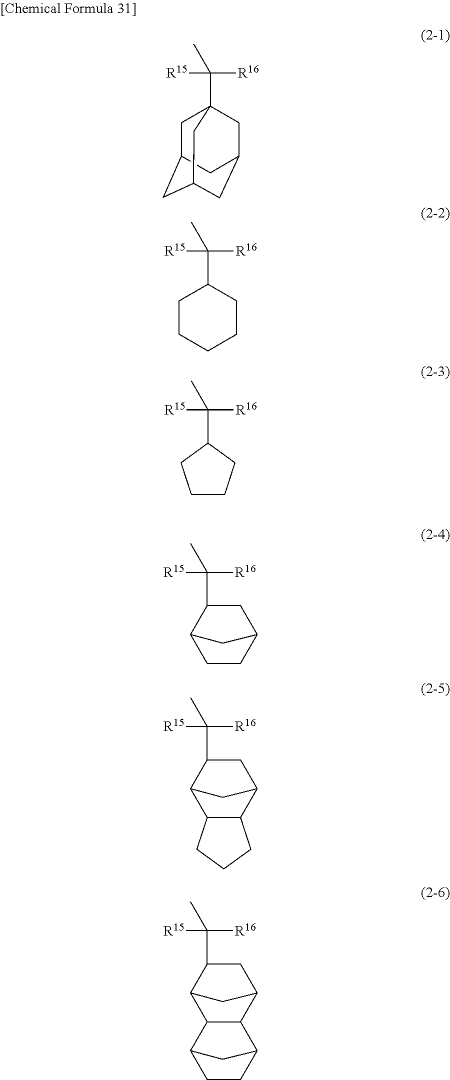

In the formulae above, each of R¹⁵ and R¹⁶ independently represents an alkyl group.

In formulae (1-1) to (1-9), the alkyl group for R¹⁴ may be linear, branched or cyclic, and is preferably linear or branched.

The linear alkyl group preferably has 1 to 5 carbon atoms, more preferably 1 to 4, and still more preferably 1 or 2. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 10 carbon atoms, and more preferably 3 to 5. Specific examples of such branched alkyl groups include an isopropyl group, an isobutyl group, a tert-butyl group, an isopentyl group and a neopentyl group, and an isopropyl group is particularly desirable.

Examples of the cyclic alkyl group include those described above for the aliphatic cyclic group.

g is preferably an integer of 0 to 3, more preferably 1 to 3, and still more preferably 1 or 2.

In formulae (2-1) to (2-6), as the alkyl group for R¹⁵ and R¹⁶, the same alkyl groups as those for R¹⁴ can be used.

In formulae (1-1) to (1-9) and (2-1) to (2-6), part of the carbon atoms constituting the ring may be replaced with an ethereal oxygen atom (—O—).

Further, in formulae (1-1) to (1-9) and (2-1) to (2-6), one or more of the hydrogen atoms bonded to the carbon atoms constituting the ring may be substituted with a substituent. Examples of the substituent include an alkyl group of 1 to 5 carbon atoms, a fluorine atom and a fluorinated alkyl group.

An “acetal-type acid dissociable group” generally substitutes a hydrogen atom at the terminal of an OH-containing polar group such as a carboxy group or hydroxyl group, so as to be bonded with an oxygen atom. When acid acts to break the bond between the acetal-type acid dissociable group and the oxygen atom to which the acetal-type, acid dissociable group is bonded, an OH-containing polar group such as a carboxy group or a hydroxy group is formed.

Examples of acetal-type acid dissociable groups include groups represented by general formula (p1) shown below.

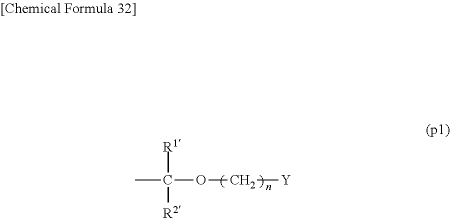

In the formula, R¹′ and R²′ each independently represent a hydrogen atom or an alkyl group of 1 to 5 carbon atoms, n represents an integer of 0 to 3, and Y represents an alkyl group or an aliphatic cyclic group.

In general formula (p1), n is preferably an integer of 0 to 2, more preferably 0 or 1, and most preferably 0.

The alkyl group for R¹′ and R²′ is preferably a linear or branched alkyl group, and specific examples include a methyl group, an ethyl group, a propyl group, an isopropyl group, a n-butyl group, an isobutyl group, a tert-butyl group, a pentyl group, an isopentyl group, and a neopentyl group. Among these, a methyl group or an ethyl group is preferable, and a methyl group is most preferable.

In the present invention, it is preferable that at least one of R¹′ and R²′ be a hydrogen atom. That is, it is preferable that the acid dissociable group (p1) is a group represented by general formula (p1-1) shown below.

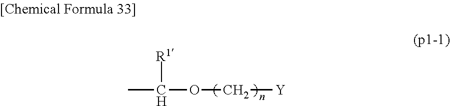

In the formula, R¹′, n and Y are the same as defined above.

As the alkyl group for Y, preferably an alkyl group of 1 to 20 carbon atoms, and more preferably an alkyl group of 1 to 10 carbon atoms; preferably a linear or branched alkyl group, and specific examples include a methyl group, an ethyl group, a propyl group, an isopropyl group, a n-butyl group, an isobutyl group, a tert-butyl group, a pentyl group, an isopentyl group, a neopentyl group, a 1,1-dimethylethyl group, a 1,1-diethyl propyl group, a 2,2-dimethylpropyl group, and a 2,2,-dimethylbutyl group.

As the aliphatic cyclic group for Y, any of the aliphatic monocyclic/polycyclic groups which have been proposed for conventional ArF resists and the like can be appropriately selected for use. For example, the same aliphatic cyclic groups described above in connection with the “acid dissociable group containing an aliphatic cyclic group” can be used.

Further, as the acetal-type, acid dissociable group, groups represented by general formula (p2) shown below can also be used.

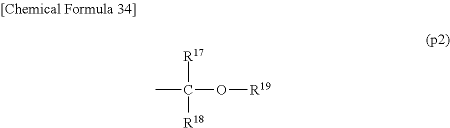

In the formula, R¹⁷ and R¹⁸ each independently represent a linear or branched alkyl group or a hydrogen atom; and R¹⁹ represents a linear, branched or cyclic alkyl group; or R¹⁷ and R¹⁹ each independently represent a linear or branched alkylene group, and the terminal of R¹⁷ is bonded to the terminal of R¹⁹ to form a ring.

The alkyl group for R¹⁷ and R¹⁸ preferably has 1 to 15 carbon atoms, and may be either linear or branched. As the alkyl group, an ethyl group or a methyl group is preferable, and a methyl group is most preferable.

It is particularly desirable that either one of R¹⁷ and R¹⁸ be a hydrogen atom, and the other be a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cycloalkyl group, it preferably has 4 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane. Among these, a group in which one or more hydrogen atoms have been removed from adamantane is preferable.

In general formula (p2) above, R¹⁷ and R¹⁹ may each independently represent a linear or branched alkylene group (preferably an alkylene group of 1 to 5 carbon atoms), and the terminal of R¹⁹ may be bonded to the terminal of R¹⁷.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4- to 7-membered ring, and more preferably a 4- to 6-membered ring. Specific examples of the cyclic group include tetrahydropyranyl group and tetrahydrofuranyl group.

The structural unit (a1) must contain an acid decomposable group, but other structures are not particularly limited, and examples include a structural unit derived from an acrylate ester which may have the hydrogen atom bonded to the carbon atom on the α-position substituted with a substituent and containing an acid decomposable group; a structural unit in which a hydrogen atom of the hydroxyl group of the structural unit derived from hydroxystyrene which may have the hydrogen atom bonded to the carbon atom on the α-position substituted with a substituent, and may have the hydrogen atom bonded to the benzene ring substituted with a substituent other than a hydroxyl group is substituted with an acid decomposable group or a substituent containing an acid decomposable group; and a structural unit in which a hydrogen atom of the hydroxyl group of the structural unit derived from vinyl(hydroxynaphthalene) which may have the hydrogen atom bonded to the carbon atom on the α-position substituted with a substituent, and may have the hydrogen atom bonded to the naphthalene ring substituted with a substituent other than a hydroxyl group is substituted with an acid decomposable group or a substituent containing an acid decomposable group.

Here, in the present description and claims, a “structural unit derived from an acrylate ester” refers to a structural unit that is formed by the cleavage of the ethylenic double bond of an acrylate ester.

An “acrylate ester” refers to a compound in which the terminal hydrogen atom of the carboxy group of acrylic acid (CH₂═CH—COOH) has been substituted with an organic group.

The acrylate ester may have the hydrogen atom bonded to the carbon atom on the α-position substituted with a substituent. The substituent that substitutes the hydrogen atom bonded to the carbon atom on the α-position is atom other than hydrogen or a group, and examples thereof include an alkyl group of 1 to 5 carbon atoms, a halogenated alkyl group of 1 to 5 carbon atoms and a hydroxyalkyl group. A carbon atom on the α-position of an acrylate ester refers to the carbon atom bonded to the carbonyl group, unless specified otherwise.

Hereafter, an acrylic acid and an acrylate ester each of which has the hydrogen atom bonded to the carbon atom on the α-position substituted with a substituent is frequently referred to as an “α-position substituted acrylic acid” and an “α-position substituted acrylate ester” respectively.

Further, the acrylic acid and the α-position substituted acrylic acid are included in and frequently referred to as an “(α-position substituted) acrylic acid,” and the acrylate ester and the α-position substituted acrylate ester are included in and frequently referred to as an “(α-position substituted) acrylate ester”.

In the α-substituted acrylate ester, the alkyl group as the substituent on the α-position is preferably a linear or branched alkyl group, and specific examples thereof include a methyl group, an ethyl group, a propyl group, an isopropyl group, an n-butyl group, an isobutyl group, a tert-butyl group, a pentyl group, an isopentyl group and a neopentyl group.

Specific examples of the halogenated alkyl group of 1 to 5 carbon atoms as the substituent on the α-position include groups in which part or all of the hydrogen atoms of the aforementioned “alkyl group of 1 to 5 carbon atoms as the substituent on the α-position” are substituted with halogen atoms. Examples of the halogen atom include a fluorine atom, a chlorine atom, a bromine atom and an iodine atom, and a fluorine atom is particularly desirable.

It is preferable that a hydrogen atom, an alkyl group of 1 to 5 carbon atoms or a halogenated alkyl group of 1 to 5 carbon atoms is bonded to the α-position of the α-substituted acrylate ester, a hydrogen atom, an alkyl group of 1 to 5 carbon atoms or a fluorinated alkyl group of 1 to 5 carbon atoms is more preferable, and in terms of industrial availability, a hydrogen atom or a methyl group is the most desirable.

A “structural unit derived from a hydroxystyrene or a hydroxy styrene derivative” refers to a structural unit that is composed by the cleavage of the ethylenic double bond of a hydroxystyrene or a hydroxystyrene derivative.

A “hydroxystyrene derivative” includes a derivative in which a hydrogen atom at the α-position of hydroxystyrene is substituted with another substituent such as an alkyl group and a halogenated alkyl group, and derivatives thereof. Unless otherwise specified, the α-position (a carbon atom at the α-position) within the “hydroxystyrene derivative” refers to a carbon atom to which a benzene ring is bonded.

A “structural unit derived from a vinylbenzoic acid or a vinylbenzoic acid derivative” refers to a structural unit that is composed by the cleavage of the ethylenic double bond of a vinylbenzoic acid or a vinylbenzoic acid derivative.

A “vinylbenzoic acid derivative” includes a derivative in which a hydrogen atom at the α-position of vinylbenzoic acid is substituted with another substituent such as an alkyl group and a halogenated alkyl group, and derivatives thereof. Unless otherwise specified, the α-position (a carbon atom at the α-position) within the “vinylbenzoic acid derivative” refers to a carbon atom to which a benzene ring is bonded.

Of these, as the structural unit (a1), a structural unit derived from an acrylate ester which may have the hydrogen atom bonded to the carbon atom on the α-position substituted with a substituent is preferable, and specific examples include a structural unit represented by the following general formula (a1-0-1), a structural unit represented by the following general formula (a1-0-2) and the like.

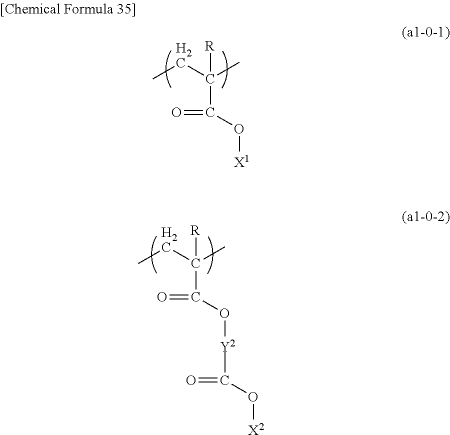

In the formulae, R represents a hydrogen atom, an alkyl group of 1 to 5 carbon atoms or a halogenated alkyl group of 1 to 5 carbon atoms; X¹ represents an acid dissociable group; Y² represents a divalent linking group; and X² represents an acid dissociable group.

In general formula (a1-0-1), the alkyl group and the halogenated alkyl group for R are respectively the same as defined for the alkyl group and the halogenated alkyl group for the substituent which may be bonded to the carbon atom on the α-position of the aforementioned α-position substituted acrylate ester. R is preferably a hydrogen atom, an alkyl group of 1 to 5 carbon atoms or a fluorinated alkyl group of 1 to 5 carbon atoms, and most preferably a hydrogen atom or a methyl group.

X¹ is not particularly limited as long as it is an acid dissociable group. Examples thereof include the aforementioned tertiary alkyl ester-type acid dissociable groups and acetal-type acid dissociable groups, and tertiary alkyl ester-type acid dissociable groups are preferable.

In general formula (a1-0-2), R is the same as defined above.

X² is the same as defined for X¹ in general formula (a1-0-1).

The divalent linking group for Y² is not particularly limited, and preferable examples thereof include a divalent hydrocarbon group which may have a substituent and a divalent linking group containing a hetero atom.

A hydrocarbon “has a substituent” means that part or all of the hydrogen atoms within the hydrocarbon group is substituted with a substituent (a group or an atom other than hydrogen).

The hydrocarbon group may be an aliphatic hydrocarbon group or an aromatic hydrocarbon group.

An “aliphatic hydrocarbon group” refers to a hydrocarbon group that has no aromaticity.

The divalent aliphatic hydrocarbon group as the divalent hydrocarbon group for Y² may be either saturated or unsaturated. In general, the divalent aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent. Examples of the substituent include a fluorine atom, a fluorinated alkyl group of 1 to 5 carbon atoms, and an oxygen atom (═O).

As examples of the hydrocarbon group containing a ring in the structure thereof, an alicyclic hydrocarbon group (a group in which two hydrogen atoms have been removed from an aliphatic hydrocarbon ring), a group in which the alicyclic hydrocarbon group is bonded to the terminal of the aforementioned chain-like aliphatic hydrocarbon group, and a group in which the alicyclic group is interposed within the aforementioned linear or branched aliphatic hydrocarbon group, can be given. As the linear or branched aliphatic hydrocarbon group, the same groups as those described above can be used.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic group, a group in which two hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The alicyclic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

The aromatic hydrocarbon group is a hydrocarbon group having an aromatic ring.

The aromatic hydrocarbon group as the divalent hydrocarbon group for Y² preferably has 5 to 30, more preferably 5 to 20, still more preferably 6 to 15, and most preferably 6 to 10 carbon atoms. Here, the number of carbon atoms within a substituent(s) is not included in the number of carbon atoms of the aromatic hydrocarbon group.

Specific examples of the aromatic ring within the aromatic hydrocarbon group include an aromatic hydrocarbon ring such as benzene, biphenyl, fluorene, naphthalene, anthracene, phenanthrene, and an aromatic hetero ring in which part of the carbon atoms constituting the aromatic hydrocarbon ring has been substituted with a heteroatom. As examples of the heteroatom of the aromatic hetero ring, an oxygen atom, a sulfur atom and a nitrogen atom can be given.

Specific examples of aromatic hydrocarbon groups include a group (arylene group) which is the aromatic hydrocarbon ring having two hydrogen atom removed therefrom, and a group (for example, a group in which one hydrogen atom of the aryl group of an arylalkyl group such as a benzyl group, a phenethyl group, a 1-naphthylmethyl group, a 2-naphthylmethyl group, a 1-naphthylethyl group or a 2-naphthylethyl group further has been removed) in which one hydrogen atom of a group (aryl group) which is the aromatic hydrocarbon ring having one hydrogen atom removed therefrom has been substituted with an alkylene group. The alkylene group (an alkyl chain within an arylalkyl group) preferably has 1 to 4 carbon atoms, more preferably 1 or 2, and most preferably 1.

The aromatic hydrocarbon group may or may not have a substituent. For example, a hydrogen atom bonded to the aromatic hydrocarbon ring within the aromatic hydrocarbon group may be substituted with a substituent. As the substituent, an alkyl group, an alkoxy group, a halogen atom, a halogenated alkyl group, a hydroxyl group, an oxygen atom (═O) or the like can be used.

The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent for is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

An example of the halogenated alkyl group as the substituent includes a group in which part or all of the hydrogen atoms within the aforementioned alkyl group have been substituted with the aforementioned halogen atoms.

With respect to a “divalent linking group containing a hetero atom” for Y², a hetero atom is an atom other than carbon and hydrogen, and examples thereof include an oxygen atom, a nitrogen atom, a sulfur atom and a halogen atom.

Examples of the divalent linking group containing a hetero atom include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O—, —NH—C(═O)—, ═N—, and a group represented by general formula —Y²¹—O—Y²²—, —[Y²¹—C(═O)—O]_{m′}—Y²²— or —Y²¹—O—C(═O)—Y²²— [wherein Y²¹ and Y²² each independently represent a divalent hydrocarbon group which may have a substituent, O represents an oxygen atom, and m′ represents an integer of 0 to 3.]

When Y² represents —NH—, H may be substituted with a substituent such as an alkyl group, an acyl group or the like. The substituent (an alkyl group, an acyl group or the like) preferably has 1 to 10 carbon atoms, more preferably 1 to 8, and most preferably 1 to 5.

In the group represented by the formula —Y²¹—O—Y²²—, —[Y²¹—C(═O)—O]_{m′}—Y²²— or —Y²¹—O—C(═O)—Y²²—, each of Y²¹ and Y²² independently represents a divalent hydrocarbon group which may have a substituent. As the divalent hydrocarbon group, the same groups as those described above for the “divalent hydrocarbon group which may have a substituent” for Y² can be mentioned.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]_{m′}—Y²²—, m′ represents an integer of 0 to 3, preferably an integer of 0 to 2, more preferably 0 or 1, and most preferably 1. Namely, it is particularly desirable that the group represented by the formula —[Y²¹—C(═O)—O]_{m′}—Y²²— is a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

As the divalent linking group containing a hetero atom, a linear group containing an oxygen atom as the hetero atom e.g., a group containing an ether bond or an ester bond is preferable, and a group represented by the aforementioned formula —Y²¹—O—Y²², —[Y²¹—C(═O)—O]_{m′}—Y²²— or —Y²¹—O—C(═O)—Y²²— is more preferable.

Among the aforementioned examples, as the divalent linking group for Y², an alkylene group, a divalent alicyclic hydrocarbon group or a divalent linking group containing a hetero atom is particularly desirable. Among these, an alkylene group or a divalent linking group containing a hetero atom is more preferable.

Specific examples of the structural unit (a1) include structural units represented by general formulae (a1-1) to (a1-4) shown below.

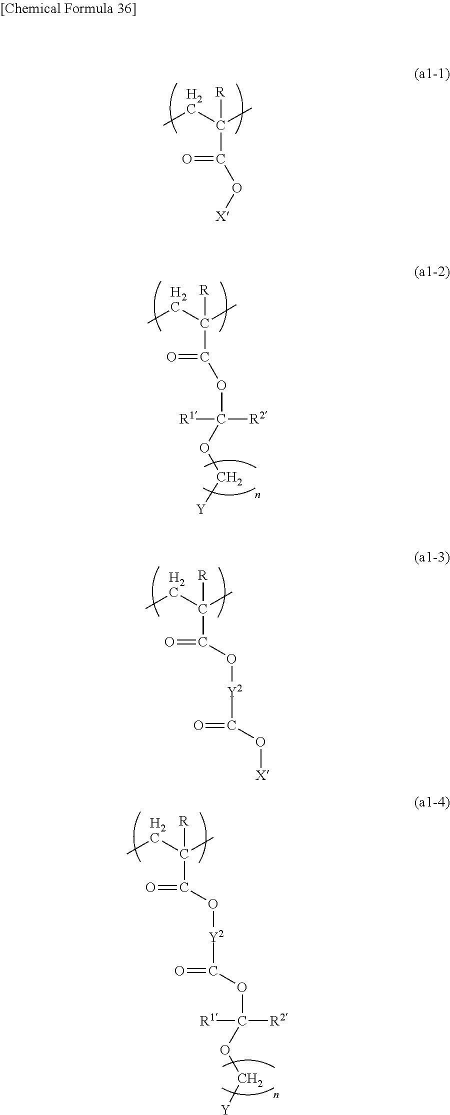

In the formulae, R, R¹′, R²′, n, Y and Y² are the same as defined above; and X′ represents a tertiary alkyl ester-type acid dissociable group.

In the formulae, the tertiary alkyl ester-type acid dissociable group for X′ include the same tertiary alkyl ester-type acid dissociable groups as those described above.

As R¹′, R²′, n and Y are respectively the same as defined for R¹′, R²′, n and Y in general formula (p1) described above in connection with the “acetal-type acid dissociable group”.

As examples of Y², the same groups as those described above for Y² in general formula (a1-0-2) can be given.

Specific examples of structural units represented by general formula (a1-1) to (a1-4) are shown below.

In the formulae shown below, R^{α} represents a hydrogen atom, a methyl group or a trifluoromethyl group.

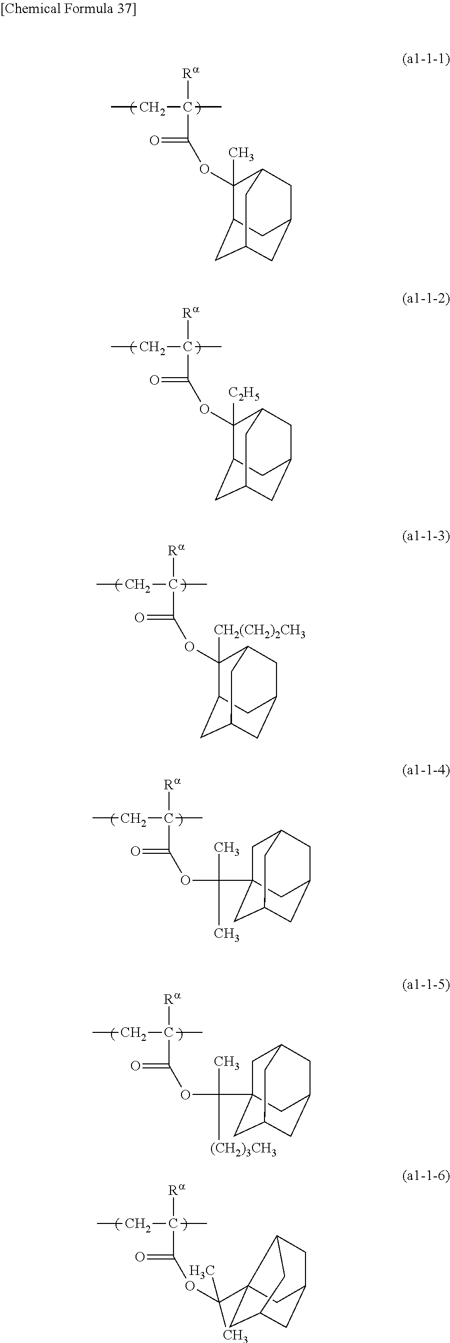

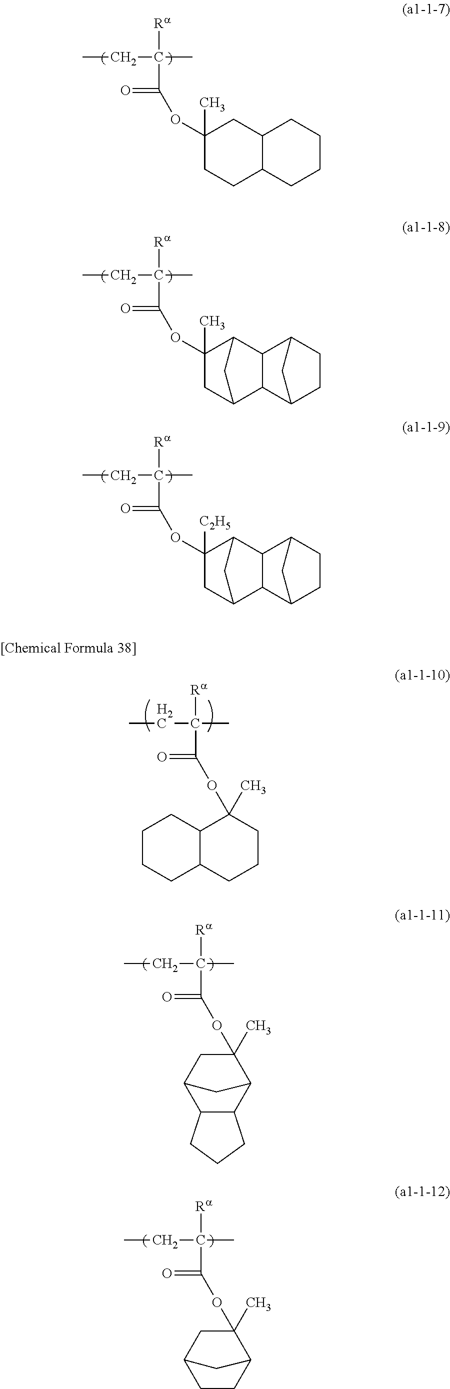

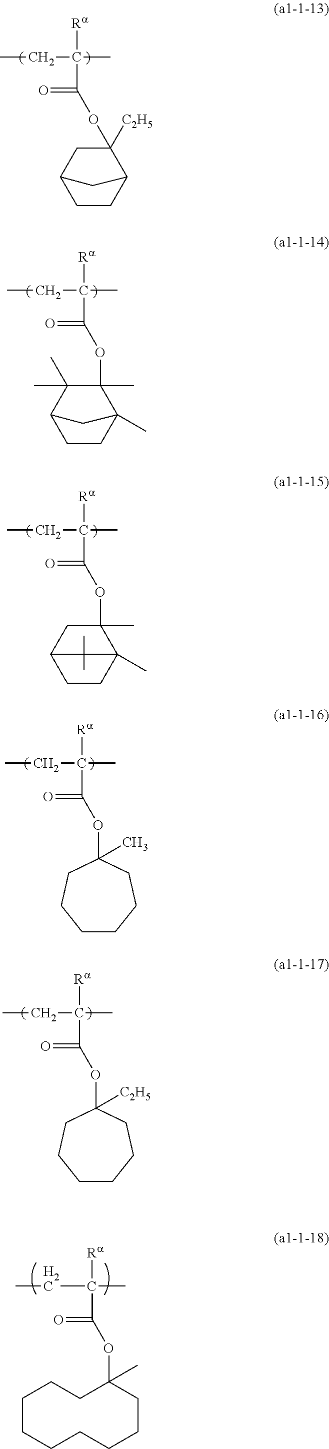

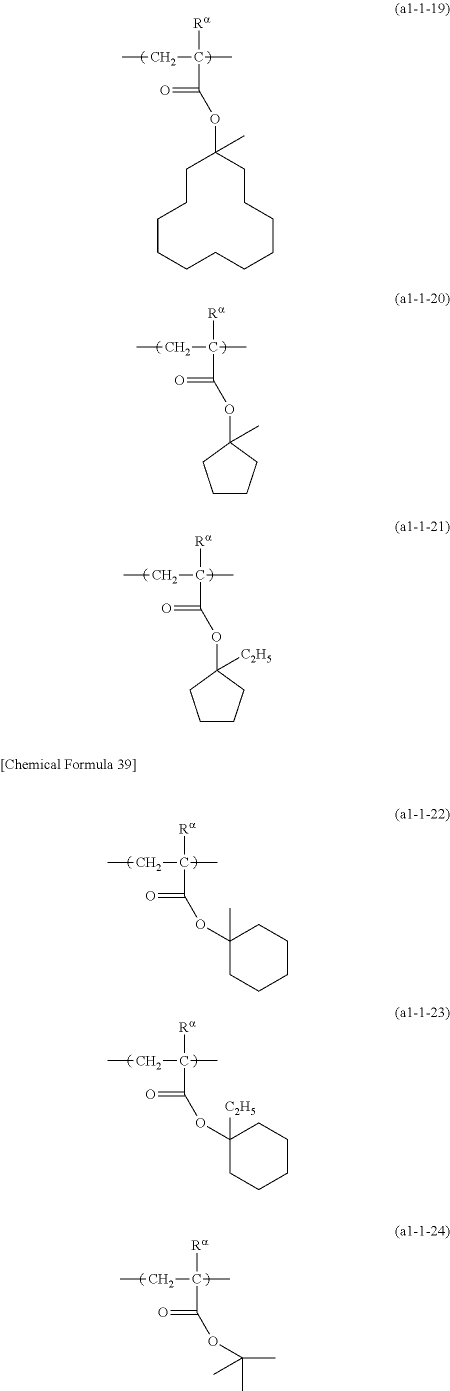

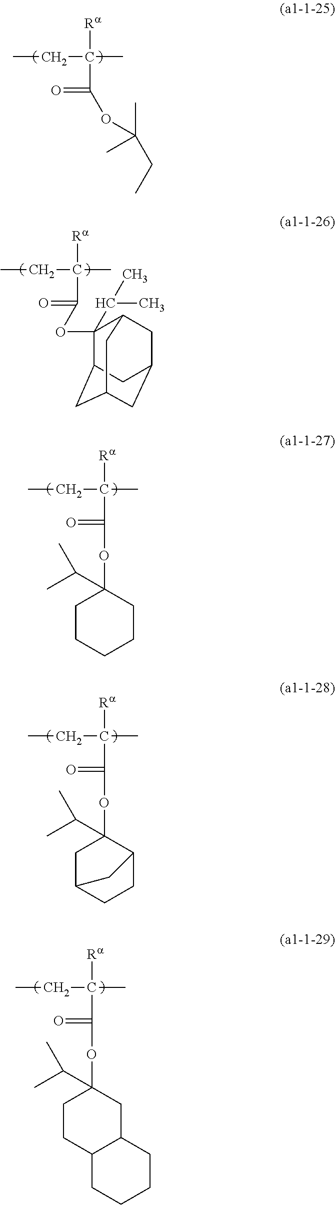

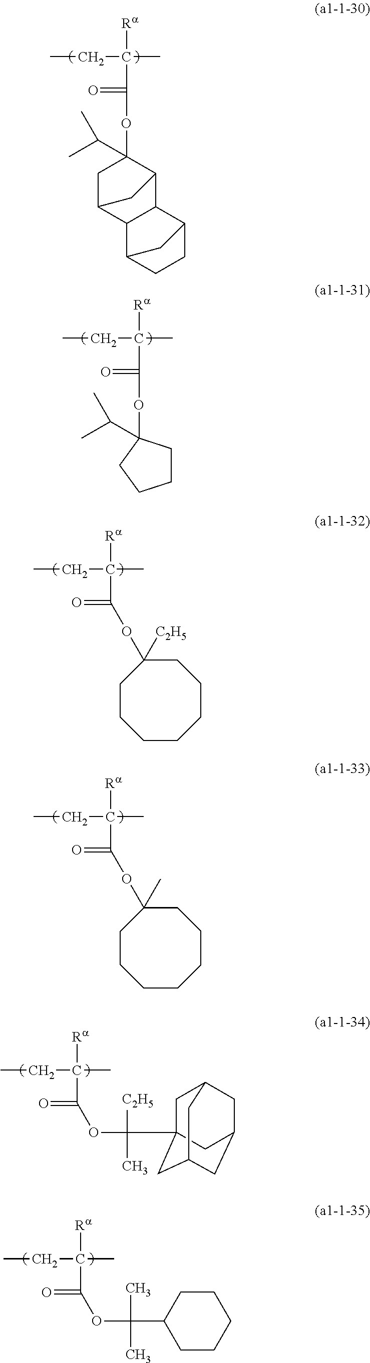

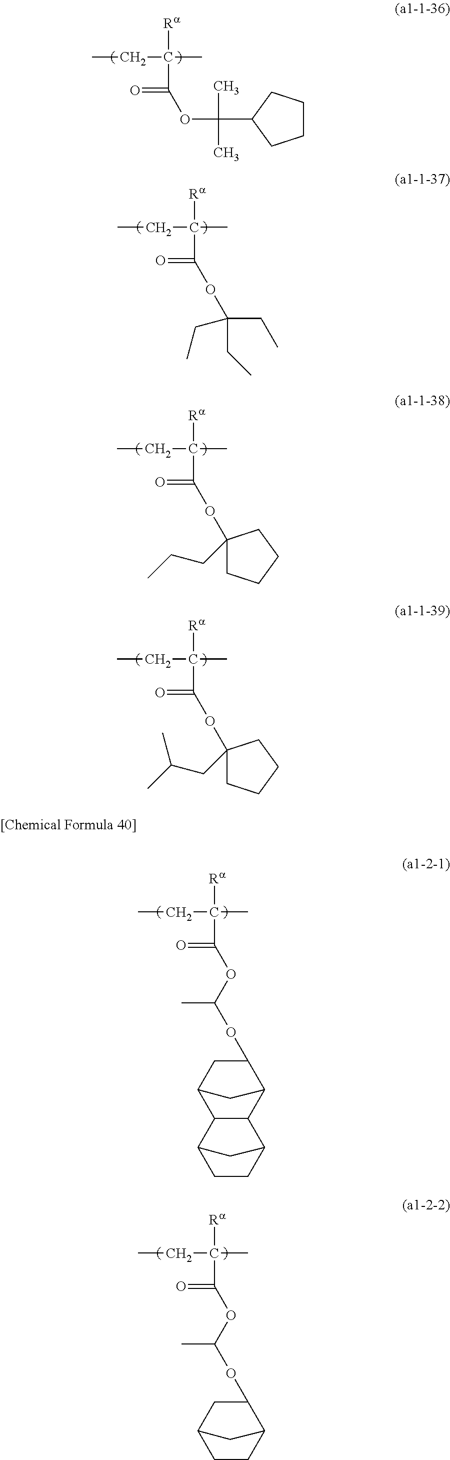

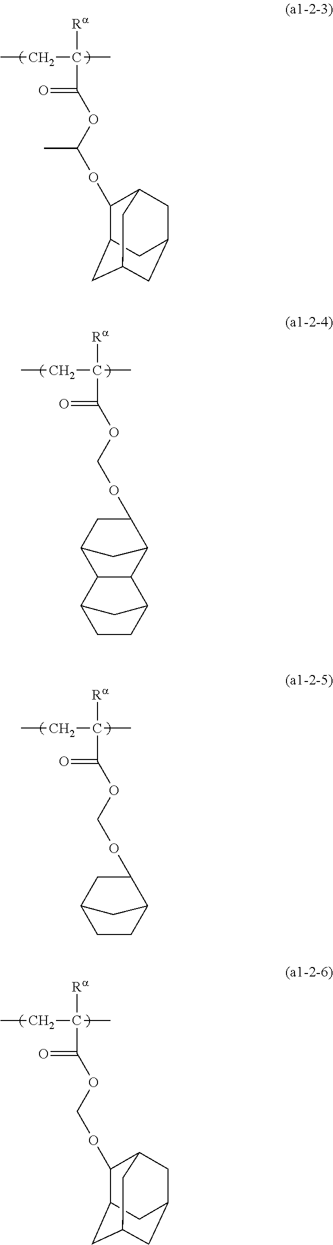

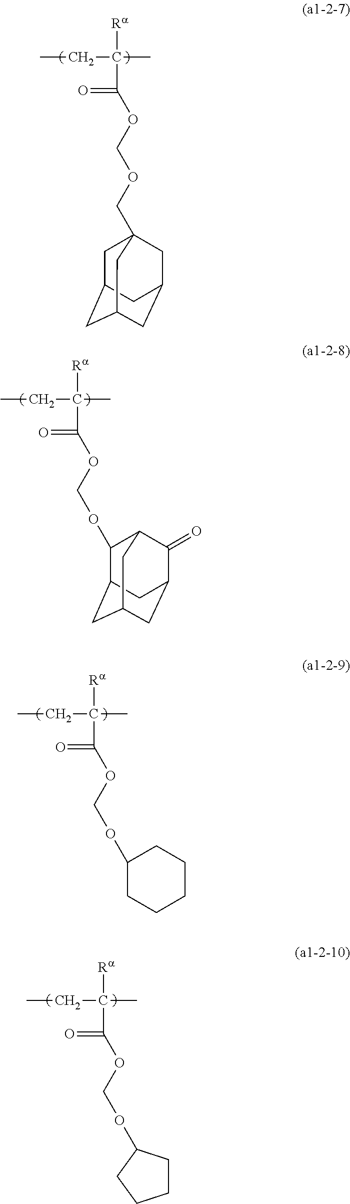

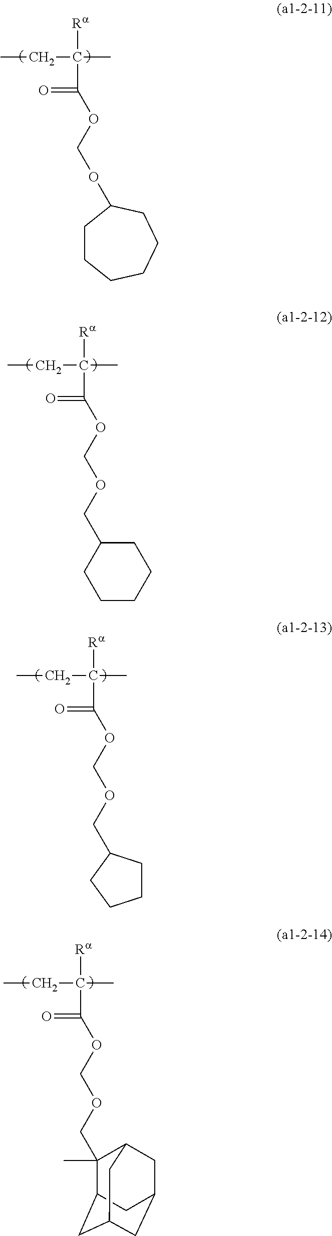

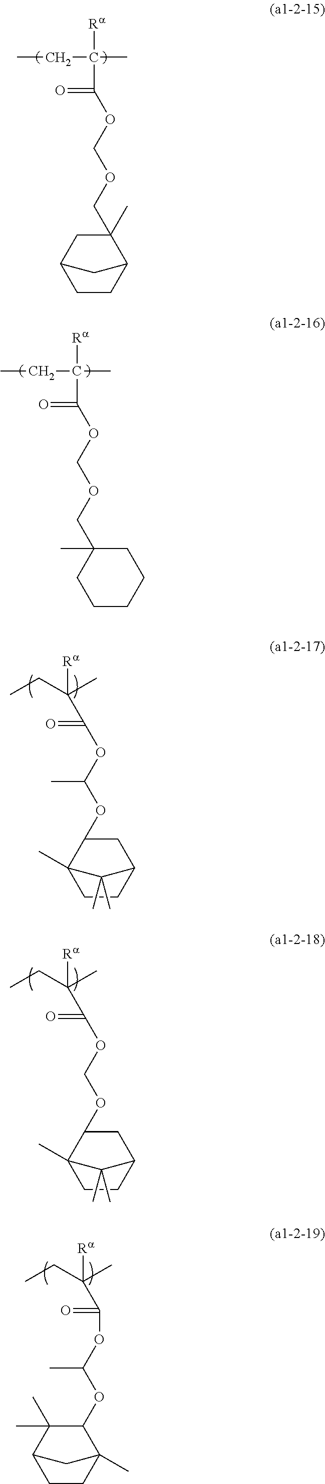

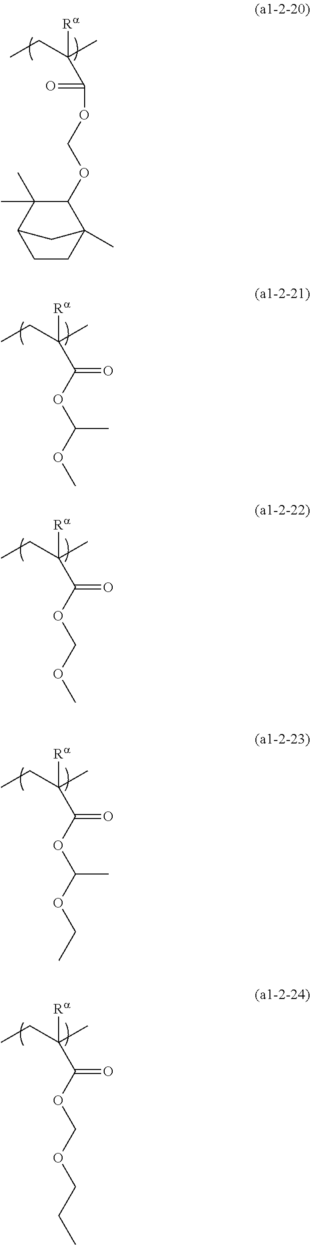

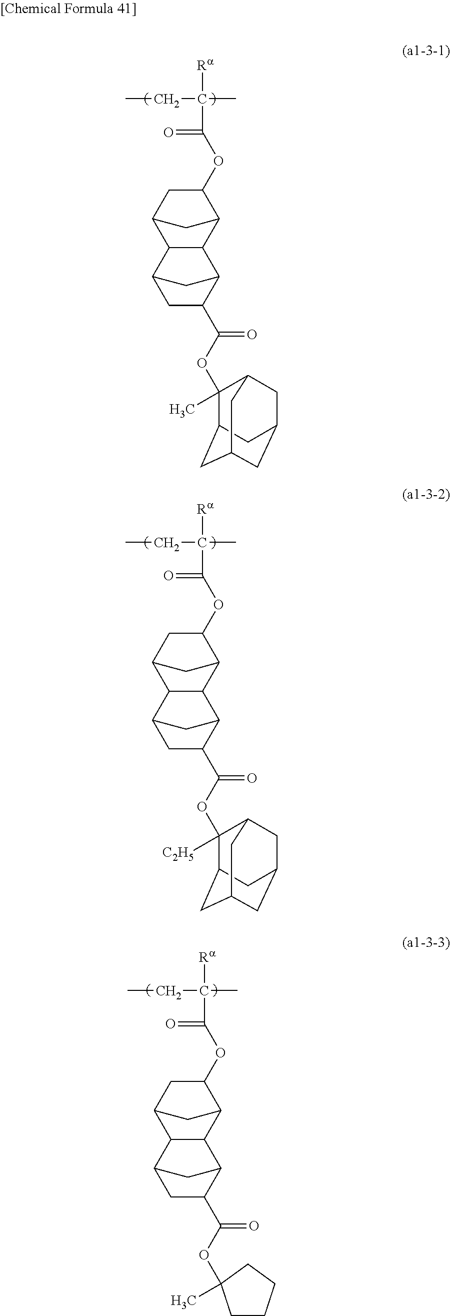

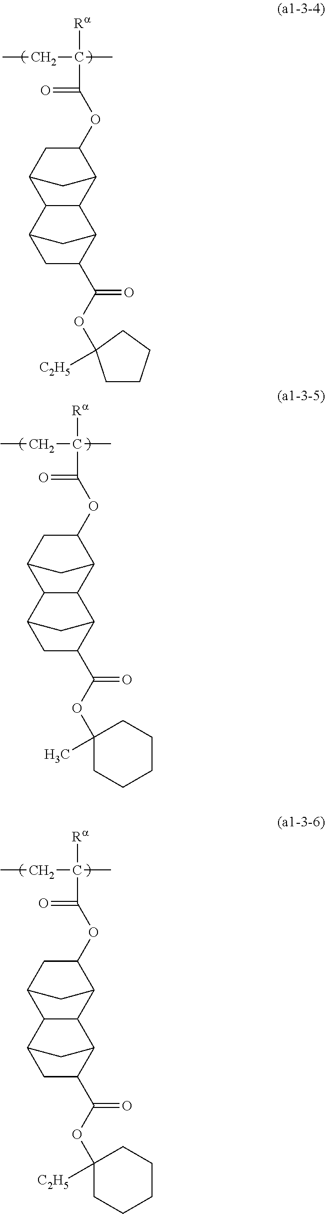

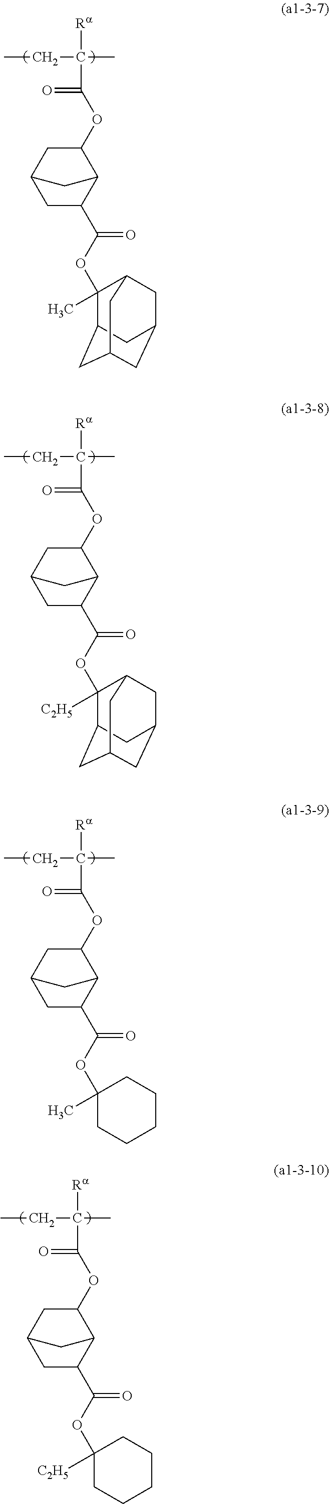

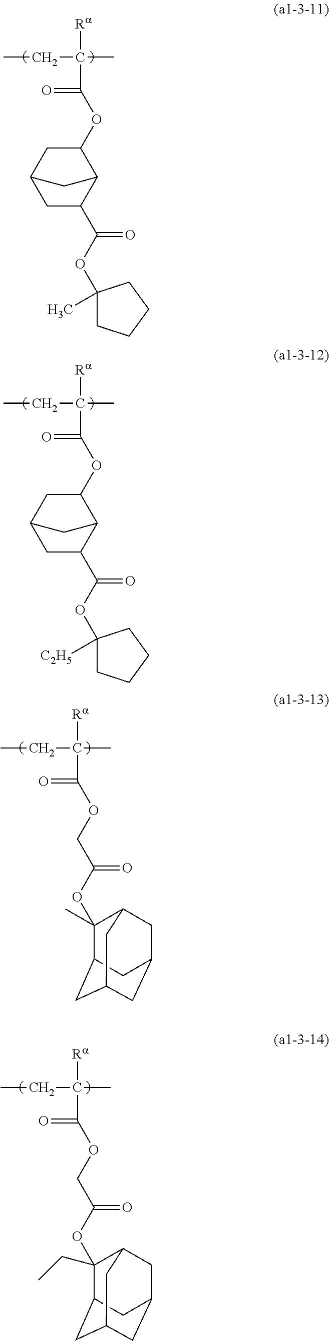

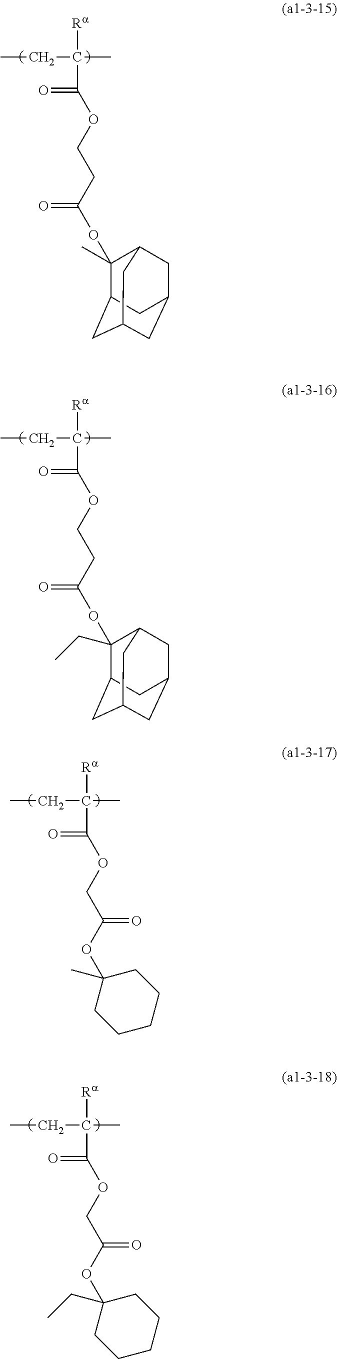

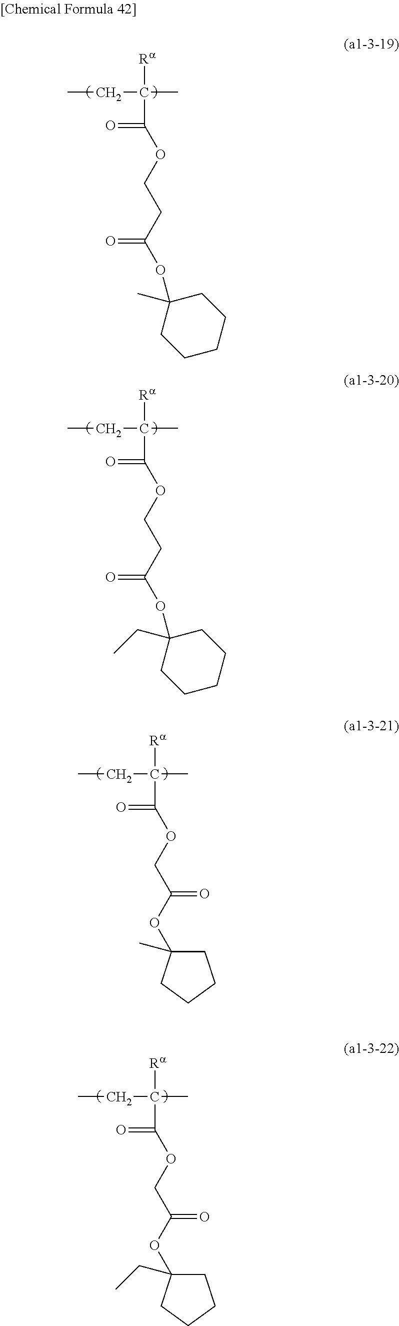

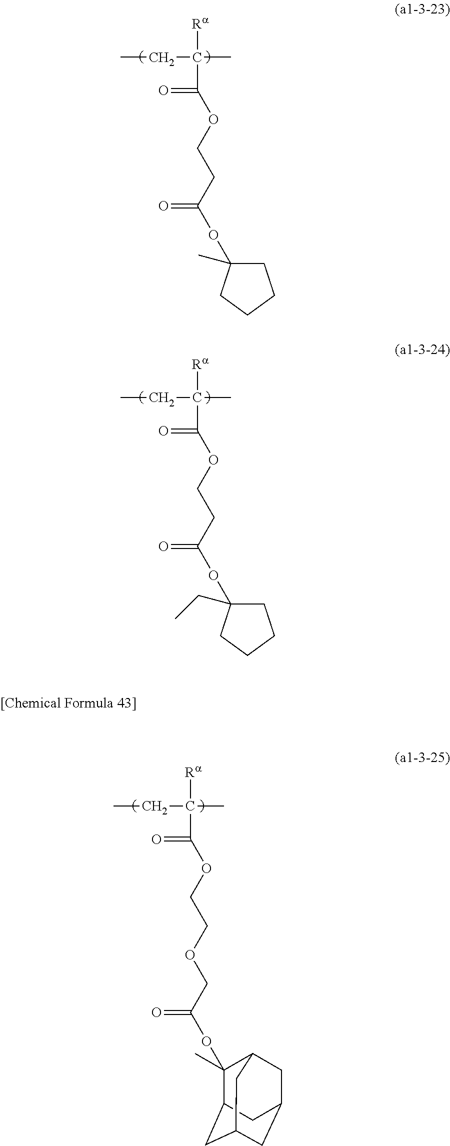

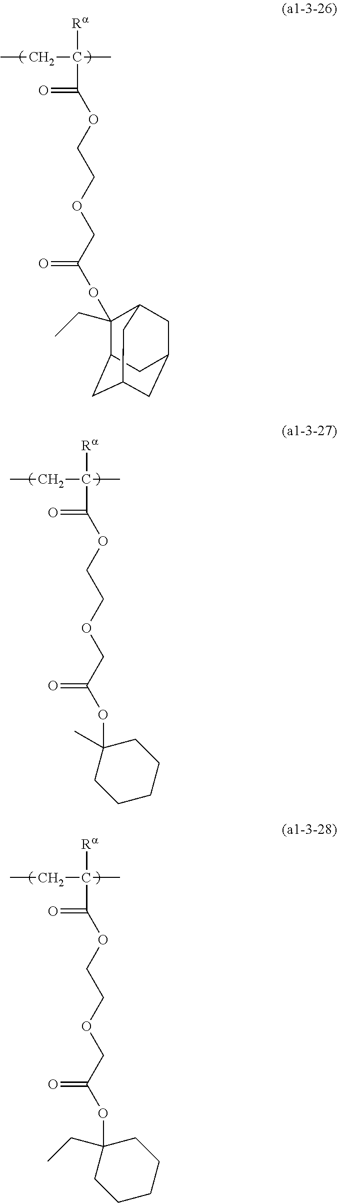

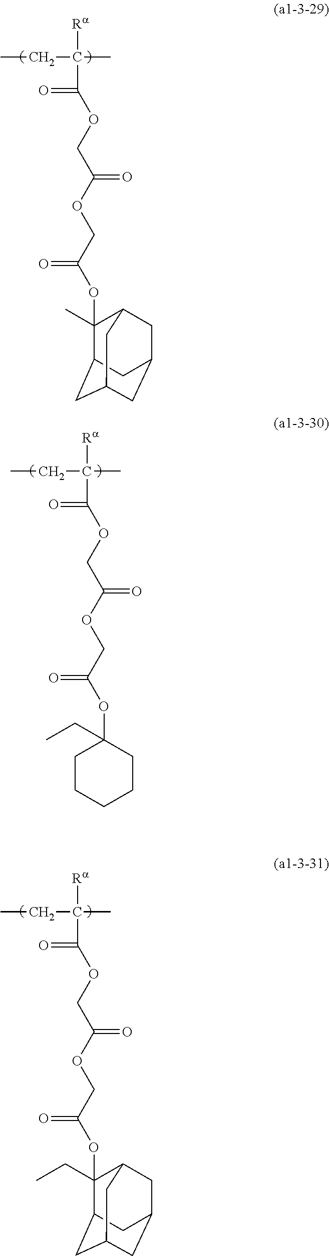

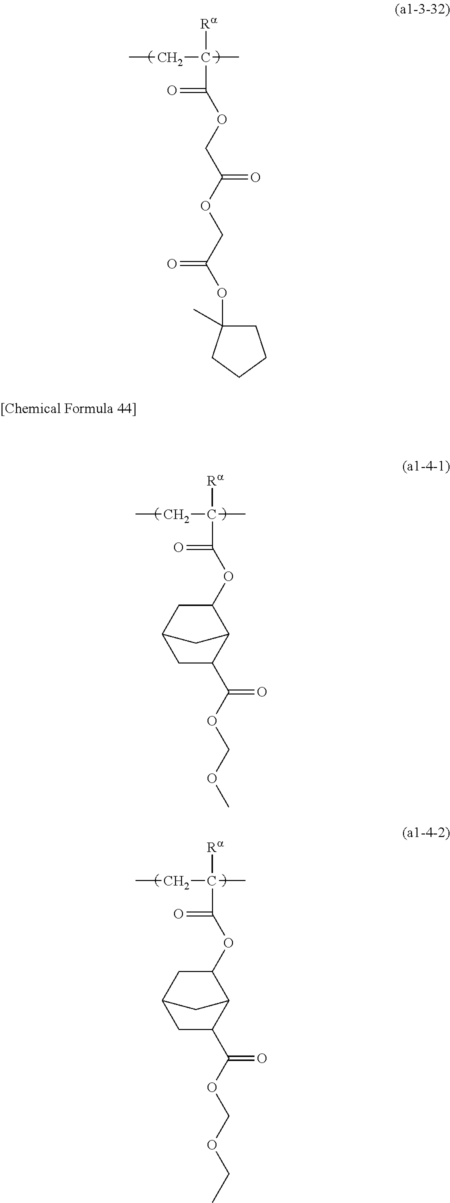

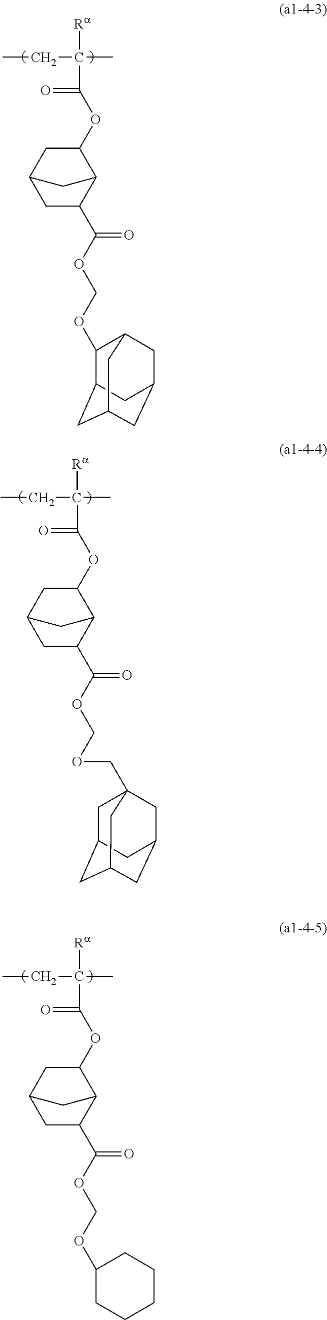

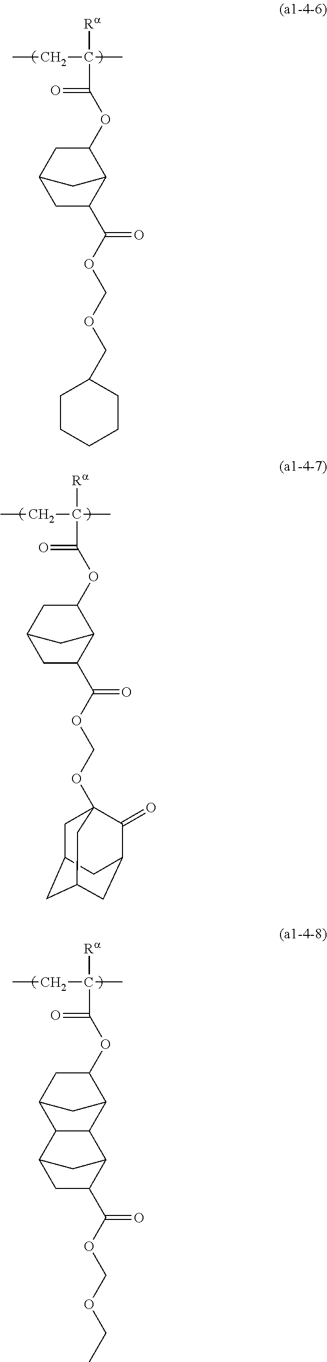

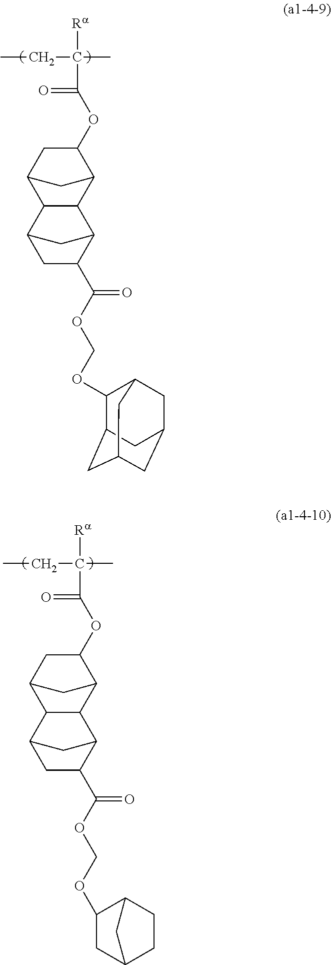

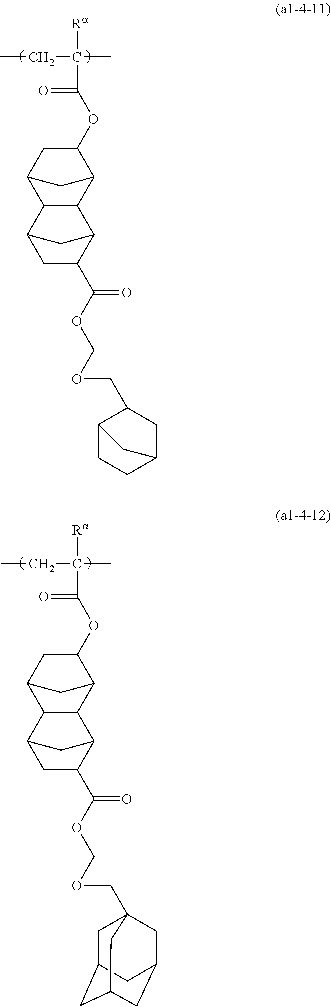

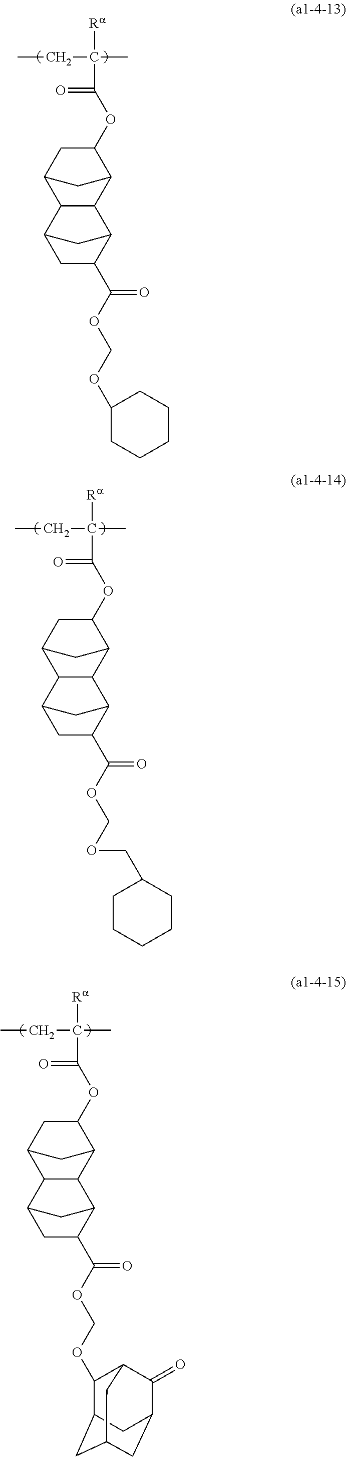

In the present invention, at least one selected from the group consisting of a structural unit represented by the above-described formulae (a1-1-16) to (a1-1-23), (a1-1-27), (a1-1-31) to (a1-1-33), (a1-1-38), or (a1-1-39), a structural unit having a tertiary carbon atom on the aliphatic monocyclic group for X′ in the above-described formula (a1-1); a structural unit represented by the above-described formulae (a1-1-26) or (a1-1-28) to (a1-1-30), a structural unit represented by the above-described formula (a1-1) in which a carbon atom on the aliphatic cyclic group for X′ is a tertiary carbon atom, and a carbon atom constituting the tertiary carbon atom is bonded to a branched alkyl group; a structural unit represented by the above-described formulae (a1-1-1) to (a1-1-3) or (a1-1-7) to (a1-1-15), a structural unit having a tertiary carbon atom on the aliphatic polycyclic group for X′ in the above-described formula (a1-1); and a structural unit represented by the above-described formulae (a1-1-25) to (a1-3-32) is preferably used as the structural unit (a1).

Examples of the structural unit (a1) also include a structural unit in which a hydrogen atom of the hydroxyl group of the structural unit derived from hydroxystyrene which may have the hydrogen atom bonded to the carbon atom on the α-position substituted with a substituent, and may have the hydrogen atom bonded to the benzene ring substituted with a substituent other than a hydroxyl group is substituted with an acid decomposable group or a substituent containing an acid decomposable group.

The term “hydroxystyrene” refers to the compound in which one vinyl group and at least one hydroxyl group are bonded to a benzene ring. The number of hydroxyl groups bonded to the benzene ring is preferably 1 to 3, and most preferably 1. The position of the benzene ring to which a hydroxyl group is bonded is not particularly limited. When the number of the hydroxyl groups is 1, the para position of the position where a vinyl group is bonded is preferable. When the number of the hydroxyl groups is an integer of two or more, any positions can be used in combination.

Examples of an acid dissociable group that substitutes for a hydrogen atom of the hydroxyl group include the same groups as those described above, and among them, tertiary alkyl ester-type acid dissociable groups are preferable, and acetal-type acid dissociable groups are more preferable.

Examples of a substituent containing the acid dissociable group include a group composed of the acid dissociable group and a divalent linking group. Examples of the divalent linking group include the same divalent linking groups for Q² in the formula (I) described above, and among them, a group having a carbonyloxy group on its terminal on the acid dissociable group-side is preferable. In this case, the acid dissociable group is preferably bonded to an oxygen atom (—O—) of the carbonyloxy group.

A group represented by the formula R¹¹′-O—C(═O)—, or a group represented by the formula R¹¹′—O—C(═O)—R¹²′— are preferable as the substituent containing the acid dissociable group. In the formulae, R¹¹′ represents an acid dissociable group, and R¹²′ represents a linear or branched alkylene group.

As the acid dissociable group for R¹¹′, a tertiary alkyl ester-type acid dissociable group or an acetal-type acid dissociable group is preferable, and a tertiary alkyl ester-type acid dissociable group is more preferable. Preferable examples of the tertiary alkyl ester-type acid dissociable group include an aliphatic branched, acid dissociable group represented by the aforementioned formula —C(R⁷¹)(R⁷²)(R⁷³), a group represented by the formulae (1-1) to (1-9), and a group represented by the formulae (2-1) to (2-6).

Examples of an alkylene group for R¹²′ include a methylene group, an ethylene group, trimethylene group, a tetramethylene group, and 1,1-dimethylethylene group. A linear alkylene group is preferable or R¹²′.

Examples of the structural unit (a1) also include a structural unit in which a hydrogen atom of the hydroxyl group of the structural unit derived from vinyl(hydroxynaphthalene) which may have the hydrogen atom bonded to the carbon atom on the α-position substituted with a substituent, and may have the hydrogen atom bonded to the naphthalene ring substituted with a substituent other than a hydroxyl group is substituted with an acid decomposable group or a substituent containing an acid decomposable group.

The term “vinyl(hydroxynaphthalene)” refers to the compound in which one vinyl group and at least one hydroxyl group are bonded to a naphthalene ring. The vinyl group may be bonded to either the 1st position or the 2nd position of the naphthalene ring. The number of hydroxyl groups bonded to the naphthalene ring is preferably 1 to 3, and most preferably 1. The position of the naphthalene ring to which a hydroxyl group is bonded is not particularly limited. When the vinyl group is bonded to either the 1st position or the 2nd position of the naphthalene ring, any of the 5th to 8th positions are preferable. In particular, when the number of the hydroxyl groups is 1, any of the 5th to 7th positions are preferable, and either the 5th or 6th position is more preferable. When the number of the hydroxyl groups is an integer of two or more, any positions can be used in combination.

Examples of each of an acid dissociable group that substitutes for a hydrogen atom of the hydroxyl group and a substituent containing the acid dissociable group include the same groups as described above for an acid dissociable group that substitutes for a hydrogen atom of the hydroxyl group in the structural unit derived from hydroxystyrene and the substituent containing the acid dissociable group, respectively.

As the structural unit (a1) contained in the component (A1), 1 type of structural unit may be used, or 2 or more types may be used.

In the component (A1), the amount of the structural unit (a1) based on the combined total of all structural units constituting the component (A1) is preferably 15 to 70 mol %, more preferably 15 to 60 mol %, still more preferably 20 to 55 mol %.

When the amount of the structural unit (a1) is at least as large as the lower limit, a resist pattern is easily obtained when the resist composition is made, and lithography properties such as sensitivity, resolution, and roughness are further improved. On the other hand, when the amount of the structural unit (a1) is no more than the upper limit of the above-mentioned range, a good balance can be reliably achieved with the other structural units.

[Structural unit (a2)]

In addition to the structural unit (a1), the component (A1) preferably further includes the structural unit (a2) which contains an —SO₂— containing cyclic group or a lactone-containing cyclic group.

The —SO₂— containing cyclic group or lactone-containing cyclic group in the structural unit (a2) is useful to improve the adhesion of a resist film to a substrate, when the component (A1) is used for forming of the resist film. Also, it is useful in an alkali developing process for increasing the compatibility with a water-containing developing solution such as an alkali developing solution.

—SO₂— Containing Cyclic Group

Here, an “—SO₂— containing cyclic group” refers to a cyclic group having a ring containing —SO₂— within the ring structure thereof, i.e., a cyclic group in which the sulfur atom (S) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂— containing cyclic group may be either a monocyclic group or a polycyclic group.

As the —SO₂— containing cyclic group, a cyclic group containing —O—SO₂— within the ring skeleton thereof, i.e., a cyclic group containing a sultone ring in which —O—S— within the —O—SO₂— group forms part of the ring skeleton is particularly desirable.

The —SO₂— containing cyclic group preferably has 3 to 30 carbon atoms, more preferably 4 to 20, still more preferably 4 to 15, and most preferably 4 to 12. Herein, the number of carbon atoms refers to the number of carbon atoms constituting the ring skeleton, excluding the number of carbon atoms within a substituent.

The —SO₂— containing cyclic group may be either a —SO₂— containing aliphatic cyclic group or a —SO₂— containing aromatic cyclic group. A —SO₂— containing aliphatic cyclic group is preferable.

Examples of the —SO₂— containing aliphatic cyclic group include aliphatic cyclic groups in which part of the carbon atoms constituting the ring skeleton has been substituted with a —SO₂— group or a —O—SO₂— group and has at least one hydrogen atom removed from the aliphatic hydrocarbon ring. Specific examples include an aliphatic hydrocarbon ring in which a —CH₂— group constituting the ring skeleton thereof has been substituted with a —SO₂— group and has at least one hydrogen atom removed therefrom; and an aliphatic hydrocarbon ring in which a —CH₂—CH₂— group constituting the ring skeleton has been substituted with a —O—SO₂— group and has at least one hydrogen atom removed therefrom.

The alicyclic hydrocarbon ring preferably has 3 to 20 carbon atoms, and more preferably has 3 to 12 carbon atoms.

The alicyclic hydrocarbon ring may be either a monocyclic group or a polycyclic group. As the monocyclic aliphatic hydrocarbon ring, a group in which two hydrogen atoms have been removed from a monocycloalkane of 3 to 6 carbon atoms is preferable, and examples of the monocycloalkane include cyclopentane and cyclohexane. As the polycyclic ring, a group in which two hydrogen atoms have been removed from a polycycloalkane of 7 to 12 carbon atoms is preferable, and specific examples of the polycycloalkane include adamantane, norbornane, isobornane, tricyclodecane and tetracyclododecane.

The —SO₂— containing cyclic group may have a substituent. Examples of the substituent include an alkyl group, an alkoxy group, a halogen atom, a halogenated alkyl group, a hydroxy group, an oxygen atom (═O), —COOR″, —OC(═O)R″, a hydroxyalkyl group and a cyano group.

The alkyl group for the substituent is preferably an alkyl group of 1 to 6 carbon atoms. Further, the alkyl group is preferably a linear alkyl group or a branched alkyl group. Specific examples include a methyl group, an ethyl group, a propyl group, an isopropyl group, an n-butyl group, an isobutyl group, a tert-butyl group, a pentyl group, an isopentyl group, a neopentyl group and a hexyl group. Among these, a methyl group or ethyl group is preferable, and a methyl group is particularly desirable.

The alkoxy group for the substituent is preferably an alkoxy group of 1 to 6 carbon atoms. The alkoxy group is preferably a linear or branched group. Specific examples include groups in which an oxygen atom (—O—) is bonded to any of the alkyl groups described above as the substituent.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups have been substituted with the aforementioned halogen atoms.

As examples of the halogenated lower alkyl group for the substituent, groups in which part or all of the hydrogen atoms of the aforementioned alkyl groups for the substituent have been substituted with the aforementioned halogen atoms can be given. As the halogenated alkyl group, a fluorinated alkyl group is preferable, and a perfluoroalkyl group is particularly desirable.

In the —COOR″ group and the —OC(═O)R″ group, R″ represents a hydrogen atom or a linear, branched or cyclic alkyl group of 1 to 15 carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The hydroxyalkyl group for the substituent preferably has 1 to 6 carbon atoms, and specific examples thereof include the aforementioned alkyl groups for the substituent in which at least one hydrogen atom has been substituted with a hydroxy group.

More specific examples of the —SO₂— containing cyclic group include groups represented by general formulas (3-1) to (3-4) shown below.

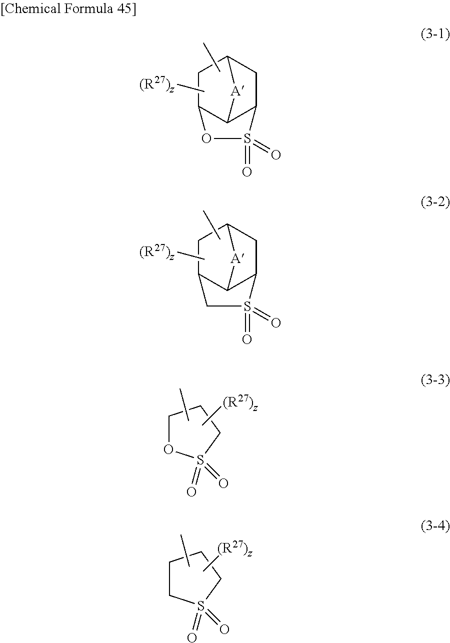

In the formulas, A′ represents an oxygen atom, a sulfur atom or an alkylene group of 1 to 5 carbon atoms which may contain an oxygen atom or a sulfur atom; z represents an integer of 0 to 2; and R²⁷ represents an alkyl group, an alkoxy group, a halogenated alkyl group, a hydroxyl group, —COOR″, —OC(═O)R″, a hydroxyalkyl group or a cyano group, wherein R″ represents a hydrogen atom or an alkyl group.

In general formulas (3-1) to (3-4) above, A′ represents an oxygen atom (—O—), a sulfur atom (—S—) or an alkylene group of 1 to 5 carbon atoms which may contain an oxygen atom or a sulfur atom.

As the alkylene group of 1 to 5 carbon atoms represented by A′, a linear or branched alkylene group is preferable, and examples thereof include a methylene group, an ethylene group, an n-propylene group and an isopropylene group.

Examples of alkylene groups that contain an oxygen atom or a sulfur atom include the aforementioned alkylene groups in which —O— or —S— is bonded to the terminal of the alkylene group or present between the carbon atoms of the alkylene group. Specific examples of such alkylene groups include —O—CH₂—, —CH₂—O—CH₂—, —S—CH₂—, —CH₂—S—CH₂—.

As A′, an alkylene group of 1 to 5 carbon atoms or —O— is preferable, more preferably an alkylene group of 1 to 5 carbon atoms, and most preferably a methylene group.

z represents an integer of 0 to 2, and is most preferably 0.

When z is 2, the plurality of R²⁷ may be the same or different from each other.

As the alkyl group, alkoxy group, halogenated alkyl group, —COOR″, —OC(═O)R″ and hydroxyalkyl group for R²⁷, the same alkyl groups, alkoxy groups, halogenated alkyl groups, —COOR″, —OC(═O)R″ and hydroxyalkyl groups as those described above as the substituent for the —SO₂— containing cyclic group can be mentioned.

Specific examples of the cyclic groups represented by general formulas (3-1) to (3-4) are shown below. In the formulas shown below, “Ac” represents an acetyl group.

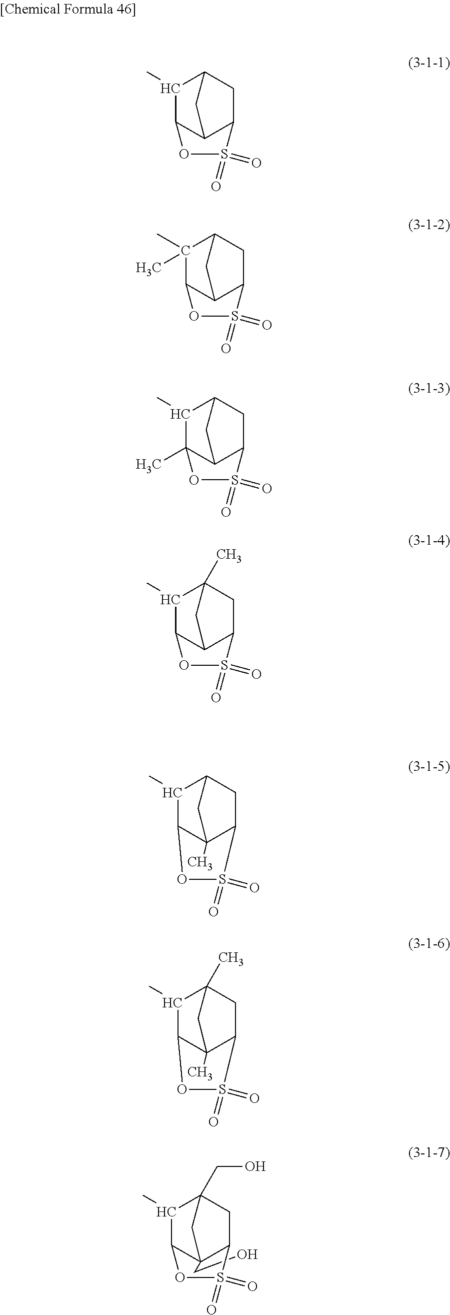

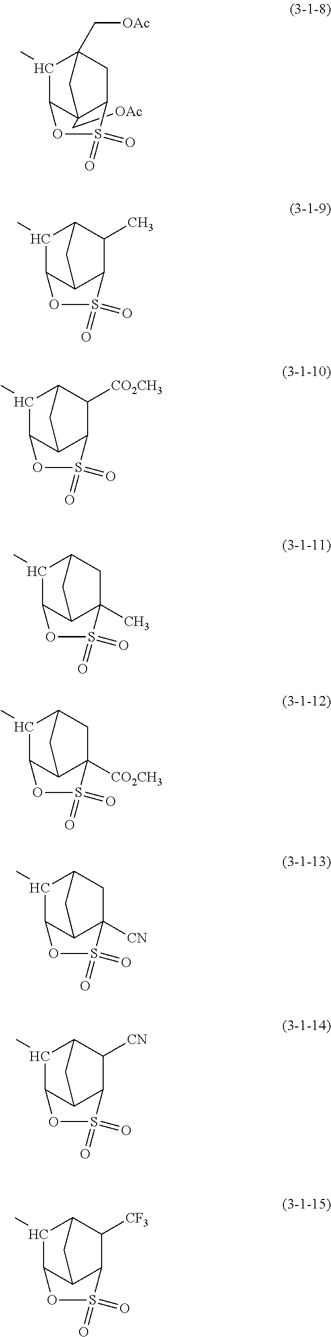

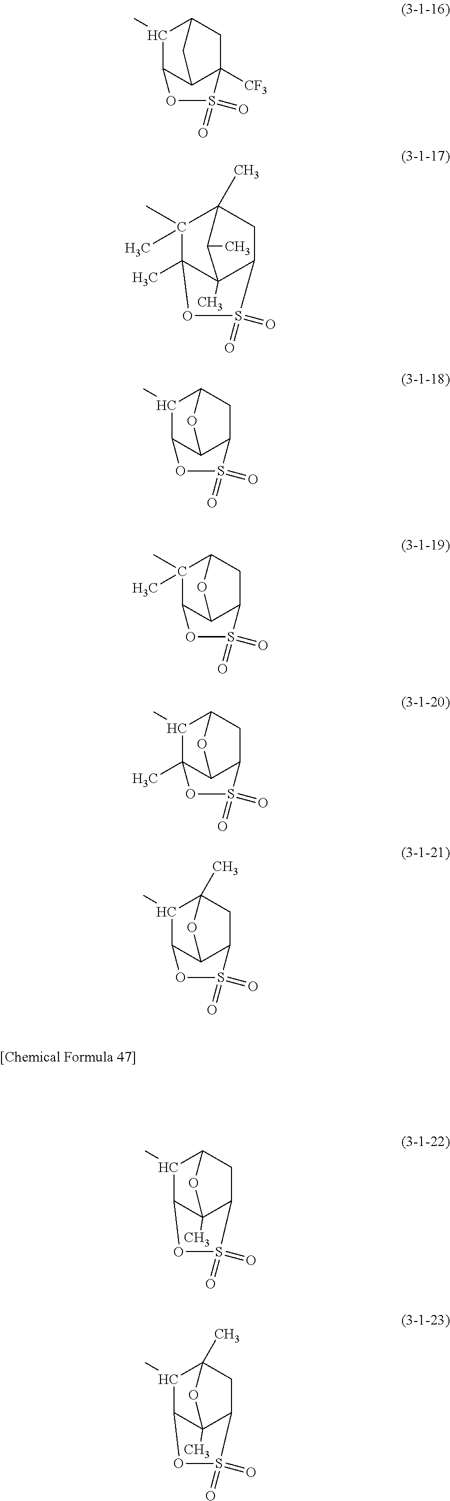

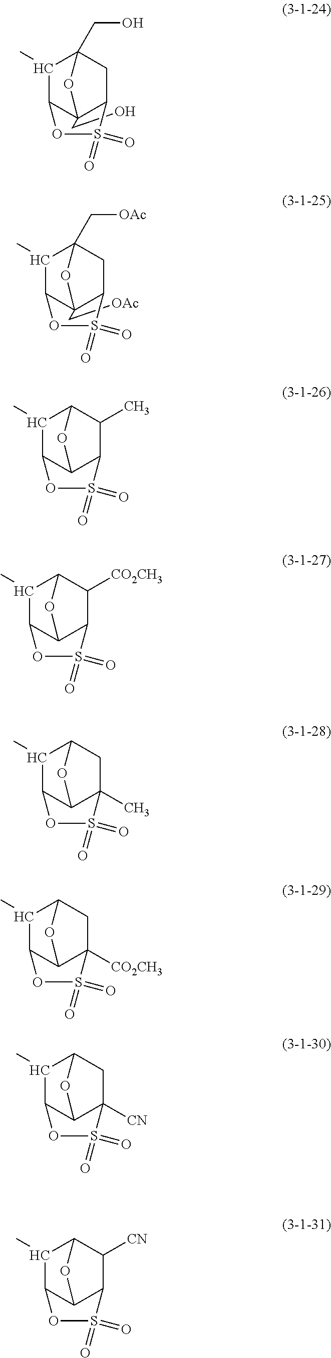

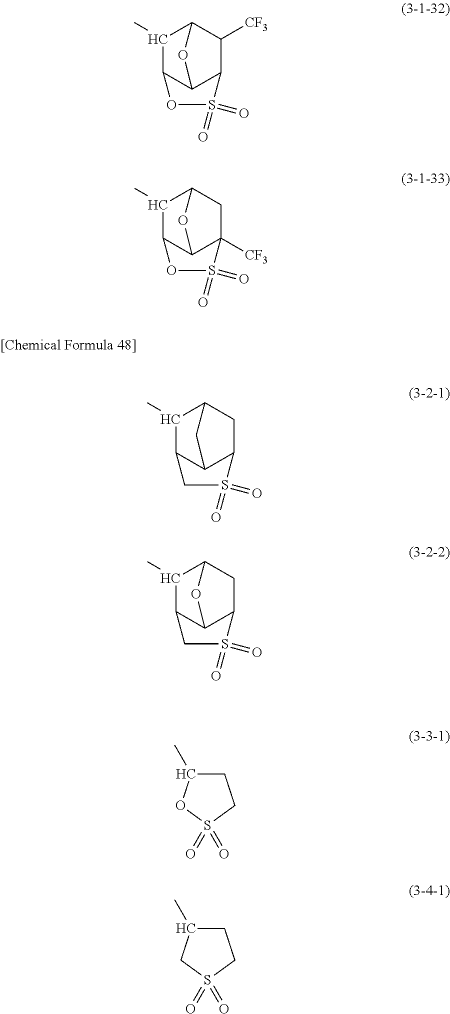

Among those described above, as the —SO₂— containing cyclic group, a group represented by above-described general formulae (3-1), (3-3), or (3-4) is preferable, at least any one group selected from the group consisting of the groups represented by the above-described chemical formulae (3-1-1), (3-1-18), (3-3-1), and (3-4-1) is more preferable, and a group represented by above-described chemical formula (3-1-1) is most preferable.

### Lactone-Containing Cyclic Group

The term “lactone-containing cyclic group” refers to a cyclic group including a ring containing a —O—C(O)— structure (lactone ring). The term “lactone ring” refers to a single ring containing a —O—C(O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

As the lactone-containing cyclic group in the structural unit (a2), there is no particular limitation, and any structural unit may be used. Specific examples of lactone-containing monocyclic groups include a group in which one hydrogen atom has been removed from a 4- to 6-membered lactone ring, such as a group in which one hydrogen atom has been removed from β-propionolatone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

More specific examples of the lactone-containing cyclic group include groups represented by the following general formulae (4-1) to (4-7).

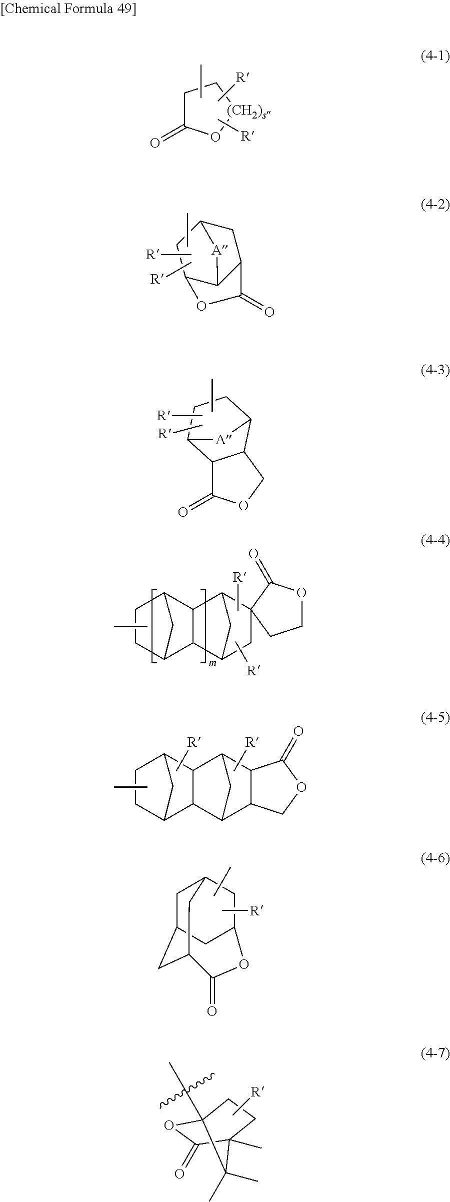

In the formula, R′ represents a hydrogen atom, an alkyl group, an alkoxy group, a halogen atom, a halogenated alkyl group, a hydroxyl group, an oxygen atom (═O), —COOR″, —OC(═O)R″, a hydroxyalkyl group, or a cyano group, R″ represents a hydrogen atom or an alkyl group; s″ represents an integer of 0, or 1 to 2; A″ represents an alkylene group having 1 to 5 carbon atoms, which may contain an oxygen atom or a sulfur atom, an oxygen atom, or a sulfur atom; and m represents an integer of 0 or 1.

Examples of an alkyl group, an alkoxy group, a halogen atom, a halogenated alkyl group, —COOR″, —OC(═O)R″, and a hydroxyalkyl group represented by R′ each include the same alkyl group, alkoxy group, halogen atom, halogenated alkyl group, —COOR″, —OC(═O)R″, hydroxyalkyl group, —COOR″, and —OC(═O)R″ (R″ represents the same as above) described above as examples of the substituent that may be contained in the —SO₂— containing cyclic group.

A″ is preferably an alkylene group of 1 to 5 carbon atoms or an —O—, and more preferably an alkylene group of 1 to 5 carbon atoms, and a methylene group is particularly desirable.

s″ is preferably an integer of 1 or 2.

Specific examples of the cyclic groups represented by the above-described general formulae (4-1) to (4-7) are shown below. Note that the wavy lines in the formula represent atomic bondings.

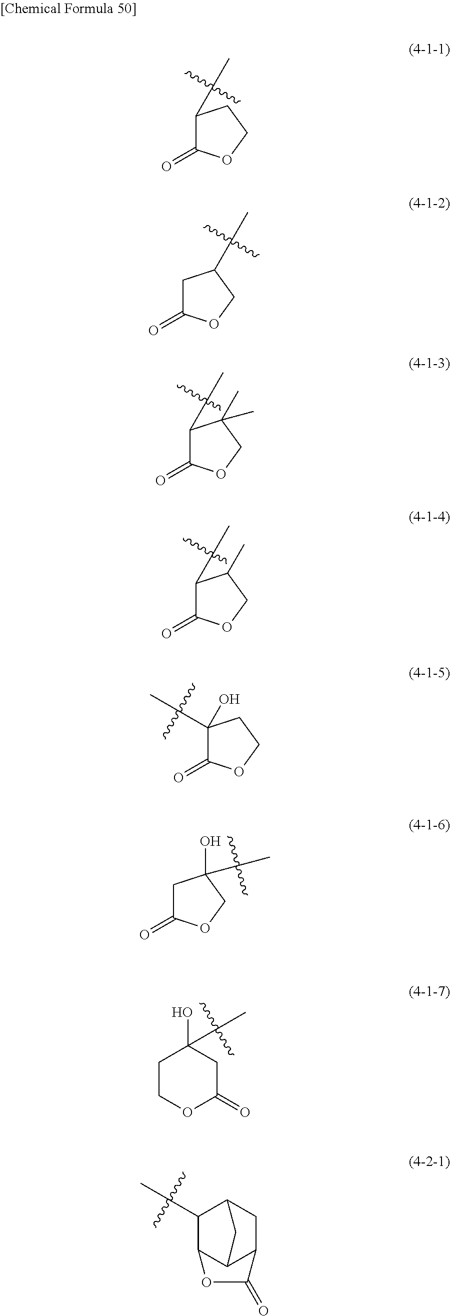

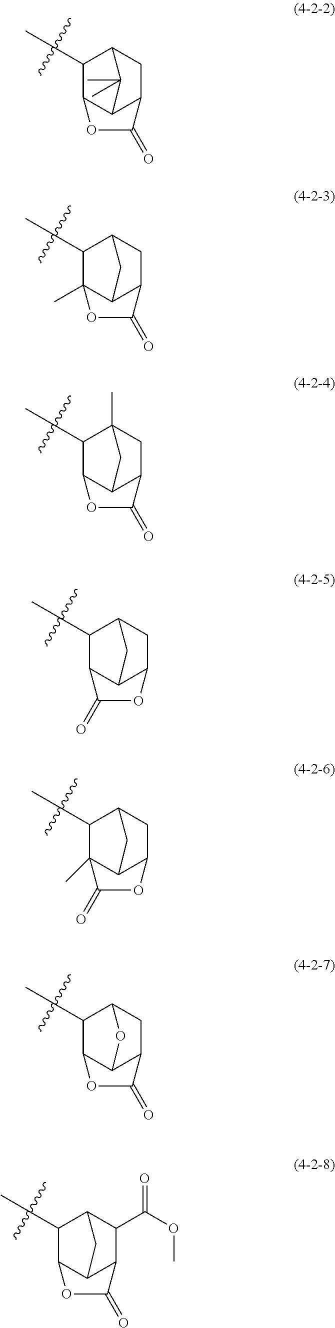

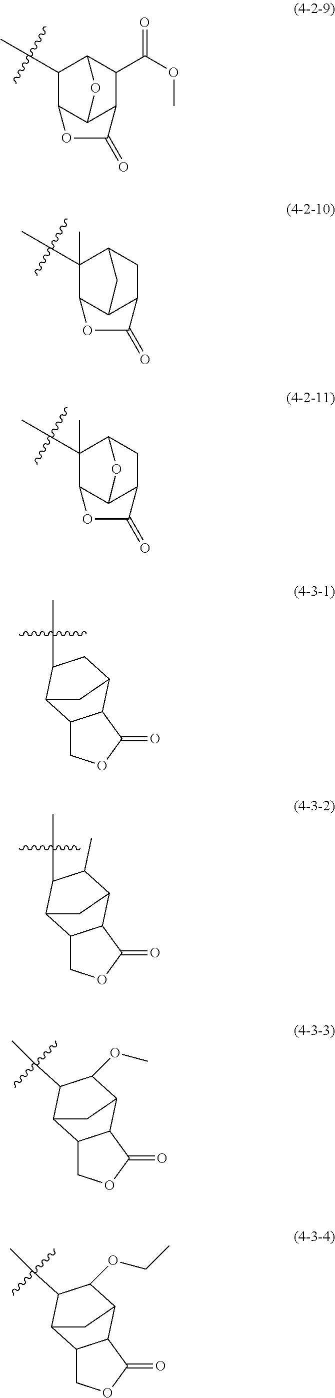

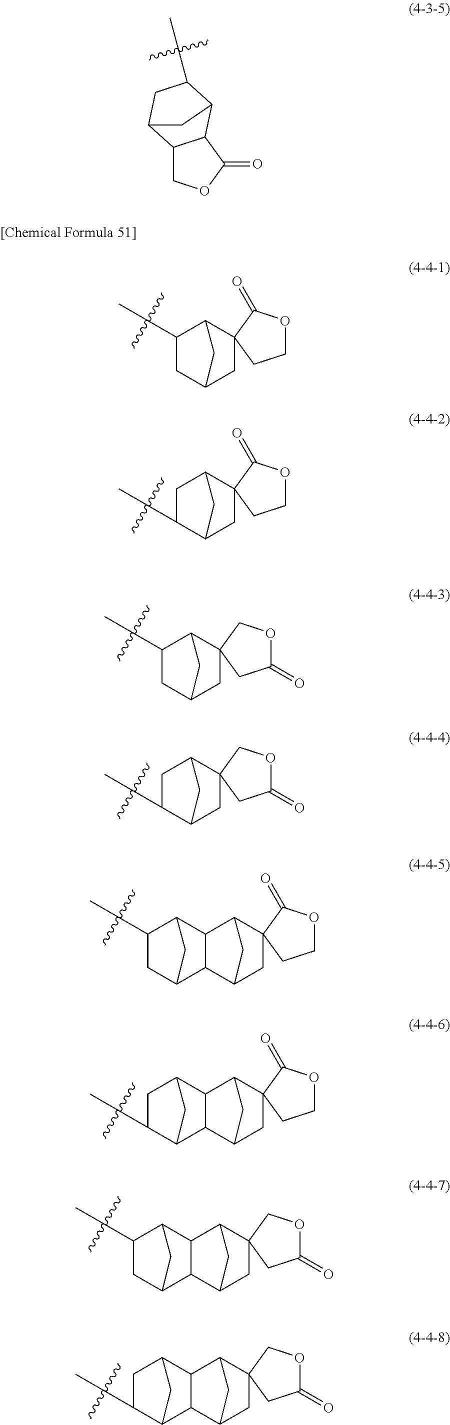

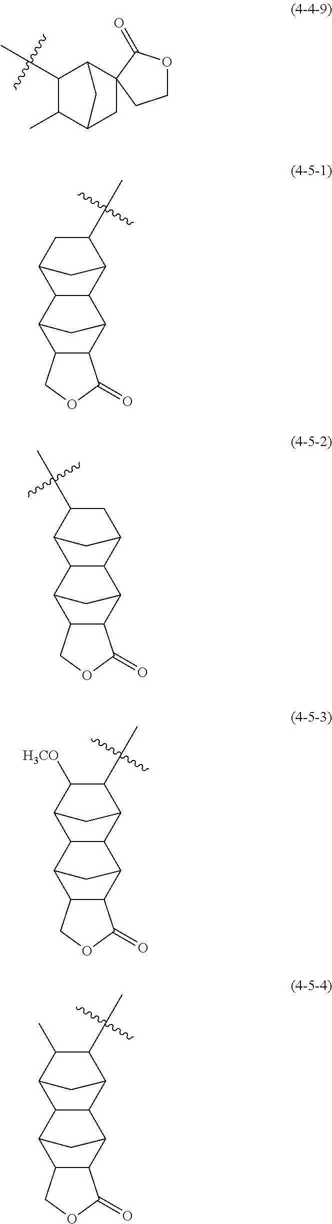

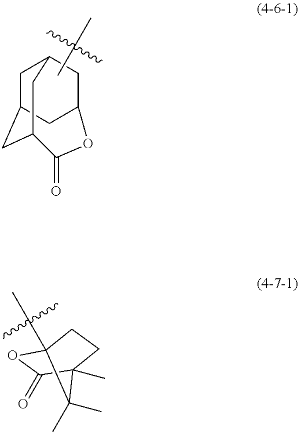

The structural unit (a2) must contain an —SO₂— containing cyclic group or a lactone-containing cyclic group, but structures of other parts are not particularly limited. Preferable examples include at least one structural unit selected from the group consisting of a structural unit derived from an acrylate ester which may have the hydrogen atom bonded to the carbon atom on the α-position substituted with a substituent and containing an —SO₂— containing cyclic group, and a structural unit derived from an acrylate ester which may have the hydrogen atoms bonded to the carbon atoms on the α-positions substituted with substituents and containing a lactone-containing cyclic group.

Specific examples of the structural unit (a2) include a structural unit represented by the general formula (a2-0) shown below.

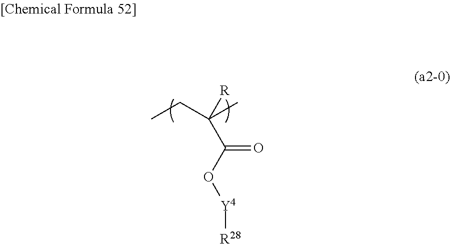

In the formula, R represents a hydrogen atom, an alkyl group of 1 to 5 carbon atoms, or a halogenated alkyl group of 1 to 5 carbon atoms, R²⁸ represents an —SO₂— containing cyclic group or a lactone-containing cyclic group, and Y⁴ represents a single bond or a divalent linking group.

In genera formula (a2-0), R is the same as defined above.

R²⁸ is the same —SO₂— containing cyclic group or lactone-containing cyclic group as defined above.

Y⁴ may represent either a single bond or a divalent linking group; however, a divalent linking group is preferable.

A divalent linking group for Y⁴ is not particularly limited, and examples include a divalent linking group which is the same as those represented by Y² in the above-described (a1-0-2). Among these, an alkylene group or a divalent linking group containing an ester bond (—C(═O)—O—) is preferable.

As the alkylene group, a linear or branched alkylene group is preferable. Specific examples include the same linear alkylene groups and branched alkylene groups as those described above for the aliphatic hydrocarbon group represented by Y².

As the divalent linking group containing an ester bond, a group represented by general formula: —R³⁰—C(═O)—O— (in the formula, R³⁰ represents a divalent linking group) is particularly desirable.

That is, the structural unit (a2) is preferably a structural unit represented by each of the following general formulae (a2-0-1) to (a2-0-3).

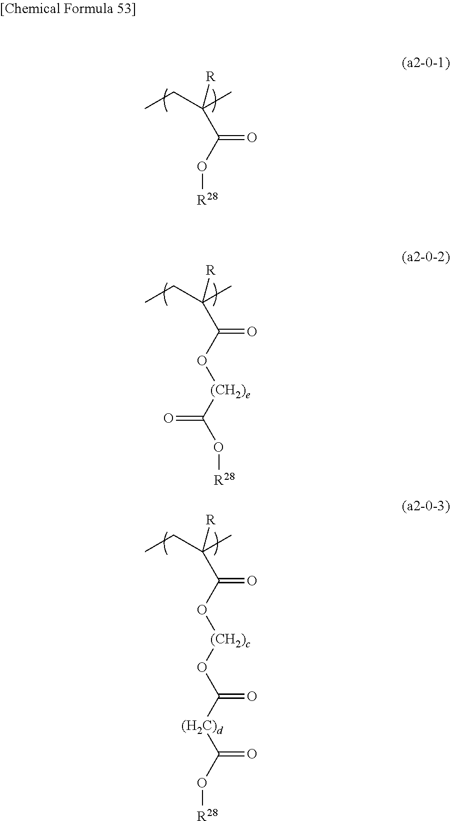

In the formula, each of R and R²⁸ is the same as defined above, and c to e each independently represent an integer of 1 to 3.

As the structural unit (a2), a structural unit represented by each of the following general formulae (a2-1-11), (a2-1-12), (a2-2-11), and (a2-2-12) is preferable, a structural unit represented by the general formula (a2-1-12), (a2-2-11), or (a2-2-12) is more preferable, and a structural unit represented by the formula (a2-1-12) is particularly preferable.

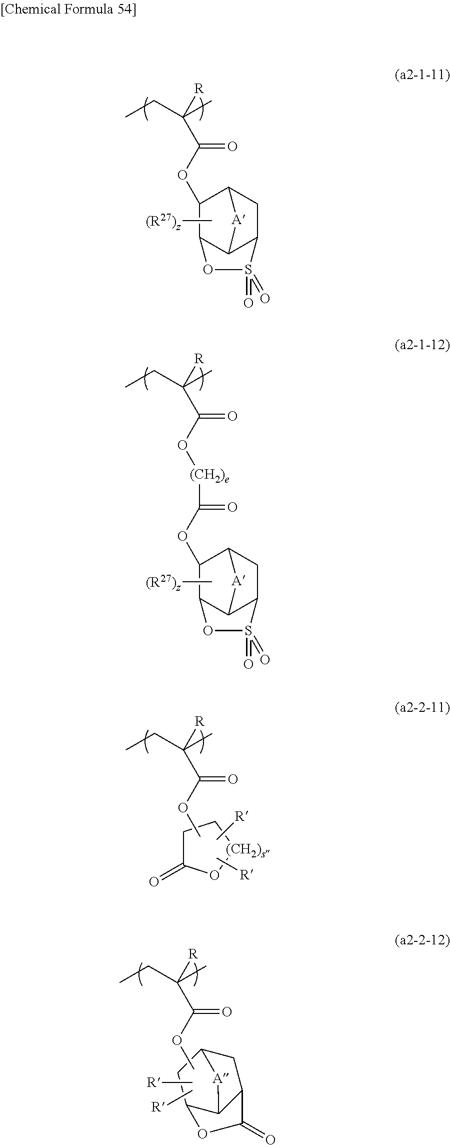

In the formula, R, A′, R²⁷, z, R′, s″, and A″ each is the same as defined above.

The component (A1) may contain one, or two or more types of the structural units (a2).

When the structural unit (a2) is included in the component (A1), the amount of the structural unit (a2) in the component (A1) based on the combined total of all the structural units that constitute the component (A1) is preferably within the range from 5 to 70 mol %, more preferably from 10 to 65 mol %, and still more preferably from 20 to 60 mol %.

When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units, and various lithography properties such as DOF and CDU and pattern shape can be improved.

(Structural Unit (a3))

The structural unit (a3) is a structural unit derived from an acrylate ester which may have the hydrogen atom bonded to the carbon atom on the α-position substituted with a substituent and containing a polar group-containing aliphatic hydrocarbon group.

When the component (A1) includes the structural unit (a3), the hydrophilicity of the component (A0) is enhanced, thereby contributing to improvement in resolution.

Examples of the polar group include a hydroxyl group, cyano group, carboxyl group, or hydroxyalkyl group in which part of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and cyclic aliphatic hydrocarbon groups (cyclic groups). The cyclic groups may be a monocyclic group or a polycyclic group. These cyclic groups can be selected appropriately from the multitude of groups that have been proposed for the resins of resist compositions designed for use with ArF excimer lasers. The cyclic groups are preferably the polycyclic group, and more preferably have 7 to 30 carbon atoms.

Of the various possibilities, structural units derived from an acrylate ester that include an aliphatic polycyclic group that contains a hydroxyl group, cyano group, carboxyl group or a hydroxyalkyl group in which part of the hydrogen atoms of the alkyl group have been substituted with fluorine atoms are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

When the aliphatic hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid. On the other hand, when the hydrocarbon group is a polycyclic group, structural units represented by formulas (a3-1), (a3-2) and (a3-3) shown below are preferable.

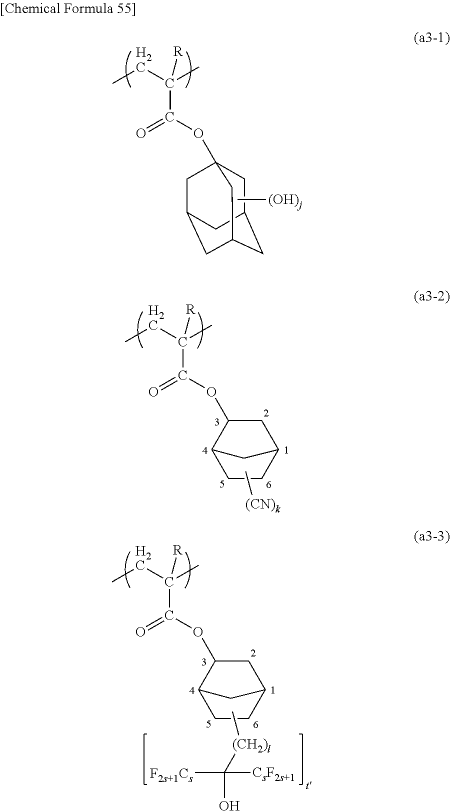

In the formulas, R is the same as defined above; j is an integer of 1 to 3; k is an integer of 1 to 3; t′ is an integer of 1 to 3; 1 is an integer of 1 to 5; and s is an integer of 1 to 3.

In general formula (a3-1), j is preferably 1 or 2, and more preferably 1. When j is 2, it is preferable that the hydroxyl groups be bonded to the 3rd and 5th positions of the adamantyl group. When j is 1, it is preferable that the hydroxyl group be bonded to the 3rd position of the adamantyl group.

j is preferably 1, and it is particularly desirable that the hydroxyl group be bonded to the 3rd position of the adamantyl group.

In formula (a3-2), k is preferably 1. The cyano group is preferably bonded to the 5th or 6th position of the norbornyl group.

In formula (a3-3), t′ is preferably 1. l is preferably 1. s is preferably 1. Further, it is preferable that a 2-norbornyl group or 3-norbornyl group be bonded to the terminal of the carboxy group of the acrylic acid. The fluorinated alkylalcohol is preferably bonded to the 5th or 6th position of the norbornyl group.

As the structural unit (a3) contained in the component (A1), one type of structural unit may be used, or two or more types may be used in combination.

In the component (A1), the amount of the structural unit (a3) based on the combined total of all structural units constituting the component (A1) is preferably 5 to 50 mol %, more preferably 5 to 40 mol %, and still more preferably 5 to 25 mol %.

When the amount of the structural unit (a3) is at least as large as the lower limit of the above-mentioned range, the effect of using the structural unit (a3) can be satisfactorily achieved. On the other hand, when the amount of the structural unit (a3) is no more than the upper limit of the above-mentioned range, a good balance can be achieved with the other structural units.

(Other Structural Units)

The component (A1) may also have a structural unit other than the above-mentioned structural units (a0), and (a1) to (a3) (hereinafter, referred to as “structural unit (a4)”), as long as the effects of the present invention are not impaired.

As the structural unit (a4), any structural unit which cannot be classified as the above-mentioned structural units (a0) and (a1) to (a3) can be used without any particular limitation, and any of the multitude of conventional structural units used within resist resins for ArF excimer lasers or KrF excimer lasers (and particularly for ArF excimer lasers) can be used.

Preferable examples of the structural unit (a4) include a structural unit derived from an acrylate ester which may have the hydrogen atom bonded to the carbon atom on the α-position substituted with a substituent and containing a non-acid-dissociable, aliphatic cyclic group, a structural unit derived from a styrene monomer, and a structural unit derived from a vinylnaphthalene monomer. Examples of this cyclic group include the same cyclic groups as those described above in relation to the aforementioned structural unit (a1), and any of the multitude of conventional polycyclic groups used within the resin component of resist compositions for ArF excimer lasers or KrF excimer lasers (and particularly for ArF excimer lasers) can be used.

In consideration of industrial availability and the like, at least one polycyclic group selected from amongst a tricyclodecanyl group, adamantyl group, tetracyclododecanyl group, isobornyl group, and norbornyl group is particularly desirable. These polycyclic groups may be substituted with a linear or branched alkyl group of 1 to 5 carbon atoms.

Specific examples of the structural unit (a4) include each structural unit having each of the structures represented by the following general formulae (a4-1) to (a4-7).

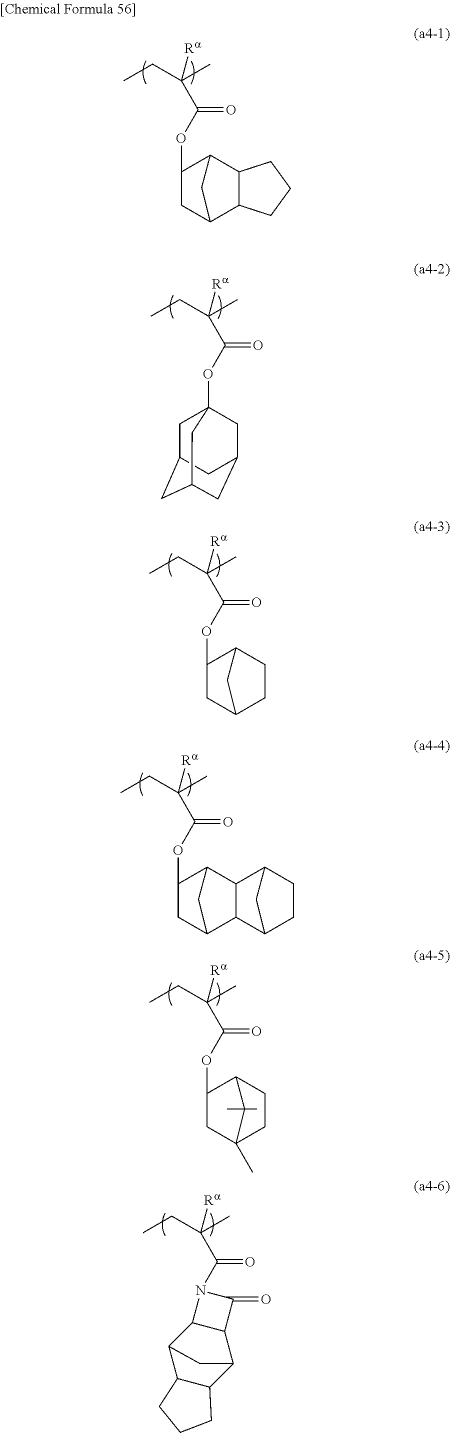

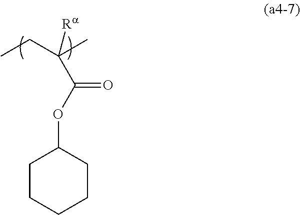

In the formula, R^{a} is the same as defined above.

As the structural unit (a4), one type of structural unit may be used, or two or more types may be used in combination.

When the component A1 include the structural unit (a4), the amount of the structural unit (a4) based on the combined total of all structural units constituting the component (A1) is preferably 1 to 20 mol %, more preferably 1 to 15 mol %, still more preferably 1 to 10 mol %.

The component (A1) is a polymer containing the structural unit (a0), and preferably a copolymer containing the structural unit (a1) in addition to the structural unit (a0).

Examples of such a copolymer include a copolymer consisting of the structural units (a0), (a1), and (a2); a copolymer consisting of the structural units (a0), (a1), (a2), and (a3); and a copolymer consisting of the structural units (a0), (a1), (a2), (a3), and (a4).

The weight average molecular weight (Mw) (the polystyrene equivalent value determined by gel permeation chromatography) of the component (A1) is not particularly limited, but is preferably 1,000 to 50,000, more preferably 1,500 to 30,000, and most preferably 2,500 to 20,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (A1) is not particularly limited, but is preferably 1.0 to 5.0, more preferably 1.0 to 3.0, and most preferably 1.2 to 2.5.

Here, Mn is the number average molecular weight.

In the component (A0), as the component (A1), one type may be used, or two or more types of compounds may be used in combination.

In the component (A0), the amount of the component (A1) based on the total weight of the component (A0) is preferably 25% by weight or more, more preferably 50% by weight or more, still more preferably 75% by weight or more, and may be even 100% by weight. When the amount of the component (A1) is 25% by weight or more, various lithography properties are improved.

The component (A0) may also have a base component other than the component (A1) (hereinafter, the base component referred to as “component (A2)”), as long as the effects of the present invention are not impaired.

As the component (A2), low molecular weight compounds that have a molecular weight of at least 500 and less than 4,000, contains a hydrophilic group, and also contains an acid dissociable group described above in connection with the component (A1) may be used. Specific examples include compounds containing a plurality of phenol skeletons in which part or all of the hydrogen atoms within hydroxyl groups have been substituted with the aforementioned acid dissociable groups.

Examples of the low-molecular weight compound include low molecular weight phenolic compounds in which a portion of the hydroxyl group hydrogen atoms have been substituted with an aforementioned acid dissociable group, and these types of compounds are known, for example, as sensitizers or heat resistance improvers for use in non-chemically amplified g-line or i-line resists.

Examples of these low molecular weight phenol compounds include bis(4-hydroxyphenyl)methane, bis(2,3,4-trihydroxyphenyl)methane, 2-(4-hydroxyphenyl)-2-(4′-hydroxyphenyl)propane, 2-(2,3,4-trihydroxyphenyl)-2-(2′,3′,4′-trihydroxyphenyl)propane, tris(4-hydroxyphenyl)methane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3-methylphenyl)-3,4-dihydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, 1-[1-(4-hydroxyphenyl)isopropyl]-4-[1,1-bis(4-hydroxyphenyl)ethyl]benzene, and dimers, trimers, tetramers, pentamers and hexamers of formalin condensation products of phenols such as phenol, m-cresol, p-cresol and xylenol. Needless to say, the low molecular weight phenol compound is not limited to these examples. In particular, a phenol compound having 2 to 6 triphenylmethane skeletons is preferable in terms of resolution and line width roughness (LWR). Also, there are no particular limitations on the acid dissociable group, and suitable examples include the groups described above.

In the resist composition of the present invention, the amount of the component (A) can be appropriately adjusted depending on the thickness of the resist film to be formed, and the like.

<Optional Components>

[Component (B)]

The resist composition of the present invention may contain an acid-generator component (B) that generates acid upon exposure (hereinafter, referred to as “component (B)”), in addition to the above-described component (A).

As the component (B), there is no particular limitation, and any of the known acid generators used in conventional chemically amplified resist compositions can be used.

Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators.

As an onium salt acid generator, a compound represented by general formula (b-1) or (b-2) shown below can be used.

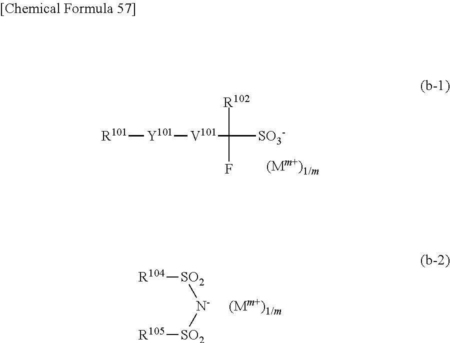

In the formula, R¹⁰¹ represents a cyclic group that may have a substituent, or a linear alkyl group or alkenyl group, which may have a substituent, Y¹⁰¹ represents a single bond, or a divalent linking group that may contain an oxygen atom, V¹⁰¹ represents a single bond, an alkylene group, or a fluorinated alkylene group, R¹⁰² represents a fluorine atom or a fluorinated alkyl group of 1 to 5 carbon atoms, and R¹⁰⁴ and R¹⁰⁵ each independently represent an alkyl group or fluorinated alkyl group of 1 to 10 carbon atoms, and these may be mutually bonded to form a ring. M^{m+} represents an m-valent organic cation.

### {Anion Moiety}

The cyclic group that may have a substituent, which is represented by R¹⁰¹ may be a cyclic aliphatic hydrocarbon group (aliphatic cyclic group), an aromatic hydrocarbon group (aromatic cyclic group), or a hetero ring containing a heteroatom in the ring.

Examples of the cyclic aliphatic hydrocarbon group represented by R¹⁰¹ include an aryl group in which one hydrogen atom has been removed from a monocycloalkane or a polycycloalkane, and an adamantyl group and a norbornyl group are preferable.

Examples of the aromatic hydrocarbon group represented by R¹⁰¹ include an aromatic hydrocarbon ring, or an aryl group in which one hydrogen atom has been removed from an aromatic compound containing two or more aromatic rings, and a phenyl group and a naphthyl group are preferable.

Specific examples of the hetero ring represented by R¹⁰¹ include each group represented by each of the following formulae (L1) to (L6) and (S1) to (S4).

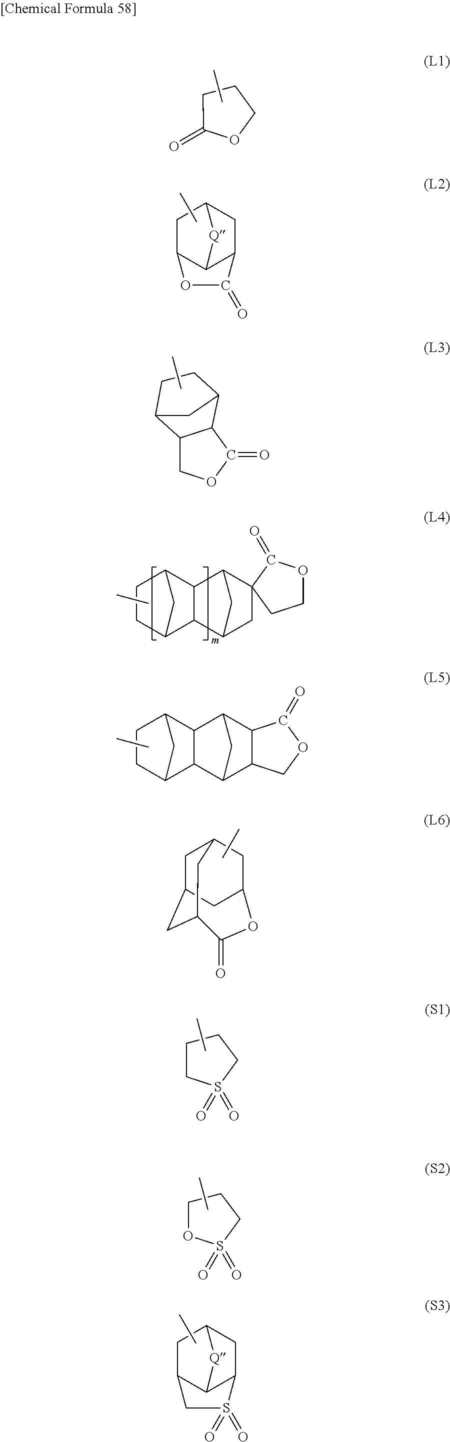

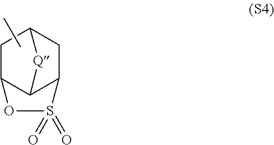

In the formula, Q″ represents an alkylene group of 1 to 5 carbon atoms, —O—, —S—, —O—R⁹⁴— or —S—R⁹⁵— (wherein each of R⁹⁴ and R⁹⁵ independently represents an alkylene group of 1 to 5 carbon atoms); and m represents 0 or 1.

In the formula, the alkylene group for Q″, R⁹⁴, or R⁹⁵ is preferably a methylene group.

Examples of the hetero ring represented by R¹⁰¹ include the following, in addition to those described above.

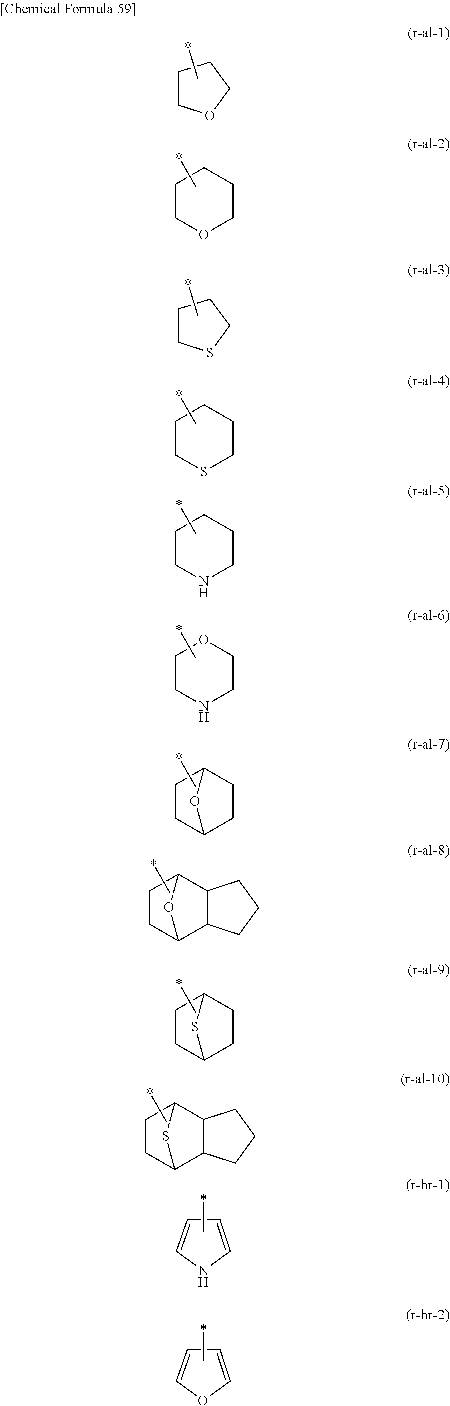

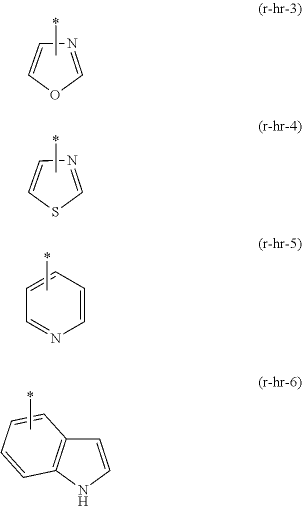

The cyclic aliphatic hydrocarbon group, aromatic hydrocarbon group, and hetero ring represented by R¹⁰¹ may have substituents. Here, when the cyclic aliphatic hydrocarbon group, aromatic hydrocarbon group, or hetero ring has a substituent, part or all of the hydrogen atoms bonded to a ring structure of the cyclic aliphatic hydrocarbon group, aromatic hydrocarbon group, or hetero ring are substituted with atoms or groups other than hydrogen atoms. Examples of a substituent include an alkyl group, an alkoxy group, a halogen atom, a halogenated alkyl group, a hydroxyl group, an oxygen atom (═O), and a nitro group.

An alkyl group as a substituent, an alkyl group of 1 to 5 carbon atoms is preferable, and a methyl group, an ethyl group, a propyl group, an n-butyl group, or a tert-butyl group is most preferable.

An alkoxy group as a substituent, an alkoxy group of 1 to 5 carbon atoms is preferable, a methoxy group, an ethoxy group, an n-propoxy group, an iso-propoxy group, an n-butoxy group, or a tert-butoxy group is preferable, and a methoxy group or an ethoxy group is most preferable.

Examples of a halogen atom as a substituent include a fluorine atom, a chlorine atom, a bromine atom, and an iodine atom, and a fluorine atom is preferable.

Examples of a halogenated alkyl group as a substituent include a group in which part or all of the hydrogen atoms of an alkyl group of 1 to 5 carbon atoms such as a methyl group, an ethyl group, a propyl group, an n-butyl group, a tert-butyl group or the like are substituted with the above-described halogen atoms.

The chain-like alkyl group for R¹⁰¹ may be either linear or branched.

As a linear alkyl group, 1 to 20 carbon atoms are preferable, 1 to 15 carbon atoms are more preferable, and 1 to 10 carbon atoms are most preferable. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

As a branched alkyl group, 3 to 20 carbon atoms are preferable, 3 to 15 carbon atoms are more preferable, and 3 to 10 carbon atoms are most preferable. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The alkenyl group for R¹⁰¹ preferably has 2 to 10 carbon atoms, preferably has 2 to 5 carbon atoms, preferably has 2 to 4 carbon atoms, and particularly preferably has 3 carbon atoms. Examples include a vinyl group, a propenyl group (allyl group), and a butenyl group. Among these, a propenyl group is particularly preferable.

Examples of the substituent in the chain-like alkyl group or alkenyl group represented by R¹⁰¹ include an alkoxy group, a halogen atom, a halogenated alkyl group, a hydroxyl group, an oxygen atom (═O), and a nitro group which are the same substituents for the above-described cyclic group, or the above-described cyclic group.

In the present invention, preferably, R¹⁰¹ is a cyclic group that may have a substituent, and preferable examples include a group in which one or more hydrogen atoms have been removed from a phenyl group, a naphthyl group, or a polycycloalkane; and a lactone-containing cyclic group and an —SO₂— containing cyclic group, which are represented by the above-described formulae (L1) to (L6) and (S1) to (S4) respectively.

The divalent linking group containing an oxygen atom for Y¹⁰¹ may contain an atom other than oxygen. Examples of atoms other than oxygen include a carbon atom, a hydrogen atom, a sulfur atom and a nitrogen atom.

Examples of divalent linking groups containing an oxygen atom include non-hydrocarbon, oxygen atom-containing linking groups such as an oxygen atom (an ether bond; —O—), an ester bond (—C(═O)—O—), an amido bond (—C(═O)—NH—), a carbonyl bond (—C(═O)—) and a carbonate bond (—O—C(═O)—O—); and combinations of the aforementioned non-hydrocarbon, heteroatom-containing linking groups with an alkylene group. Furthermore, the combinations may have a sulfonyl group (—SO₂—) bonded thereto.

Specific examples of the combinations include —V¹⁰⁵—O—, —V¹⁰⁵—O—C(═O)—, —C(═O)—O—V¹⁰⁵—O—C(═O)—, —SO₂—O—V¹⁰⁵—O—C(═O)—, and —V¹⁰⁵—SO₂—O—V¹⁰⁶—O—C(═O)— (in the formulae, each of V¹⁰⁵ to V¹⁰⁶ independently represents an alkylene group).

The alkylene group for V¹⁰⁵ to V¹⁰⁶ is preferably a linear or branched alkylene group, and preferably has 1 to 12 carbon atoms, more preferably 1 to 5, and most preferably 1 to 3.

Examples of the alkylene group include the same linear or branched alkylene groups as those explained for Y².

Y¹⁰¹ is preferably a divalent linking group containing an ester linkage or ether linkage, and more preferably a group of —V¹⁰⁵—O—, —V¹⁰⁵—O—C(═O)—, or —C(═O)—O—V¹⁰⁵—O—C(═O)—.

The alkylene group for V¹⁰¹ is the same alkylene group described for the V¹⁰⁵ to V¹⁰⁶, and the alkylene group preferably has 1 to 5 carbon atoms.

Examples of the fluorinated alkylene group for V¹⁰¹ include a group in which part or all of the hydrogen atoms which constitute an alkylene group for V¹⁰⁵ to V¹⁰⁶ have been substituted with fluorine atoms. The fluorinated alkylene group preferably has 1 to 5 carbon atoms, and more preferably has 1 to 2 carbon atoms.

Examples of the fluorinated alkyl group of 1 to 5 carbon atoms, which is for R¹⁰², include a group in which part or all of the hydrogen atoms which constitute an alkyl group of 1 to 5 carbon atoms have been substituted with fluorine atoms.

R¹⁰⁴ and R¹⁰⁵ each independently represent an alkyl group or fluorinated alkyl group of 1 to 10 carbon atoms, and may be mutually bonded to form a ring.

R¹⁰⁴ and R¹⁰⁵ each preferably represents a linear or branched (fluorinated) alkyl group. The (fluorinated) alkyl group has 1 to 10 carbon atoms, preferably has 1 to 7 carbon atoms, and more preferably has 1 to 3 carbon atoms. The smaller the number of carbon atoms of the (fluorinated) alkyl group for R¹⁰⁴ and R¹⁰⁵ within the above-mentioned range of the number of carbon atoms, the more solubility in a resist solvent is improved.

Further, in the (fluorinated) alkyl group for R¹⁰⁴ and R¹⁰⁵, it is preferable that the number of hydrogen atoms substituted with fluorine atoms is as large as possible because the acid strength increases and the transparency to high energy radiation of 200 nm or less or electron beam is improved. The fluorination ratio of the (fluorinated) alkyl group is preferably from 70 to 100%, more preferably from 90 to 100%, and it is particularly desirable that the alkylene group or alkyl group be a perfluoroalkylene group or perfluoroalkyl group in which all hydrogen atoms are substituted with fluorine atoms.

Specific examples of the anion moiety represented by the formula (b-1) include an anion represented by any of the following formulae (b1) to (b9).

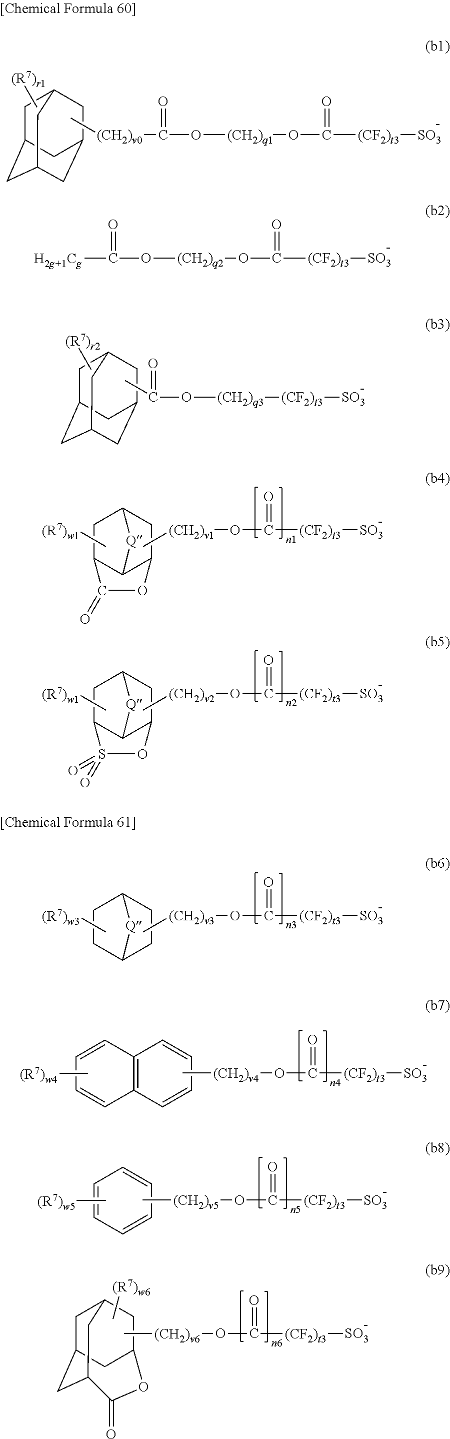

In the formula, q1 to q2 each independently represent an integer of 1 to 5, q3 represents an integer of 1 to l2, t3 represents an integer of 1 to 3, r1 to r2 each independently represent an integer of 0 to 3, g represents an integer of 1 to 20, R⁷ represents a substituent, n1 to n6 each independently represent 0 or 1, v0 to v6 each independently represent an integer of 0 to 3, w1 to w6 each independently represent an integer of 0 to 3, and Q″ is the same as defined above.

Examples of a substituent for R⁷ include the same groups defined in the above explanation for R¹⁰¹, such as a substituent that may substitute for part of hydrogen atoms bonded to carbon atoms constituting the ring structure of the aliphatic cyclic group; and a substituent that may substitute for a hydrogen atom bonded to an aromatic ring contained in the aromatic hydrocarbon group.

If there are two or more of the R⁷ group, as indicated by the values r1, r2, and w1 to w6, then the two or more of the R⁷ groups may be the same or different from each other.

Regarding the anion moiety, in addition to those described above, it is also possible to use each of onium salts in which the anion moiety of these onium salts is replaced by an alkyl sulfonate, such as methanesulfonate, n-propanesulfonate, n-butanesulfonate, n-octanesulfonate, 1-adamantanesulfonate or 2-norbornanesulfonate; or replaced by a sulfonate, such as d-camphor-10-sulfonate, benzenesulfonate, perfluorobenzenesulfonate or p-toluenesulfonate.

### {Cation Moiety}

In the above-described formulae (b-1) and (b-2), M^{m+} represents an m-valent organic cation.

The m-valent organic cation represented by M^{m+} is not particularly limited, and for example, an organic cation which has been known as a cation moiety of onium salt acid generators for resist compositions can be used.

Preferable examples of the m-valent organic cation include a sulfonium cation and an iodonium cation, and in addition to each cation represented by each of the above-described formulae (ca-1) to (ca-3), a cation represented by the following general formula (ca-4) is also preferable.

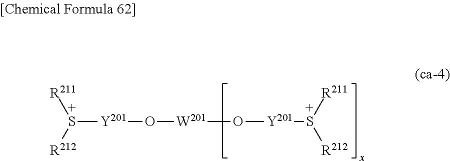

In the formula, R²¹¹ and R²¹² each independently represent an aryl group, an alkyl group, or an alkenyl group, which may have a substituent, and R²¹¹ to R²¹² may be mutually bonded to form a ring together with the sulfur atom in the formula. Y²⁰¹ represents an arylene group, an alkylene group, or an alkenylene group, x represents 1 or 2, and W²⁰¹ represents an (x+1)-valent linking group.

Examples of an aryl group for R²¹¹ to R²¹² include an aryl group of 6 to 20 carbon atoms, which does not have any substituent, and a phenyl group or a naphthyl group is preferable.

As an alkyl group for R²¹¹ to R²¹², a chain-like or cyclic alkyl group of 1 to 30 carbon atoms is preferable.

As an alkenyl group for R²¹¹ to R²¹², an alkenyl group of 2 to 10 carbon atoms is preferable.

Examples of a substituent which R²¹¹ to R²¹² may have include the same a substituent which R²⁰¹ in the formula (ca-1) may have.

When R²¹¹ to R²¹² are mutually bonded to form a ring together with the sulfur atom in the formula, it is the same as when R²⁰¹ to R²⁰³ in the above-described formula (ca-1) form a ring.

x represents 1 or 2.

W²⁰¹ represents an (x+1)-valent, i.e., divalent or trivalent linking group.

Examples of the divalent linking group for W²⁰¹ include the same divalent linking group for Y² in the above-described formula (a1-0-2), and the divalent linking group may be linear, branched, or cyclic, and cyclic is preferable. Among these, a group in which two carbonyl groups are bonded to the both ends of an arylene group is preferable. Examples of the arylene group include a phenylene group and a naphthylene group, and a phenylene group is particularly preferable.

Examples of the trivalent linking group for W²⁰¹ include a group in which one hydrogen atom has been removed from a divalent linking group, and a group in which a divalent linking group is further bonded to another divalent linking group. Examples of the divalent linking group include the same divalent linking group for Y² in the above-described formula (a1-0-2). As the trivalent linking group for W¹, a group in which three carbonyl groups are bonded to an arylene group is preferable.

Preferable specific examples of a cation for the formula (ca-4) include a cation represented by the following formula.

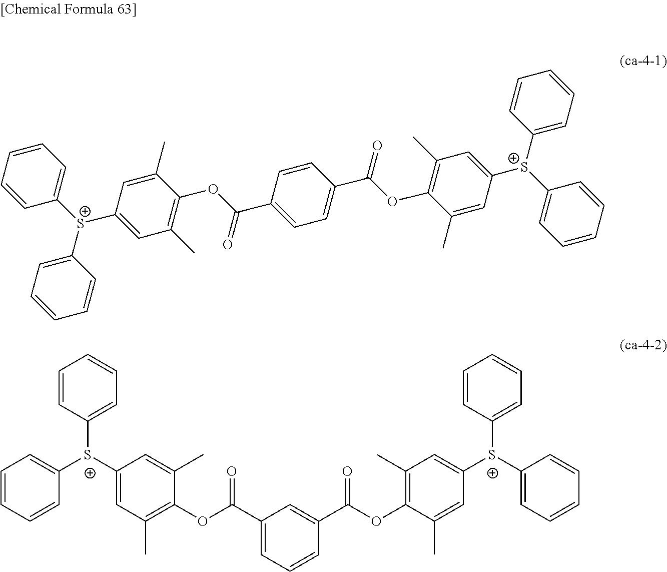 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

As an organic cation for M^{m+}, the sulfonium cation represented by the above-described formula (ca-1) or (ca-3) is preferable.

Oxime sulfonate acid generators disclosed in Japanese Unexamined Patent Application, First Publication No. Hei 9-208554 (Chemical Formulas 18 and 19 shown in paragraphs [0012] to [0014]) and oxime sulfonate acid generators disclosed in WO 2004/074242A2 (Examples 1 to 40 described at pages 65 to 86) may be preferably used.

Diazomethane acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may be preferably used.

Furthermore, as examples of poly(bis-sulfonyl)diazomethanes, those disclosed in Japanese Unexamined Patent Application, First Publication No. Hei 11-322707, including

1,3-bis(phenylsulfonyldiazomethylsulfonyl)propane,
1,4-bis(phenylsulfonyldiazomethylsulfonyl)butane,
1,6-bis(phenylsulfonyldiazomethylsulfonyl)hexane,
1,10-bis(phenylsulfonyldiazomethylsulfonyl)decane,
1,2-bis(cyclohexylsulfonyldiazomethylsulfonyl)ethane,
1,3-bis(cyclohexylsulfonyldiazomethylsulfonyl)propane,
1,6-bis(cyclohexylsulfonyldiazomethylsulfonyehexane, and
1,10-bis(cyclohexylsulfonyldiazomethylsulfonyl)decane, may be given.

As the component (B), one type of acid generator described above may be used, or two or more types of the acid generators may be used in combination.

In the positive resist composition of the present invention, the amount of the component (B) relative to 100 parts by weight of the component (A) is preferably 0.5 to 60 parts by weight, more preferably 1 to 50 parts by weight, and still more preferably 1 to 40 parts by weight. When the amount of the component (B) is within the above-mentioned range, formation of a resist pattern can be satisfactorily performed. Further, when each component of the resist composition is dissolved in the organic solvent, by virtue of the above-mentioned range, a uniform solution can be obtained and the storage stability becomes satisfactory.

[Component (D)]

The resist composition of the present invention may further include a nitrogen-containing organic compound (D) which does not fall under the category of the component (A) or (B) (hereafter referred to as the component (D)), as long as the effects of the present invention are not impaired.

As the component (D), there is no particular limitation as long as it functions as an acid diffusion control agent, i.e., a quencher which traps the acid generated from the component (A) (structural unit (a0)), or from the component (A) (structural unit (a0)) and the component (B) upon exposure. A multitude of these components (D) have already been proposed, and any of these known compounds may be used. Examples of the component (D) include an aliphatic amine and an aromatic amine, although an aliphatic amine, and particularly a secondary aliphatic amine or tertiary aliphatic amine is preferable.

An aliphatic amine is an amine having one or more aliphatic groups, and the aliphatic groups preferably have 1 to 20 carbon atoms.

Examples of these aliphatic amines include amines in which at least one hydrogen atom of ammonia (NH₃) has been substituted with an alkyl group or hydroxyalkyl group of 1 to 20 carbon atoms (i.e., alkylamines or alkylalcoholamines), and cyclic amines.

The alkyl group and the alkyl group for the hydroxyalkyl group may be any of linear, branched or cyclic.

When the alkyl group is linear or branched, the alkyl group preferably has 2 to 20 carbon atoms, and more preferably 2 to 8 carbon atoms.

When the alkyl group is cyclic (i.e., a cycloalkyl group), the number of carbon atoms is preferably 3 to 30, more preferably 3 to 20, still more preferably 3 to 15, still more preferably 4 to 12, and most preferably 5 to 10. The alkyl group may be monocyclic or polycyclic. Examples thereof include groups in which one or more of the hydrogen atoms have been removed from a monocycloalkane; and groups in which one or more of the hydrogen atoms have been removed from a polycycloalkane such as a bicycloalkane, a tricycloalkane, or a tetracycloalkane. Specific examples of the monocycloalkane include cyclopentane and cyclohexane. Specific examples of the polycycloalkane include adamantane, norbornane, isobornane, tricyclodecane and tetracyclododecane.

Specific examples of the alkylamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; and trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, and tri-n-dodecylamine.

Specific examples of the alkylalcoholamines include diethanolamine, triethanolamine, diisopropanolamine, triisopropanolamine, di-n-octanolamine, tri-n-octanolamine, stearyldiethanolamine and laurildiethanolamine.

Examples of the cyclic amine include heterocyclic compounds containing a nitrogen atom as a heteroatom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine and tris[2-{2-(2-hydroxyethoxy)ethoxy}ethyl]amine.

Examples of aromatic amines include aniline, pyridine, 4-dimethylaminopyridine, pyrrole, indole, pyrazole, imidazole and derivatives thereof, as well as diphenylamine, triphenylamine and tribenzylamine.

The component (D) can be used either alone, or in combinations of two or more different compounds.

The component (D) is typically used in an amount within a range from 0.01 to 5.0 parts by weight, relative to 100 parts by weight of the component (A). When the amount of the component (D) is within the above-mentioned range, the shape of the resist pattern and the post exposure stability of the latent image formed by the pattern-wise exposure of the resist layer are improved.

[Component (E)]

Furthermore, in the resist composition of the present invention, for preventing any deterioration in sensitivity, and improving the resist pattern shape and the post exposure stability of the latent image formed by the pattern-wise exposure of the resist layer, at least one compound (E) (hereafter referred to as the “component (E)”) selected from the group consisting of an organic carboxylic acid, or a phosphorus oxo acid or derivative thereof can be added.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid. Among these, phosphonic acid is particularly desirable.

Examples of oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenyl phosphonate, diphenyl phosphonate and dibenzyl phosphonate.

Examples of phosphinic acid derivatives include phenylphosphinic acid and phosphinic acid esters.

As the component (E), one type may be used alone, or two or more types may be used in combination.

The component (E) is typically used in an amount within a range from 0.01 to 5.0 parts by weight, relative to 100 parts by weight of the component (A).

[Component (F)]

The resist composition of the present invention may further include a fluorine additive (hereafter, referred to as “component (F)”) for imparting water repellency to the resist film. By containing the component (F), water repellency of the surface of resist film is enhanced, and thereby defects after the development is decreased.

As the component (F), for example, a fluorine-containing polymeric compound described in Japanese Unexamined Patent Application, First Publication No. 2010-002870 can be used.

Specific examples of the component (F) include copolymers having a structural unit represented by general formula (f1) shown below. More specifically, a polymer (homopolymer) consisting of a structural unit represented by the following formula (f1); a copolymer of a structural unit represented by the following formula (f1) and the aforementioned structural unit (a1); and a copolymer of a structural unit represented by the following formula (f1), a structural unit derived from acrylic acid or methacrylic acid and the aforementioned structural unit (a1) are preferable.

Among the structural unit (a1), a structural unit represented by the aforementioned formula (a1-1-32) is most preferable.

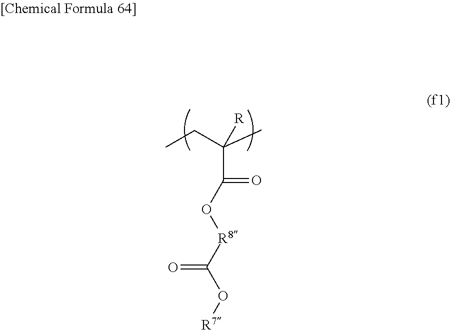

In the formula, R represents a hydrogen atom, an alkyl group of 1 to 5 carbon atoms or a halogenated alkyl group of 1 to 5 carbon atoms, R⁷″ represents an organic group containing a fluorine atom, and R⁸″ represents an alkylene group of 1 to 5 carbon atoms, which may have a substituent.

In the aforementioned formula (f1), R⁷″ represents an organic group containing a fluorine atom, and is preferably a hydrocarbon group containing a fluorine atom. As the hydrocarbon group containing a fluorine atom, a fluorinated alkyl group is preferable, and a fluorinated alkyl group of 1 to 5 carbon atoms is more preferable. Among these examples, as R⁷″, a group represented by the formula: “—(CH₂)o-CF₃” is preferable (in the formula, o represents the repeating numbers of CH₂, and is an integer of 1 to 3).

In the formula (f1), an alkylene group for R⁸″ has 1 to 5 carbon atoms, preferably 1 to 3, and more preferably 1 or 2 carbon atoms. The hydrogen atoms of the alkylene group for R⁸″ may be substituted with fluorine atoms, alkyl groups of 1 to 5 carbon atoms, or fluorinated alkyl groups of 1 to 5 carbon atoms.

In the formula (f1), R is the same as defined above. As R, a hydrogen atom or a methyl group is preferable.

As the component (F), one type may be used alone, or two or more types may be used in combination.

In the resist composition, the component (F) is preferably used in an amount within a range from 1 to 10 parts by weight, relative to 100 parts by weight of the component (A). When the amount of the component (F) is within the above-mentioned range, water repellency of the surface of resist film is enhanced, and thereby defects after the development is decreased.

If desired, miscible additives can also be added to the resist composition of the present invention. Examples of such miscible additives include additive resins for improving the performance of the resist film, surfactants for improving the applicability, dissolution inhibitors, plasticizers, stabilizers, colorants, halation prevention agents, and dyes.

[Component (S)]

The resist composition of the present invention can be prepared by dissolving the materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene.

These solvents can be used individually, or in combination as a mixed solvent.

Among these, γ-butyrolactone, propylene glycol monomethyl ether acetate (PGMEA), propylene glycol monomethyl ether (PGME), cyclohexanone and ethyl lactate (EL) are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2. For example, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME weight ratio is preferably from 1:9 to 9:1, more preferably from 2:8 to 8:2, and still more preferably 3:7 to 7:3. Alternatively, when PGME and cyclohexanone is mixed as the polar solvent, the PGMEA:PGME and cyclohexanone weight ratio is preferably from 1:9 to 9:1, more preferably from 2:8 to 8:2, and still more preferably 3:7 to 7:3.

Further, as the component (S), a mixed solvent of one of PGMEA, EL, or the mixed solvent of PGMEA and the polar solvent with γ-butyrolactone is also preferable. The mixing ratio (former:latter) of such a mixed solvent is preferably from 70:30 to 95:5.

The amount of the component (S) is not particularly limited, and is appropriately adjusted to a concentration which enables coating of a coating solution to a substrate, depending on the thickness of the coating film. In general, the organic solvent is used in an amount such that the solid content of the resist composition becomes within the range from 1 to 20% by weight, and preferably from 2 to 15% by weight.

<<Method of Forming a Resist Pattern>>

The method of forming a resist pattern according to the present invention described above includes: forming a resist film on a substrate using a resist composition of the present invention; conducting exposure of the resist film; and developing the resist film to form a resist pattern.

The method for forming a resist pattern according to the present invention can be performed, for example, as follows.

Firstly, the resist composition of the present invention is applied to a substrate using a spinner or the like, and a bake treatment (post applied bake (PAB)) is conducted at a temperature of 80 to 150° C. for 40 to 120 seconds, preferably 60 to 90 seconds, to form a resist film.

Following selective exposure of the thus formed resist film, either by exposure through a mask having a predetermined pattern formed thereon (mask pattern) using an exposure apparatus such as an ArF exposure apparatus, an electron beam lithography apparatus or an EUV exposure apparatus, or by patterning via direct irradiation with an electron beam without using a mask pattern, baking treatment (post exposure baking (PEB)) is conducted under temperature conditions of 80 to 150° C. for 40 to 120 seconds, and preferably 60 to 90 seconds.

Subsequently, the resulting resist film is subjected to developing treatment.

For an alkali developing process, an alkali developing solution is used in developing treatment. For a solvent developing process, a developing solution containing an organic solvent (organic developing solution) is used in developing treatment.

After the developing treatment, it is preferable to perform rinse treatment. In the case of an alkali developing process, the rinse treatment is preferably a water rinse using pure water. In the case of a solvent developing process, it is preferable to use a rinse liquid containing an organic solvent.

In the case of a solvent developing process, after the developing treatment or the rinse treatment, the developing solution or the rinse liquid remaining on the pattern can be removed by a treatment using a supercritical fluid.

After the developing treatment or the rinse treatment, drying is conducted. If desired, bake treatment (post bake) can be conducted following the developing. In this manner, a resist pattern can be obtained.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used.

Here, a “multilayer resist method” is a method in which at least one layer of an organic film (lower-layer organic film) and at least one layer of a resist film (upper resist film) are provided on a substrate, and a resist pattern formed on the upper resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film (triple-layer resist method).

The wavelength to be used for exposure is not particularly limited and the exposure can be conducted using radiation such as ArF excimer laser, KrF excimer laser, F₂ excimer laser, extreme ultraviolet rays (EUV), vacuum ultraviolet rays (VUV), electron beam (EB), X-rays, and soft X-rays. The resist composition of the present invention is effective to KrF excimer laser, ArF excimer laser, EB and EUV.

The exposure of the resist film can be either a general exposure (dry exposure) conducted in air or an inert gas such as nitrogen, or immersion exposure (immersion lithography).

In immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long at it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

As examples of the alkali developing solution for developing treatment in an alkali developing process, a 0.1 to 10% by weight aqueous solution of tetramethylammonium hydroxide (TMAH) can be given.

As the organic solvent contained in the organic developing solution for developing treatment in a solvent developing process, any of the conventional organic solvents can be used which are capable of dissolving the component (A) (prior to exposure). Specific examples of the organic solvent include polar solvents such as ketone solvents, ester solvents, alcohol solvents, amide solvents and ether solvents, and hydrocarbon solvents.

If desired, the organic developing solution may have a conventional additive blended. Examples of the additive include surfactants. The surfactant is not particularly limited, and for example, an ionic or non-ionic fluorine and/or silicon surfactant can be used.

When a surfactant is added, the amount thereof based on the total amount of the organic developing solution is generally 0.001 to 5% by weight, preferably 0.005 to 2% by weight, and more preferably 0.01 to 0.5% by weight.

The development treatment can be performed by a conventional developing method. Examples thereof include a method in which the substrate is immersed in the developing solution for a predetermined time (a dip method), a method in which the developing solution is cast up on the surface of the substrate by surface tension and maintained for a predetermined period (a puddle method), a method in which the developing solution is sprayed onto the surface of the substrate (spray method), and a method in which the developing solution is continuously ejected from a developing solution ejecting nozzle while scanning at a constant rate to apply the developing solution to the substrate while rotating the substrate at a constant rate (dynamic dispense method).

As the organic solvent contained in the rinse liquid used for rinse treatment after the developing treatment in a solvent developing process, any of the aforementioned organic solvents for the organic developing solution can be used which hardly dissolve the pattern. In general, at least one solvent selected from the group consisting of hydrocarbon solvents, ketone solvents, ester solvents, alcohol solvents, amide solvents and ether solvents is used. Among these, at least one solvent selected from the group consisting of hydrocarbon solvents, ketone solvents, ester solvents, alcohol solvents and amide solvents is preferable, more preferably at least one solvent selected from the group consisting of alcohol solvents and ester solvents, and an alcohol solvent is particularly desirable.

The rinse treatment (washing treatment) using the rinse liquid can be performed by a conventional rinse method. Examples thereof include a method in which the rinse liquid is continuously applied to the substrate while rotating it at a constant rate (rotational coating method), a method in which the substrate is immersed in the rinse liquid for a predetermined time (dip method), and a method in which the rinse liquid is sprayed onto the surface of the substrate (spray method).

### EXAMPLES

As follows is a description of examples of the present invention, although the scope of the present invention is by no way limited by these examples.

In the following examples, a compound represented by a chemical formula (1) is referred to as “compound (1)”, and the same applies for compounds represented by other chemical formulas.

Note that, in the NMR analysis, the internal standard for ¹H-NMR and ¹³C-NMR was tetramethylsilane (TMS).

### Example 1

### Production Example of Polymeric Compound 3

Step for Obtaining the First Precursor Polymer:

In a separable flask equipped with a thermometer, a reflux tube and a nitrogen feeding pipe, 40.00 g (126.5 mmol) of the compound 1, 57.43 g (245.1 mmol) of the compound 2, and 16.99 g (39.00 mmol) of the compound 3 were dissolved in 143.9 g of a mixed solvent of methyl ethyl ketone and cyclohexanone (MEK/CH) to obtain a solution. Then, 28.74 mmol of dimethyl 2,2″-azobis(isobutyrate) (V-601) was added and dissolved in the obtained solution. Then, the resultant was dropwise added to 79.75 g of MEK/CH in a nitrogen atmosphere over 4 hours for a reaction. Thereafter, the reaction solution was heated for 1 hour while stirring, and then cooled to room temperature. Then, the obtained reaction polymer solution was dropwise added to an excess amount of an n-heptane, and an operation to deposit a polymer was conducted. Thereafter, the precipitated white powder was separated by filtration, followed by washing with a methanol and drying, thereby obtaining 79.10 g of the polymeric compound 1 (first precursor polymer).

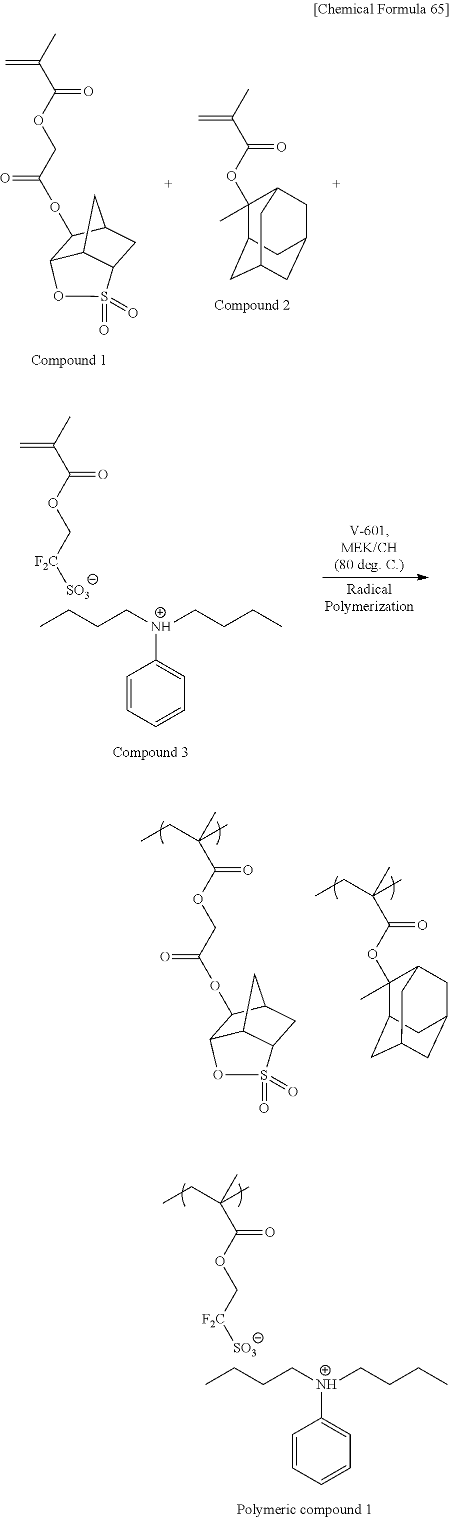

Amine Reaction Step:

In an eggplant shaped flask, 39.5 g of the polymeric compound 1, 2.87 g of the compound 4 (amine), 158 g of acetonitrile, and 158 g of n-heptane were added, and stirred for 30 minutes to extract an acetonitrile layer. The extracted acetonitrile layer was dropwise added to an excess amount of diisopropyl ether, and an operation to deposit a polymer was conducted. Thereafter, the precipitated white powder was separated by filtration, followed by drying, thereby obtaining 33.1 g of the polymeric compound 2 (second precursor polymer).

[pKa]

The pKa of the conjugate acid (second ammonium cation) in the compound 4 (amine) was 10.98, and the pKa of the ammonium cation (first ammonium cation) in the polymeric compound 1 was 6.28. That is, the pKa of the conjugate acid (second ammonium cation) was larger than that of the first ammonium cation.

[Hydrophobicity]

The retention time of the ammonium cation (second ammonium cation) in the polymeric compound 2 was 2.2 minutes, and the retention time of the first ammonium cation in the polymeric compound 1 was 3.6 minutes. That is, the second ammonium cation was less hydrophobic than the first ammonium cation.

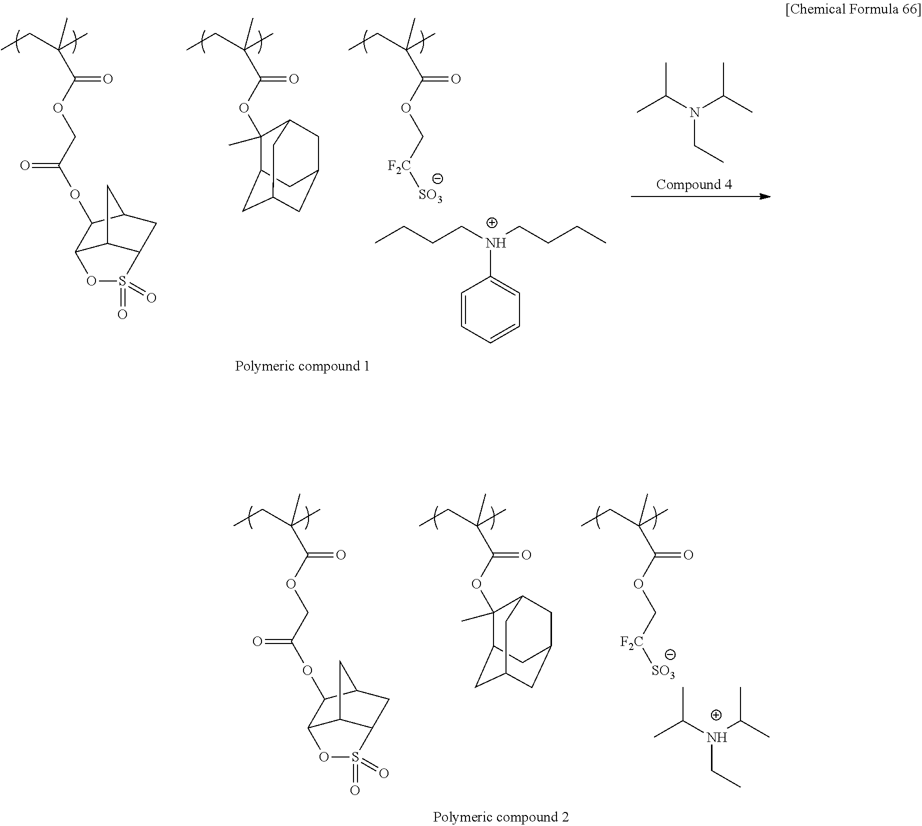

Salt-Exchange Step:

In a round-bottom flask, 33.1 g of the polymeric compound 2, 6.11 g of the compound 5, 132 g of dichloromethane, and 132 g of water were added, and stirred for 30 minutes to extract an organic layer. The extracted organic layer was dropwise added to an excess amount of n-heptane, and an operation to deposit a polymer was conducted. Thereafter, the precipitated white powder was separated by filtration, followed by drying, thereby obtaining 33.1 g of the polymeric compound 3.

With respect to the polymeric compound 3, the weight average molecular weight (Mw) and the dispersity (Mw/Mn) were determined by the polystyrene equivalent value as measured by gel permeation chromatography (GPC). As a result, it was found that the weight average molecular weight was 12,400, and the dispersity was 1.56. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=44.2/41.5/14.3.

[Hydrophobicity]

The retention time of the second ammonium cation in the polymeric compound 2 was 2.2 minutes, and the retention time of the sulfonium cation in the polymeric compound 5 was 2.6 minutes. That is, the second ammonium cation was less hydrophobic than the sulfonium cation.

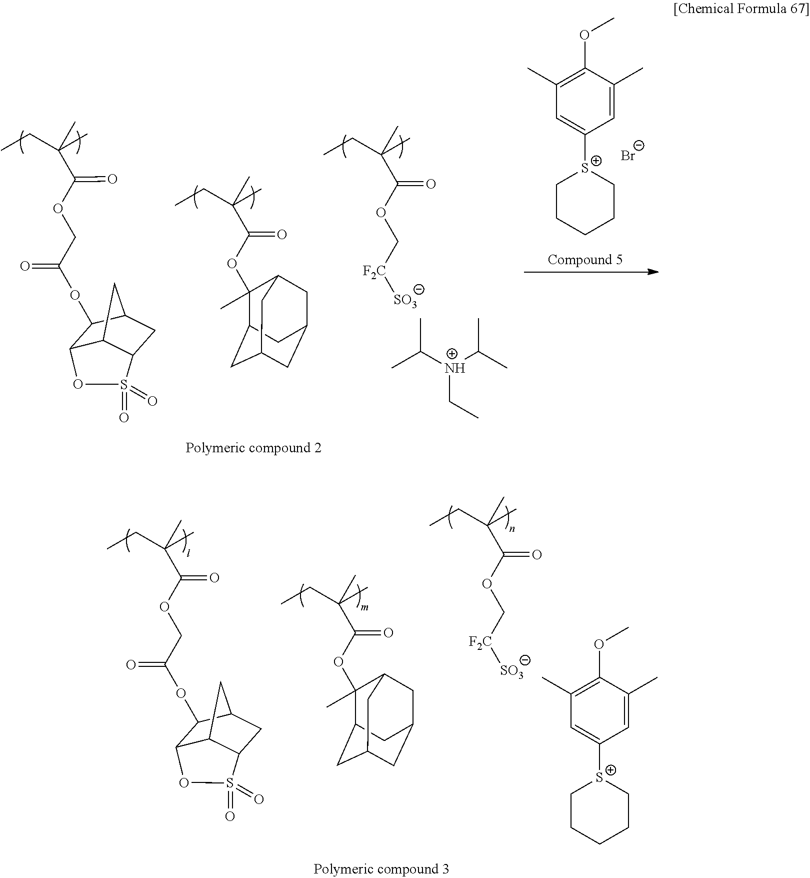

### Comparative Example 1

In a round-bottom flask, 39.5 g of the polymeric compound 1, 7.03 g of the compound 5, 158 g of dichloromethane, and 158 g of water were added, and stirred for 30 minutes to extract an organic layer. The extracted organic layer was dropwise added to an excess amount of n-heptane, and an operation to deposit a polymer was conducted. However, only the polymeric compound 1 was collected, and the polymeric compound 3 was not obtained.

With respect to the collected polymeric compound 1, the weight average molecular weight (Mw) and the dispersity (Mw/Mn) were determined by the polystyrene equivalent value as measured by gel permeation chromatography (GPC). As a result, it was found that the weight average molecular weight was 12,600, and the dispersity was 1.62. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=44.0/41.8/14.2.

[Hydrophobicity]

The retention time of the ammonium cation in the polymeric compound 1 was 3.6 minutes, and the retention time of the sulfonium cation in the polymeric compound 5 was 2.6 minutes. That is, the ammonium cation in the polymeric compound 1 was more hydrophobic than the sulfonium cation.

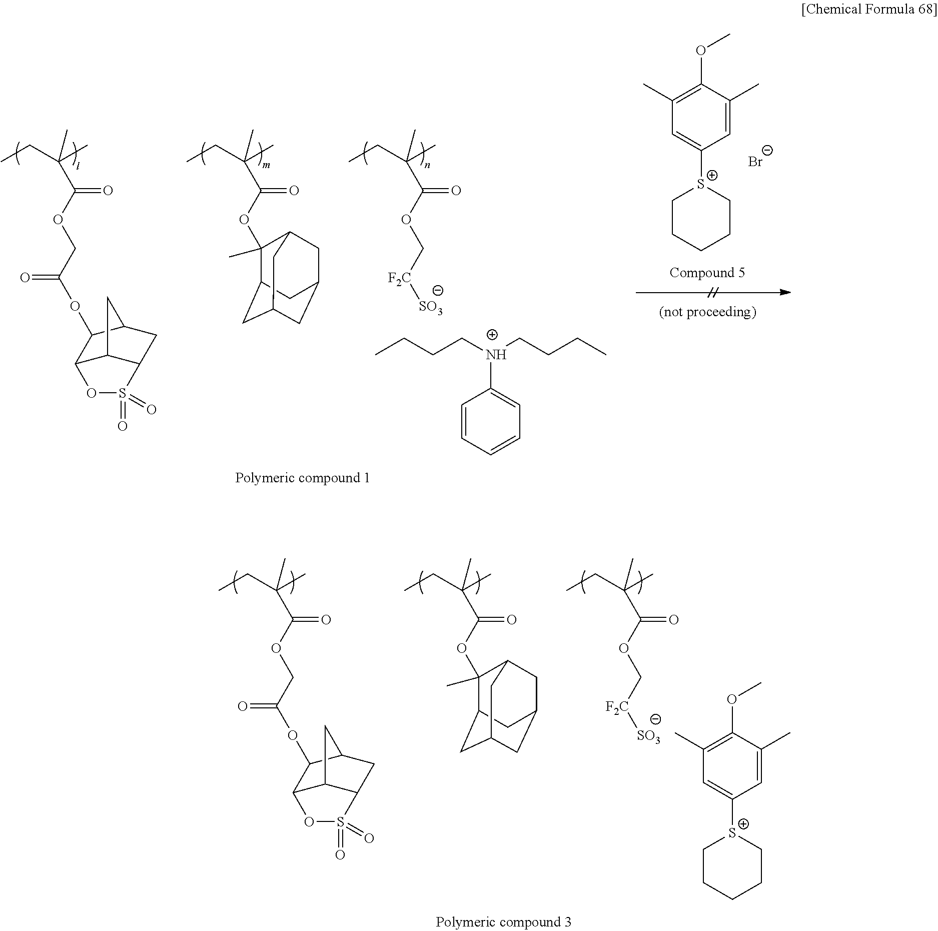

### Comparative Example 2

In a separable flask equipped with a thermometer, a reflux tube and a nitrogen feeding pipe, 10.00 g (31.61 mmol) of the compound 1, 14.36 g (61.27 mmol) of the compound 2, and 4.55 g (9.75 mmol) of the compound 6 were dissolved in 36.35 g of a mixed solvent of methyl ethyl ketone and cyclohexanone (MEK/CH) to obtain a solution. Then, 7.18 mmol of dimethyl 2,2′-azobis(isobutyrate) (V-601) was added and dissolved in the obtained solution. Then, the resultant was dropwise added to 20.15 g of MEK/CH in a nitrogen atmosphere over 4 hours for a reaction. Thereafter, the reaction solution was heated for 1 hour while stirring to obtain a white solid.

Then, the white solid was separated by filtration, and a result of a following analysis by carbon 13 nuclear magnetic resonance spectroscopy (600 MHz, ¹³C-NMR) confirmed that the compound 2 was deprotected, and the polymeric compound 3 was not obtained. In addition, a weight average molecular weight (Mw), a dispersity (Mw/Mn), and a composition of the copolymer could not be measured.

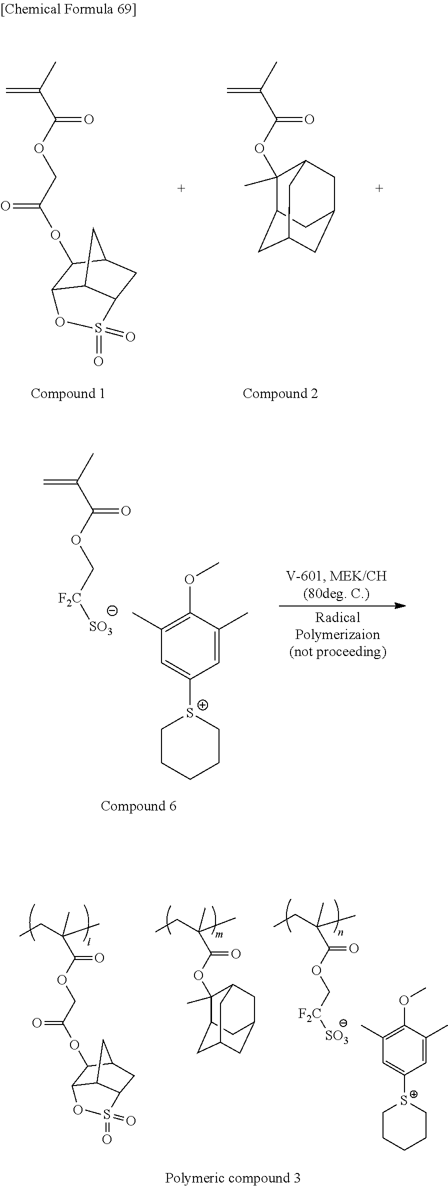

### Example 2

### Production Example of Polymeric Compound 7

Step for Obtaining the First Precursor Polymer:

In a separable flask equipped with a thermometer, a reflux tube and a nitrogen feeding pipe, 40.00 g (126.5 mmol) of the compound 1, 57.43 g (245.1 mmol) of the compound 2, and 19.21 g (39.00 mmol) of the compound 7 were dissolved in 146.7 g of a mixed solvent of methyl ethyl ketone and cyclohexanone (MEK/CH) to obtain a solution. Then, 28.74 mmol of dimethyl 2,2′-azobis(isobutyrate) (V-601) was added and dissolved in the obtained solution. Then, the resultant was dropwise added to 81.30 g of MEK/CH in a nitrogen atmosphere over 4 hours for a reaction. Thereafter, the reaction solution was heated for 1 hour while stirring, and then cooled to room temperature. Then, the obtained reaction polymer solution was dropwise added to an excess amount of an n-heptane, and an operation to deposit a polymer was conducted. Thereafter, the precipitated white powder was separated by filtration, followed by washing with a methanol and drying, thereby obtaining 81.2 g of the polymeric compound 4 (third precursor polymer).

In a round-bottom flask, 81.2 g of the polymeric compound 4, 21.2 g of the compound 8 (salt), 325 g of MEK, and 325 g of water were added, and stirred for 30 minutes to extract an organic layer. The extracted organic layer was dropwise added to an excess amount of n-heptane, and an operation to deposit a polymer was conducted. Thereafter, the precipitated white powder was separated by filtration, followed by drying, thereby obtaining 73.3 g of the polymeric compound 5 (first precursor polymer).

[Hydrophobicity]

The retention time of the sulfonium cation in the polymeric compound 4 was 2.7 minutes, and the retention time of the ammonium cation (first ammonium cation) in the polymeric compound 8 (salt) was 3.6 minutes. That is, the first ammonium cation was more hydrophobic than the sulfonium cation.

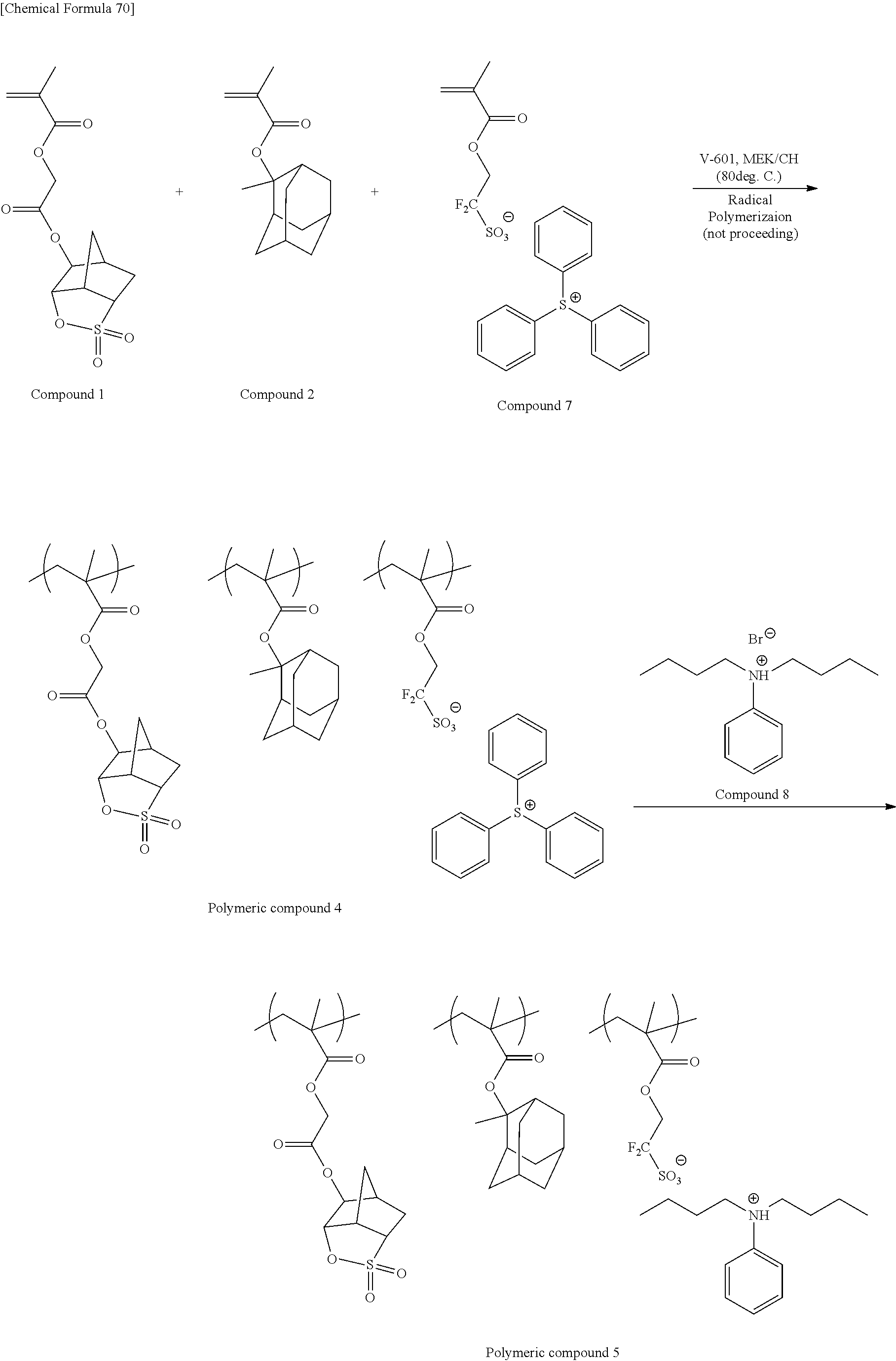

Amine Reaction Step:

The polymeric compound 6 (second precursor polymer; the chemical structure thereof is the same as the aforementioned polymeric compound 2) was obtained in the same manner as in the amine reaction step of Example 1 (the compound 4 was used as the amine), except that the aforementioned polymeric compound 5 was used instead of the aforementioned polymeric compound 1.

[pKa]

The pKa of the conjugate acid (second ammonium cation) in the compound 4 (amine) was 10.98, and the pKa of the ammonium cation (first ammonium cation) in the polymeric compound 5 was 6.28. That is, the pKa of the conjugate acid (second ammonium cation) was larger than that of the first ammonium cation.

[Hydrophobicity]

The retention time of the ammonium cation (second ammonium cation) in the polymeric compound 6 was 2.2 minutes, and the retention time of the first ammonium cation in the polymeric compound 5 was 3.6 minutes. That is, the second ammonium cation was less hydrophobic than the first ammonium cation.

Salt-Exchange Step:

The polymeric compound 7 (the chemical structure thereof is the same as the aforementioned polymeric compound 3) was obtained in the same manner as in the salt-exchange reaction step of Example 1, except that the aforementioned polymeric compound 6 was used instead of the aforementioned polymeric compound 2.

With respect to the polymeric compound 7, the weight average molecular weight (Mw) and the dispersity (Mw/Mn) were determined by the polystyrene equivalent value as measured by gel permeation chromatography (GPC). As a result, it was found that the weight average molecular weight was 12,600, and the dispersity was 1.54. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=43.8/42.0/14.2.

[Hydrophobicity]

The retention time of the second ammonium cation in the polymeric compound 6 was 2.2 minutes, and the retention time of the sulfonium cation in the polymeric compound 5 was 2.6 minutes. That is, the second ammonium cation was less hydrophobic than the sulfonium cation.

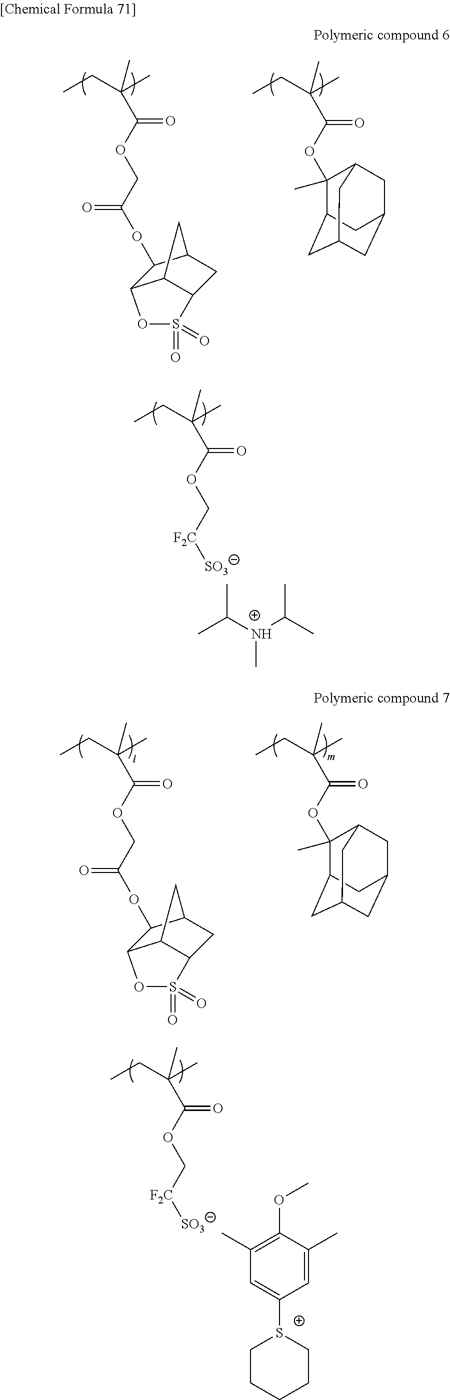

### Comparative Example 3

In a round-bottom flask, 5.00 g of the polymeric compound 4, 0.84 g of the compound 5, 20.0 g of dichloromethane, and 20.0 g of water were added, and stirred for 30 minutes to extract an organic layer. The extracted organic layer was dropwise added to an excess amount of n-heptane, and an operation to deposit a polymer was conducted. However, only the polymeric compound 4 was collected, and the polymeric compound 3 was not obtained.

With respect to the collected polymeric compound 4, the weight average molecular weight (Mw) and the dispersity (Mw/Mn) were determined by the polystyrene equivalent value as measured by gel permeation chromatography (GPC). As a result, it was found that the weight average molecular weight was 12,900, and the dispersity was 1.71. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=45.1/40.4/14.5.

[Hydrophobicity]

The retention time of the sulfonium cation in the polymeric compound 4 was 2.7 minutes, and the retention time of the sulfonium cation in the polymeric compound 5 was 2.6 minutes. That is, the sulfonium cation in the polymeric compound 4 was more hydrophobic than the sulfonium cation in the compound 5.

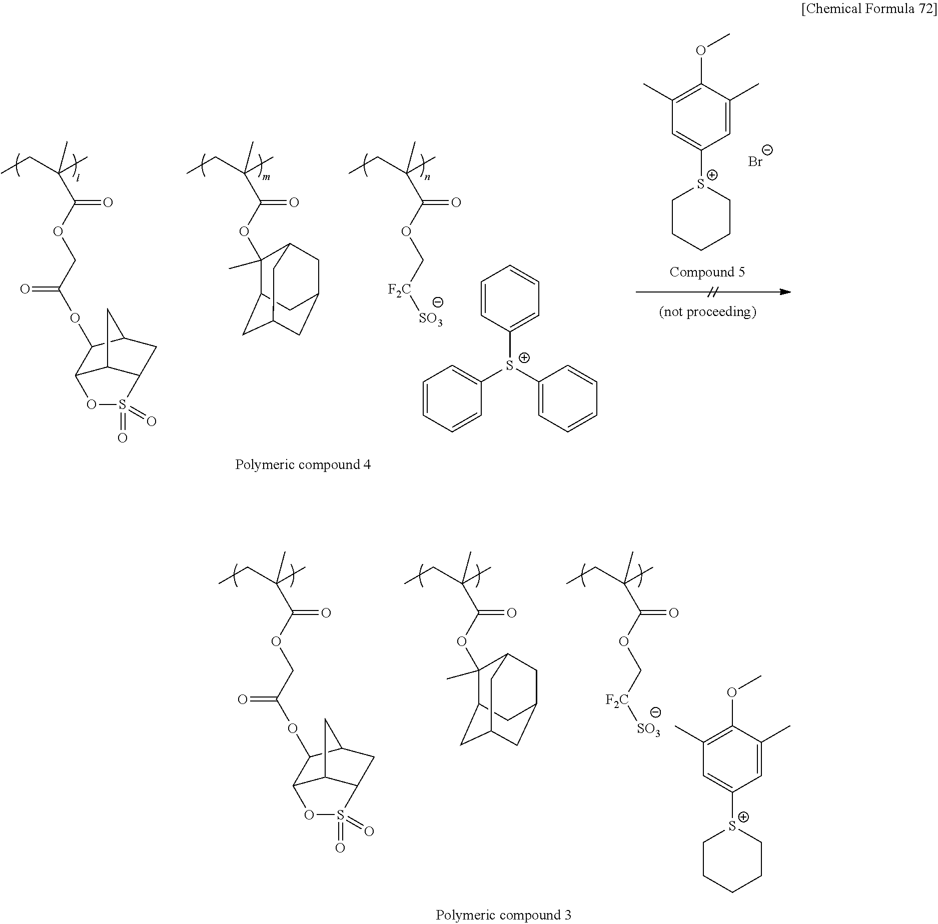

### Comparative Example 4

An acetonitrile layer was extracted by using the polymeric compound 1, in the same manner as in the amine reaction step of Example 1, except that the aforementioned compound 9 was used as an amine, instead of the aforementioned compound 4. The extracted acetonitrile layer was dropwise added to an excess amount of diisopropyl ether, and an operation to deposit a polymer was conducted. However, only the polymeric compound 1 was collected, and the polymeric compound 8 was not obtained.

With respect to the collected polymeric compound 1, the weight average molecular weight (Mw) and the dispersity (Mw/Mn) were determined by the polystyrene equivalent value as measured by gel permeation chromatography (GPC). As a result, it was found that the weight average molecular weight was 12,600, and the dispersity was 1.61. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=44.1/41.9/14.0.

[pKa]

The pKa of the conjugate acid (ammonium cation) in the compound 9 (amine) was 4.25, and the pKa of the ammonium cation in the polymeric compound 1 was 6.28. That is, the pKa of the conjugate acid (ammonium cation) was smaller than that of the ammonium cation in the polymeric compound 1.

[Hydrophobicity]

The retention time of the ammonium cation in the polymeric compound 8 was 6.0 minutes, and the retention time of the ammonium cation in the polymeric compound 1 was 3.6 minutes. That is, the ammonium cation in the polymeric compound 8 was more hydrophobic than the ammonium cation in the polymeric compound 1.

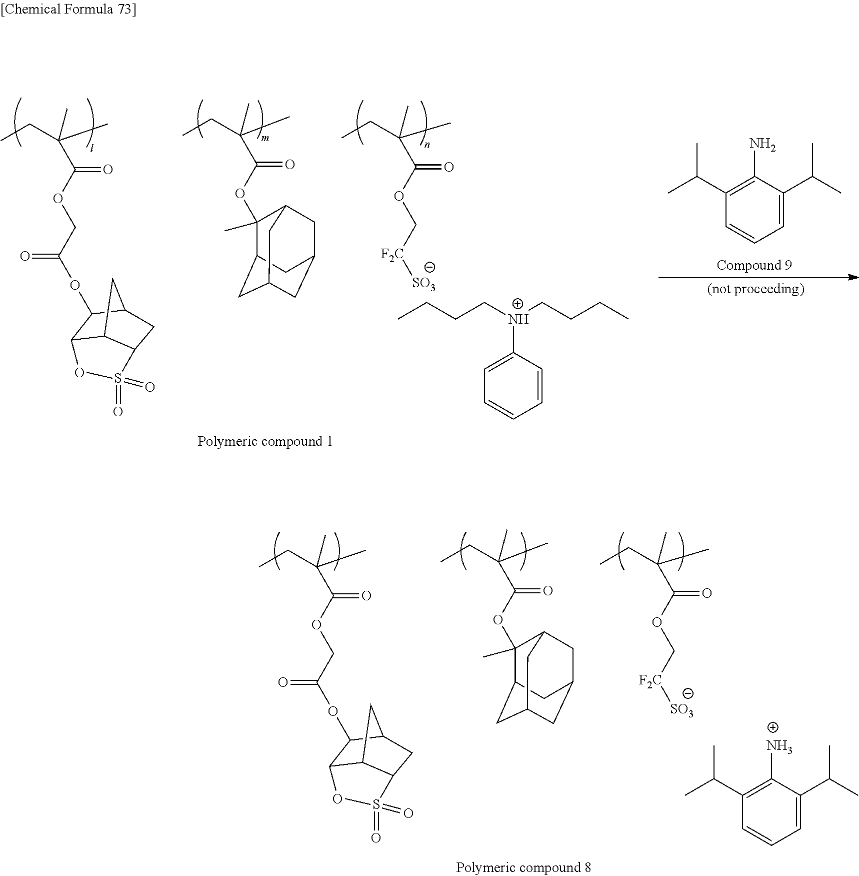

### Example 3

The polymeric compound 9 was obtained by performing each operation in the step for obtaining the first precursor polymer, the amine reaction step (the compound 4 was used as an amine), and the salt-exchange step in the same manner as in Example 2, except that the compound 10 was further used in addition to the compounds 1, 2, and 7, when the third precursor polymer was synthesized.

With respect to the polymeric compound 9, the weight average molecular weight (Mw) and the dispersity (Mw/Mn) were determined by the polystyrene equivalent value as measured by gel permeation chromatography (GPC). As a result, it was found that the weight average molecular weight was 11,700, and the dispersity was 1.80. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n/o=36.2/33.4/17.1/13.3.

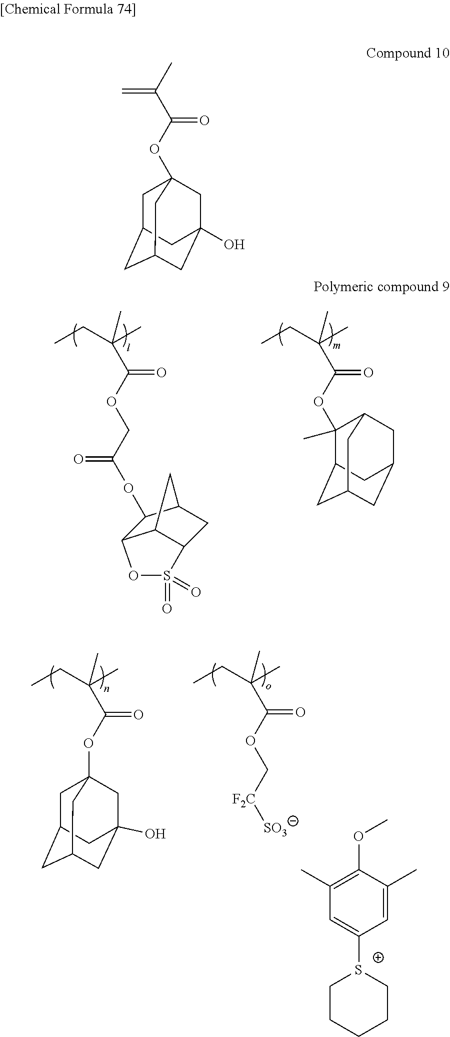

### Example 4

The polymeric compound 10 was obtained by performing each operation in the step for obtaining the first precursor polymer, the amine reaction step (the compound 4 was used as an amine), and the salt-exchange step in the same manner as in Example 1, except that the compound 11 was used instead of the compound 2.

With respect to the polymeric compound 10, the weight average molecular weight (Mw) and the dispersity (Mw/Mn) were determined by the polystyrene equivalent value as measured by gel permeation chromatography (GPC). As a result, it was found that the weight average molecular weight was 12,000, and the dispersity was 1.76. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=44.9/40.8/14.3.

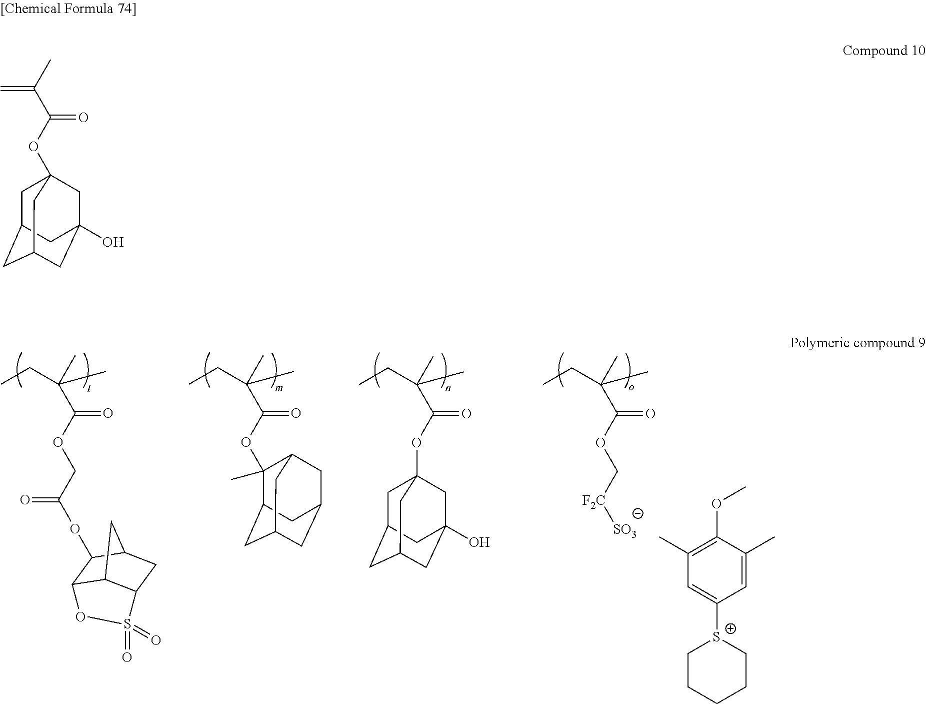

### Example 5

The polymeric compound 11 was obtained by performing each operation in the step for obtaining the first precursor polymer, the amine reaction step (the compound 4 was used as an amine), and the salt-exchange step in the same manner as in Example 1, except that the compound 12 was used instead of the compound 2.

With respect to the polymeric compound 11, the weight average molecular weight (Mw) and the dispersity (Mw/Mn) were determined by the polystyrene equivalent value as measured by gel permeation chromatography (GPC). As a result, it was found that the weight average molecular weight was 13,500, and the dispersity was 1.59. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=45.5/41.7/12.8.

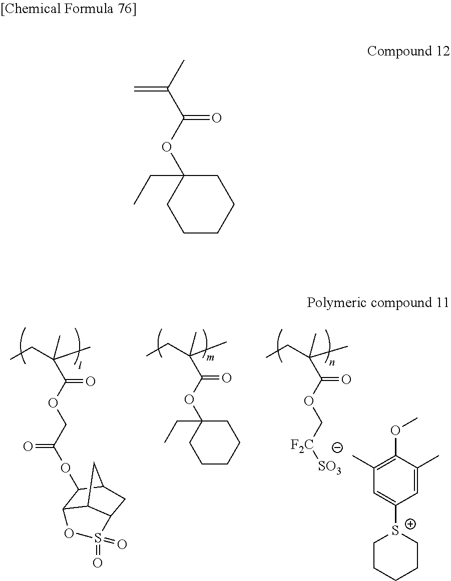

### Example 6

The polymeric compound 12 was obtained by performing each operation in the step for obtaining the first precursor polymer, the amine reaction step (the compound 4 was used as an amine), and the salt-exchange step in the same manner as in Example 2, except that the compound 12 was further used in addition to the compounds 1, 2, and 3, when the third precursor polymer was synthesized.

With respect to the polymeric compound 12, the weight average molecular weight (Mw) and the dispersity (Mw/Mn) were determined by the polystyrene equivalent value as measured by gel permeation chromatography (GPC). As a result, it was found that the weight average molecular weight was 13,700, and the dispersity was 1.83. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n/o=43.2/21.2/20.7/14.9.

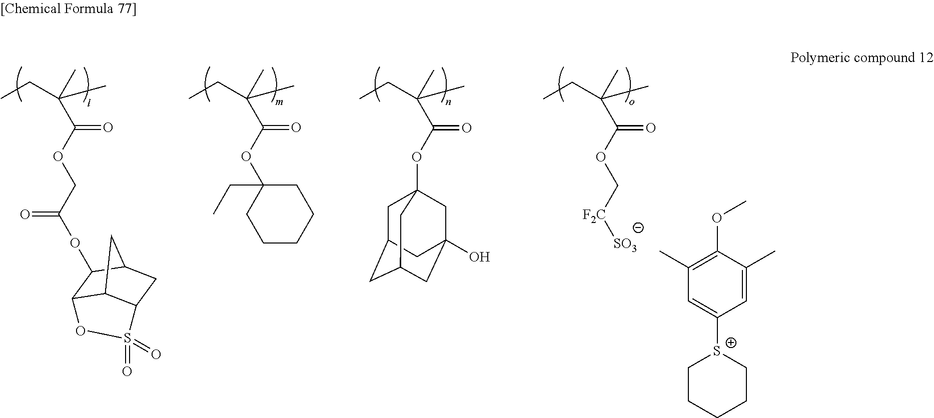

### Example 7

The polymeric compound 13 was obtained by performing each operation in the step for obtaining the first precursor polymer, the amine reaction step (the compound 4 was used as an amine), and the salt-exchange step in the same manner as in Example 1, except that the compound 13 was used instead of the compound 2.

With respect to the polymeric compound 13, the weight average molecular weight (Mw) and the dispersity (Mw/Mn) were determined by the polystyrene equivalent value as measured by gel permeation chromatography (GPC). As a result, it was found that the weight average molecular weight was 13,400, and the dispersity was 1.68. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=46.2/41.5/12.3.

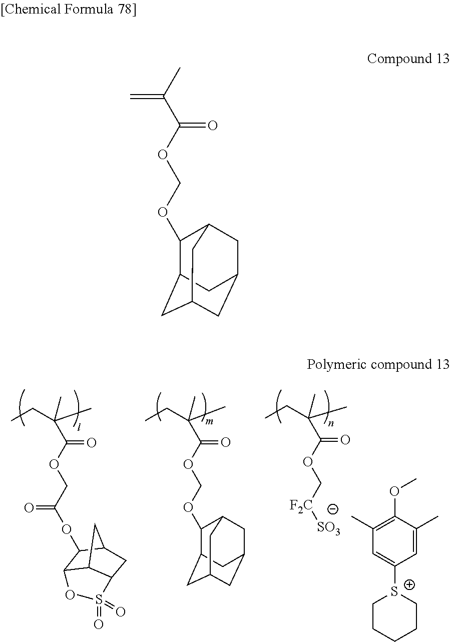

### Example 8

The polymeric compound 14 was obtained by performing each operation in the step for obtaining the first precursor polymer, the amine reaction step (the compound 4 was used as an amine), and the salt-exchange step in the same manner as in Example 1, except that the compound 14 was used instead of the compound 5.

With respect to the polymeric compound 14, the weight average molecular weight (Mw) and the dispersity (Mw/Mn) were determined by the polystyrene equivalent value as measured by gel permeation chromatography (GPC). As a result, it was found that the weight average molecular weight was 12,500, and the dispersity was 1.56. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=44.4/41.0/14.6.

[Hydrophobicity in the Salt-Exchange Step]

The retention time of the second ammonium cation in the polymeric compound 2 was 2.2 minutes, and the retention time of the sulfonium cation in the polymeric compound 14 was 2.3 minutes. That is, the second ammonium cation was less hydrophobic than the sulfonium cation.

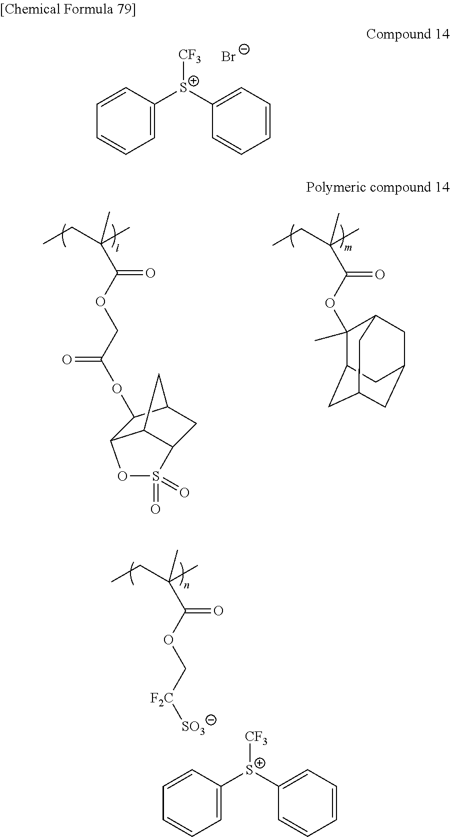

### Example 9

The polymeric compound 15 was obtained by performing each operation in the step for obtaining the first precursor polymer, the amine reaction step (the compound 4 was used as an amine), and the salt-exchange step in the same manner as in Example 1, except that the compound 15 was used instead of the compound 1.

With respect to the polymeric compound 15, the weight average molecular weight (Mw) and the dispersity (Mw/Mn) were determined by the polystyrene equivalent value as measured by gel permeation chromatography (GPC). As a result, it was found that the weight average molecular weight was 13,100, and the dispersity was 1.60. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=45.5/41.4/13.1.

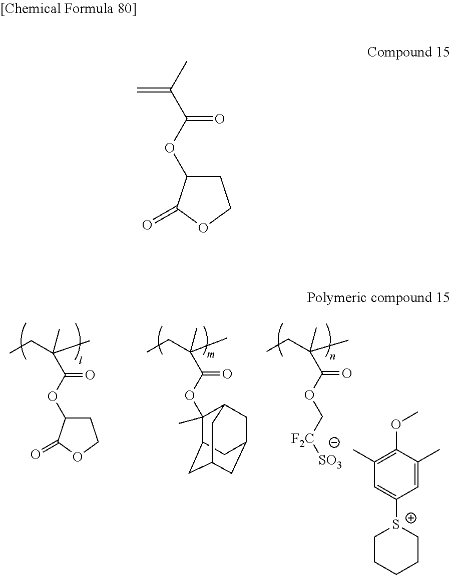

### Example 10

The polymeric compound 16 was obtained by performing each operation in the step for obtaining the first precursor polymer, the amine reaction step (the compound 4 was used as an amine), and the salt-exchange step in the same manner as in Example 1, except that the compound 16 was used instead of the compound 1.

With respect to the polymeric compound 16, the weight average molecular weight (Mw) and the dispersity (Mw/Mn) were determined by the polystyrene equivalent value as measured by gel permeation chromatography (GPC). As a result, it was found that the weight average molecular weight was 12,000, and the dispersity was 1.81. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=42.7/45.0/12.3.

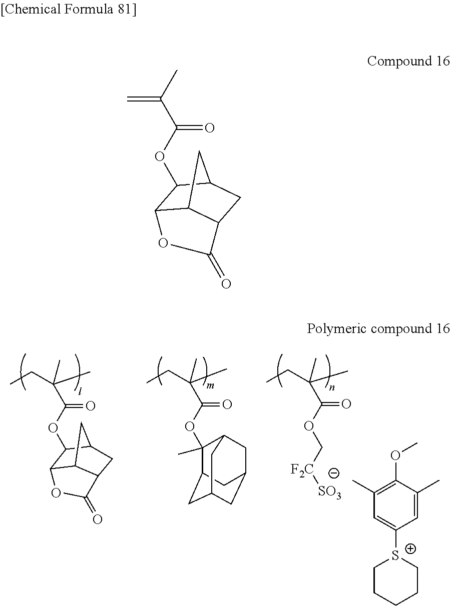

### Example 11

The polymeric compound 17 was obtained by performing each operation in the step for obtaining the first precursor polymer, the amine reaction step (the compound 4 was used as an amine), and the salt-exchange step in the same manner as in Example I, except that the compound 17 was used instead of the compound 1.

With respect to the polymeric compound 17, the weight average molecular weight (Mw) and the dispersity (Mw/Mn) were determined by the polystyrene equivalent value as measured by gel permeation chromatography (GPC). As a result, it was found that the weight average molecular weight was 12,800, and the dispersity was 1.67. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=43.0/44.9/12.1.

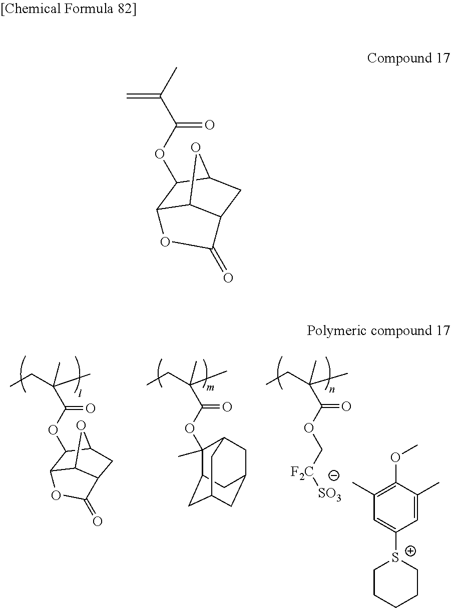

### Example 12

The polymeric compound 18 was obtained by performing each operation in the step for obtaining the first precursor polymer, the amine reaction step (the compound 4 was used as an amine), and the salt-exchange step in the same manner as in Example 1, except that the compound 18 was used instead of the compound 3.

With respect to the polymeric compound 18, the weight average molecular weight (Mw) and the dispersity (Mw/Mn) were determined by the polystyrene equivalent value as measured by gel permeation chromatography (GPC). As a result, it was found that the weight average molecular weight was 11,500, and the dispersity was 1.71. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=44.1/41.9/14.0.

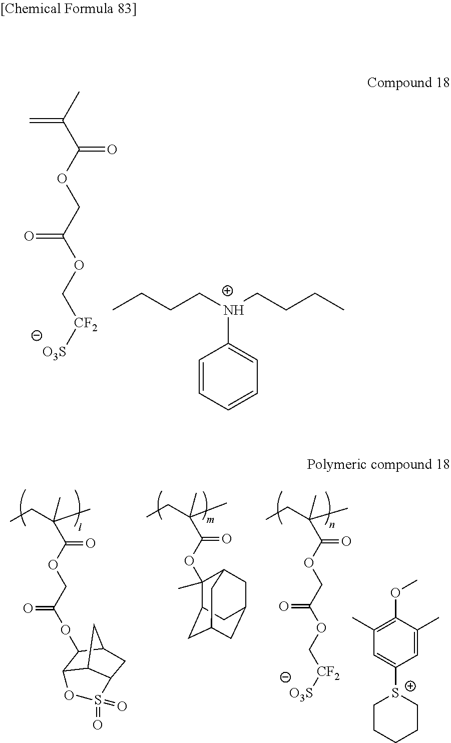

### Example 13

The polymeric compound 19 was obtained by performing each operation in the step for obtaining the first precursor polymer, the amine reaction step (the compound 4 was used as an amine), and the salt-exchange step in the same manner as in Example 1, except that the compound 19 was used instead of the compound 3.

With respect to the polymeric compound 19, the weight average molecular weight (Mw) and the dispersity (Mw/Mn) were determined by the polystyrene equivalent value as measured by gel permeation chromatography (GPC). As a result, it was found that the weight average molecular weight was 12,500, and the dispersity was 1.59. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=44.5/41.8/13.7.

[pKa in the Amine Reaction Step]

The pKa of the conjugate acid (second ammonium cation) in the compound 4 (amine) was 10.98, and the pKa of the first ammonium cation in the first precursor polymer was 4.25. That is, the pKa of the conjugate acid (second ammonium cation) was larger than that of the first ammonium cation.

[Hydrophobicity in the Amine Reaction Step]

The retention time of the second ammonium cation in the second precursor polymer was 2.2 minutes, and the retention time of the first ammonium cation in the first precursor polymer was 6.0 minutes. That is, the second ammonium cation was less hydrophobic than the first ammonium cation.

[Hydrophobicity in the Salt-Exchange Step]

The retention time of the second ammonium cation in the second precursor polymer was 2.2 minutes, and the retention time of the sulfonium cation in the compound 5 was 2.6 minutes. That is, the second ammonium cation was less hydrophobic than the sulfonium cation.

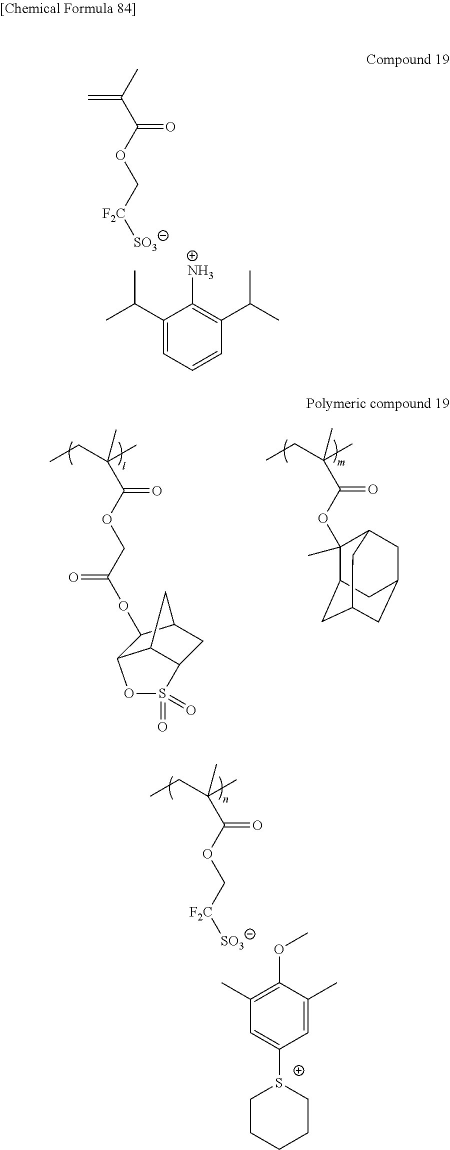

### Example 14

The polymeric compound 20 was obtained by performing each operation in the step for obtaining the first precursor polymer, the amine reaction step (the compound 4 was used as an amine), and the salt-exchange step in the same manner as in Example 1, except that the compound 20 was used instead of the compound 3.

With respect to the polymeric compound 20, the weight average molecular weight (Mw) and the dispersity (Mw/Mn) were determined by the polystyrene equivalent value as measured by gel permeation chromatography (GPC). As a result, it was found that the weight average molecular weight was 12,500, and the dispersity was 1.61. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=44.2/41.3/14.5.

[pKa in the Amine Reaction Step]

The pKa of the conjugate acid (second ammonium cation) in the compound 4 (amine) was 10.98, and the pKa of the first ammonium cation in the first precursor polymer was 6.23. That is, the pKa of the conjugate acid (second ammonium cation) was larger than that of the first ammonium cation.

[Hydrophobicity in the Amine Reaction Step]

The retention time of the second ammonium cation in the second precursor polymer was 2.2 minutes, and the retention time of the first ammonium cation in the first precursor polymer was 12.9 minutes. That is, the second ammonium cation was less hydrophobic than the first ammonium cation.

[Hydrophobicity in the Salt-Exchange Step]

The retention time of the second ammonium cation in the second precursor polymer was 2.2 minutes, and the retention time of the sulfonium cation in the compound 5 was 2.6 minutes. That is, the second ammonium cation was less hydrophobic than the sulfonium cation.

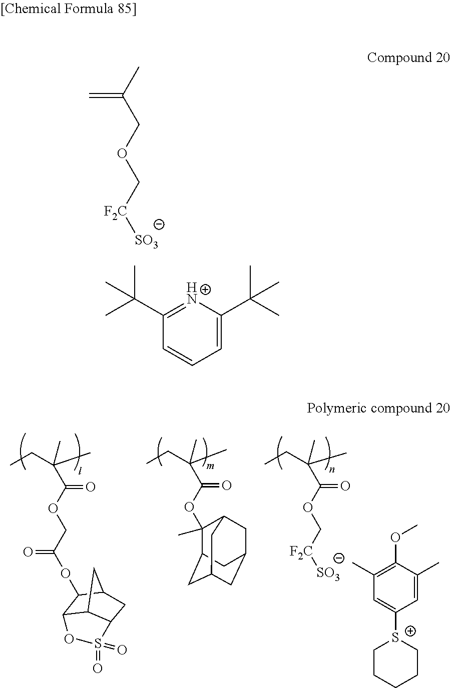

### Example 15

The polymeric compound 21 was obtained by performing each operation in the step for obtaining the first precursor polymer, the amine reaction step, and the salt-exchange step in the same manner as in Example 1, except that the compound 21 was used instead of the compound 4.

With respect to the polymeric compound 21, the weight average molecular weight (Mw) and the dispersity (Mw/Mn) were determined by the polystyrene equivalent value as measured by gel permeation chromatography (GPC). As a result, it was found that the weight average molecular weight was 12,300, and the dispersity was 1.62. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=43.7/42.0/14.3.

[pKa in the Amine Reaction Step]

The pKa of the conjugate acid (second ammonium cation) in the compound 21 (amine) was 10.62, and the pKa of the first ammonium cation in the first precursor polymer was 6.28. That is, the pKa of the conjugate acid (second ammonium cation) was larger than that of the first ammonium cation.

[Hydrophobicity in the Amine Reaction Step]

The retention time of the second ammonium cation in the second precursor polymer was 2.2 minutes, and the retention time of the first ammonium cation in the first precursor polymer was 3.6 minutes. That is, the second ammonium cation was less hydrophobic than the first ammonium cation.

[Hydrophobicity in the Salt-Exchange Step]

The retention time of the second ammonium cation in the second precursor polymer was 2.2 minutes, and the retention time of the sulfonium cation in the compound 5 was 2.6 minutes. That is, the second ammonium cation was less hydrophobic than the sulfonium cation.

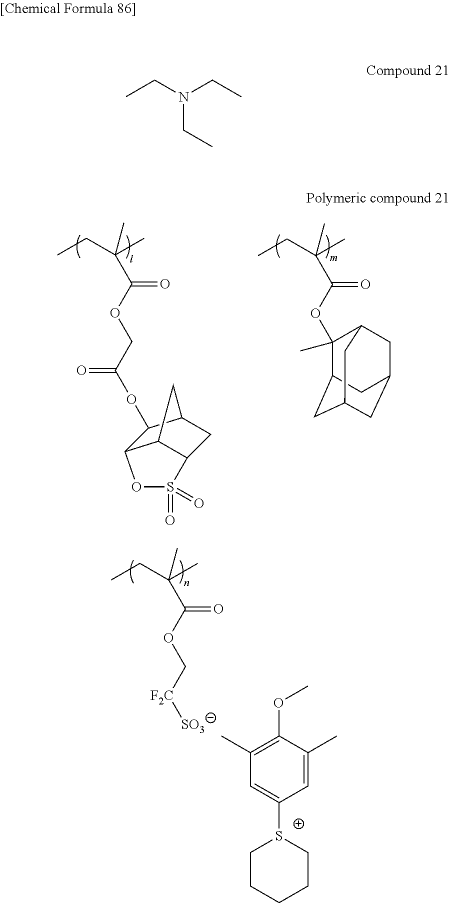

### Example 16

The polymeric compound 22 was obtained by performing each operation in the step for obtaining the first precursor polymer, the amine reaction step, and the salt-exchange step in the same manner as in Example I, except that the compound 22 was used instead of the compound 4.

With respect to the polymeric compound 22, the weight average molecular weight (Mw) and the dispersity (Mw/Mn) were determined by the polystyrene equivalent value as measured by gel permeation chromatography (GPC). As a result, it was found that the weight average molecular weight was 12,400, and the dispersity was 1.57. Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was l/m/n=44.0/41.6/14.4.

[pKa in the Amine Reaction Step]

The pKa of the conjugate acid (second ammonium cation) in the compound 22 (amine) was 9.52, and the pKa of the first ammonium cation in the first precursor polymer was 6.28. That is, the pKa of the conjugate acid (second ammonium cation) was larger than that of the first ammonium cation.

[Hydrophobicity in the Amine Reaction Step]

The retention time of the second ammonium cation in the second precursor polymer was 2.2 minutes, and the retention time of the first ammonium cation in the first precursor polymer was 3.6 minutes. That is, the second ammonium cation was less hydrophobic than the first ammonium cation.

[Hydrophobicity in the Salt-Exchange Step]

The retention time of the second ammonium cation in the second precursor polymer was 2.2 minutes, and the retention time of the sulfonium cation in the compound 5 was 2.6 minutes. That is, the second ammonium cation was less hydrophobic than the sulfonium cation.

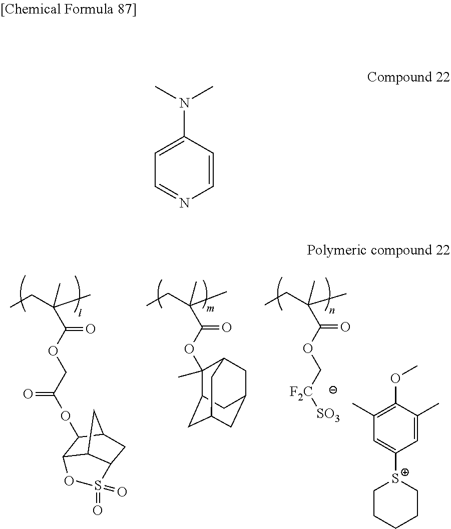

### Preparation of Resist Composition

### Examples 17 to 20

The components shown in Table 1 were mixed together and dissolved to obtain a positive resist composition.

TABLE 1

| | Component | Component | Component | Component | Component | Component |
|---|---|---|---|---|---|---|
| | (A) | (B) | (D) | (E) | (F) | (S) |
| Example | (A)-1 | — | (D)-1 | (E)-1 | (F)-1 | (S)-1 |
| 17 | [100] | | [0.38] | [0.47] | [3.0] | [2400] |
| Example | (A)-1 | — | (D)-1 | (E)-1 | (F)-1 | (S)-1 |
| 18 | [100] | | [0.38] | [0.47] | [3.0] | [2400] |
| Example | (A)-2 | (B)-1 | (D)-1 | (E)-1 | (F)-1 | (S)-1 |
| 19 | [100] | [3.2] | [0.38] | [0.47] | [3.0] | [2400] |
| Example | (A)-12 | — | (D)-1 | (E)-1 | (F)-1 | (S)-1 |
| 20 | [100] | | [0.38] | [0.47] | [3.0] | [2400] |

In Table 1, the values in brackets [ ] indicate the amount (in terms of parts by weight) of the component added, and the reference characters indicate the following

(A)-1: the aforementioned polymeric compound 3 produced in Example 1.

(A)-2: the aforementioned polymeric compound 7 produced in Example 2.

(A)-12: the aforementioned polymeric compound 18 produced in Example 12.

(B)-1: compound (B)-1 shown below.

(D)-1: tri-n-pentylamine.

(E)-1: salicylic acid.

(F)-1: the polymeric compound (F)-1 (Mw: 18,000, Mw/Mn: 1.5; In the chemical formula, the subscript numerals shown on the bottom right of the parentheses ( ) indicate the percentage (mol %) of the respective structural units.

(S)-1: a mixed solvent of PGMEA/PGME/cyclohexanone=45/30/25 (weight ratio).

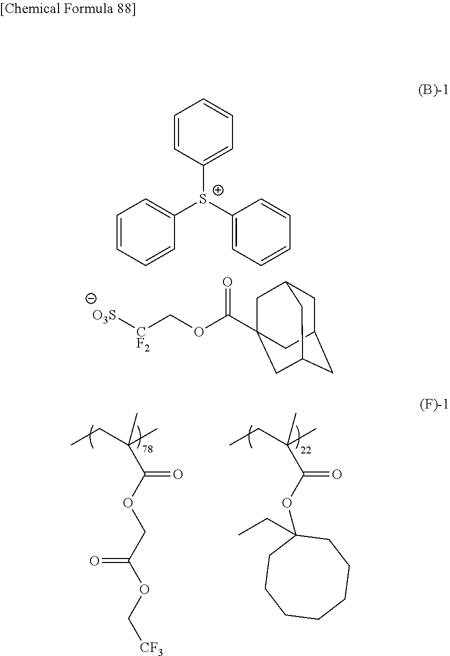

<Formation of Resist Pattern>

An organic anti-reflection film composition (product name: ARC29A, manufactured by Brewer Science Ltd.) was applied to an 12-inch silicon wafer using a spinner, and the composition was then baked at 205° C. for 60 seconds, thereby forming an organic anti-reflection film having a film thickness of 89 nm.

Then, each of the aforementioned resist compositions was applied to the organic anti-reflection film using a spinner, and was then prebaked (PAB) on a hotplate at 110° C. for 60 seconds and dried, thereby forming a resist film having a film thickness of 90 nm.

Subsequently, the top coat-formed resist film was selectively irradiated with an ArF excimer laser (193 nm) through a mask, using an ArF immersion exposure apparatus NSR-S609B (manufactured by Nikon Corporation, NA (numerical aperture)=1.07).

Thereafter, a post exposure bake (PEB) treatment was conducted for 60 seconds, at 130° C. in Examples 17, 18, and 20, and at 100° C. in Example 19, followed by alkali development for 10 seconds at 23° C. in a 2.38% by weight aqueous solution of tetramethylammonium hydroxide (TMAH) “NMD-3” (product name, manufactured by Tokyo Ohka Kogyo Co., Ltd.). Then, the resist was washed for 30 seconds with pure water, followed by drying by shaking.

Further, a post bake was conducted at 100° C. for 45 seconds.

As a result, in each of the examples, a resist pattern of line and space having line patterns with a width of 49 nm provided at equal intervals (pitch: 98 nm) was formed on the resist film.

Although it has been difficult to obtain a polymeric compound having a final sulfonium or iodonium cation by a direct polymerization, as shown in the above Examples 1 to 16, such polymeric compounds can be obtained by the novel production method of a polymeric compound having a structural unit that is decomposed and generates acid upon exposure, according to the present invention.

As shown in Examples 17 to 20, such polymeric compounds are particularly useful as materials for photoresist compositions which form resist patterns having good lithography properties.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method of producing a polymeric compound having a structural unit that is decomposed and generates acid upon exposure, the method comprising:
reacting a first precursor polymer having a first ammonium cation with an amine whose conjugate acid has an acid dissociation constant (pKa) larger than an acid dissociation constant (pKa) of the first ammonium cation to obtain a second precursor polymer having a second ammonium cation that is a conjugate acid of the amine; and
performing a salt-exchange between the second precursor polymer and a sulfonium cation or an iodonium cation,
wherein the second ammonium cation is less hydrophobic than the first ammonium cation, and also less hydrophobic than the sulfonium cation or the iodonium cation.

2. The method of producing a polymeric compound according to claim 1, further comprising:
performing a salt-exchange between a third precursor polymer having a sulfonium cation or an iodonium cation and the first ammonium cation that is more hydrophobic than the sulfonium cation or the iodonium cation to obtain the first precursor polymer.

3. The method of producing a polymeric compound according to claim 1, wherein the first precursor polymer comprises a structural unit having an acid decomposable group whose polarity is increased by an action of acid.

4. A resist composition comprising a polymeric compound produced by the method of producing a polymeric compound according to claim 1.

5. A method of forming a resist pattern, comprising:
forming a resist film on a substrate by using the resist composition according to claim 4;
exposing the resist film; and
forming a resist pattern by developing the resist film.

6. A method of producing a polymeric compound, comprising:
reacting a first precursor polymer having a first ammonium cation with an amine whose conjugate acid has an acid dissociation constant (pKa) larger than an acid dissociation constant (pKa) of the first ammonium cation, and the conjugate acid is less hydrophobic than the first ammonium cation.
